(19) United States
(12) Patent Application Publication
(10) Pub. No.: US 2023/0269993 A1
(43) Pub. Date: Aug. 24, 2023

(54) DISPLAY DEVICE

(71) Applicant: Sony Semiconductor Solutions Corporation, Kanagawa (JP)

(72) Inventor: Masaaki Sekine, Saitama (JP)

(21) Appl. No.: 17/922,679

(22) PCT Filed: Jun. 10, 2021
(86) PCT No.: PCT/JP2021/022028

§ 371 Date: Nov. 1, 2022

(30) Foreign Application Priority Data
Jun. 25, 2020 (JP) 2020-109361

(51) Int. Cl. H10K 59/80; H10K 59/38

(52) U.S. Cl. CPC H10K 59/879; H10K 59/38; H10K 2102/351

(57) ABSTRACT

A display device includes a plurality of light emitting element units each including a first light emitting element (10₁), a second light emitting element (10₂), and a third light emitting element (10₃), wherein in each light emitting element unit, a first base (35₁) having a thickness TB₁ and a first lens unit (51₁) having a thickness TL₁ is provided on a first light emitting unit (30₁) that emits light of a first color, a second base (35₂) having a thickness TB₂ and a second lens unit (51₂) having a thickness TL₂ is provided on a second light emitting unit (30₂) that emits light of a second color, a third base (35₃) having a thickness TB₃ and a third lens unit (51₃) having a thickness TL₃ is provided on a third light emitting unit (30₃) that emits light of a third color, and (TL₃+TB₃)≤(TL₂+TB₂)<(TL₁+TB₁) is satisfied, excluding a case where TB₃, TB₂, and TB₁ have a same value.

### FIELD

The present disclosure relates to a display device.

### BACKGROUND

Display devices in which an organic EL element is used as a light emitting element (organic electroluminescence (EL) display devices) have recently been developed. An organic EL display device includes, for example, a plurality of light emitting elements each including a first electrode (lower electrode, e.g. anode electrode) formed separately for each pixel, an organic layer including at least a light emitting layer, and a second electrode (upper electrode, e.g. cathode electrode), the organic layer and the second electrode being formed on the first electrode. For example, each of a red light emitting element, a green light emitting element, and a blue light emitting element is provided as a subpixel, one pixel is constituted by these subpixels, and light from the light emitting layer is emitted to the outside via the second electrode (upper electrode).

Such a display device is provided with a lens member on the light emission side of each light emitting element to achieve long light emission life of the light emitting element, to improve light extraction efficiency, and to increase front luminance. For example, JP 2012-109213 A discloses a display device in which a convex lens is provided to reduce a difference in deterioration characteristics in an organic EL element for each emission color of a pixel. Specifically, a pixel including an organic EL element having a high deterioration rate is provided with a lens having a light collection characteristic larger than that of a lens provided to an organic EL element having a low deterioration rate, and the light collection characteristic is controlled by the curvature radius of a convex lens or the refractive index of the convex lens. JP 2012-089474 A discloses a display device in which a lens is provided to reduce a difference in angle dependence of luminance in an organic EL element for each emission color of a pixel. Specifically, a pixel including an organic EL element in which angle dependence of luminance is high is provided with a lens having a divergence characteristic larger than that of a lens provided to an organic EL element in which angle dependence of luminance is low, and the divergence characteristic is controlled by the curvature radius of a concave lens, the distance between the concave lens and a light emitting layer, or the refractive index of the concave lens.

### CITATION LIST

### Patent Literature

Patent Literature 1: JP 2012-109213 A
Patent Literature 2: JP 2012-089474 A

### SUMMARY

### Technical Problem

However, it is often difficult to control the light collection characteristic only by a curvature radius of the convex lens or the refractive index of a convex lens, and to control the divergence characteristic only by the curvature radius of a concave lens, the distance between the concave lens and a light emitting layer, or the refractive index of the concave lens.

An object of the present disclosure is to provide a display device having a configuration and a structure in which a lens unit is disposed on a light emission side of a light emitting element and emission of light from the light emitting element can be brought closer to a desired state.

### Solution to Problem

A display device according to a first aspect of the present disclosure in order to solve the above problem includes a plurality of light emitting element units,

the plurality of light emitting element units each includes:

a first light emitting element including a first light emitting unit that emits light of a first color;

a second light emitting element including a second light emitting unit that emits light of a second color; and

a third light emitting element including a third light emitting unit that emits light of a third color,

wherein

in each light emitting element unit,

a first base having a thickness TB₁ is provided on the first light emitting unit,

a second base having a thickness TB₂ is provided on the second light emitting unit,

a third base having a thickness TB₃ is provided on the third light emitting unit,

a first lens unit having a thickness TL₁ is provided on the first base,

a second lens unit having a thickness TL₂ is provided on the second base,

a third lens unit having a thickness TL₃ is provided on the third base, and

(TL₃+TB₃)≤(TL₂+TB₂)<(TL₁+TB₁)

is satisfied, excluding a case where TB₃, TB₂, and TB₁ have a same value.

A display device according to a second aspect of the present disclosure in order to solve the above problem includes a plurality of light emitting element units,

the plurality of light emitting element units each includes at least a first light emitting element having a first light emitting unit that emits light of a first color and a second light emitting element having a second light emitting unit that emits light of a second color,

wherein

in each light emitting element unit,

a first base having a thickness TB₁ is provided above the first light emitting unit,

a second base having a thickness TB₂ is provided above the second light emitting unit,

a first lens unit having a thickness TL₁ is provided on the first base, and

TB₂<(TL₁+TB₁)

is satisfied.

### BRIEF DESCRIPTION OF DRAWINGS

FIG. 1 is a schematic and partial sectional view of a display device of Example 1.

FIG. 2A is a schematic view of a lens unit and the like of one light emitting element unit in Example 1 as viewed from above.

FIG. 2B is a schematic view of the lens unit and the like of one light emitting element unit in Example 1 as viewed from above.

FIG. 3A is a schematic view of the lens unit and the like of one light emitting element unit in Example 1 as viewed from above.

FIG. 3B is a schematic view of the lens unit and the like of one light emitting element unit in Example 1 as viewed from above.

FIG. 4A is a schematic and partial sectional view of a lens unit and a base taken along the arrows A-A and C-C in FIG. 2A.

FIG. 4B is a schematic and partial sectional view of the lens unit and the base taken along the arrows B-B and D-D in FIG. 2A.

FIG. 5 is a schematic and partial sectional view of Modification-1 of the display device of Example 1.

FIG. 6 is a schematic and partial sectional view of Modification-2 of the display device of Example 1.

FIG. 7 is a schematic and partial sectional view of Modification-3 of the display device of Example 1.

FIG. 8 is a schematic and partial sectional view of a display device of Example 2.

FIG. 9A is a schematic view of a lens unit and the like of one light emitting element unit in Example 2 as viewed from above.

FIG. 9B is a schematic view of a lens unit and the like of one light emitting element unit in Example 2 as viewed from above.

FIG. 10 is a schematic view of a lens unit and the like of one light emitting element unit in Example 2 as viewed from above.

FIG. 11A is a schematic and partial sectional view of a lens unit and a base taken along the arrows A-A and C-C in FIG. 9A.

FIG. 11B is a schematic and partial sectional view of the lens unit and the base taken along the arrows B-B and D-D in FIG. 9A.

FIG. 12 is a schematic and partial sectional view of Modification-1 of the display device of Example 2.

FIG. 13 is a schematic and partial sectional view of Modification-2 of the display device of Example 2.

FIG. 14 is a schematic and partial sectional view of Modification-3 of the display device of Example 2.

FIG. 15 is a schematic and partial sectional view of a display device of Example 3.

FIG. 16 is a schematic and partial sectional view of Modification-1 of the display device of Example 3.

FIG. 17 is a schematic and partial sectional view of a display device of Example 4.

FIG. 18 is a schematic and partial sectional view of Modification-1 of the display device of Example 4.

FIG. 19 is a schematic and partial sectional view of Modification-2 of the display device of Example 4.

FIG. 20 is a schematic and partial sectional view of a display device of Example 5.

FIG. 21 is a schematic and partial sectional view of a base and the like constituting the display device of Example 5.

FIG. 22 is a schematic and partial sectional view of Modification-1 of the display device of Example 5.

FIG. 23 is a schematic view of a lens unit and the like of one light emitting element unit in Modification-1 of the display device of Example 5 as viewed from above.

FIG. 24 is a schematic and partial sectional view of a base and the like constituting a display device of Example 6.

FIG. 25 is a schematic and partial sectional view of Modification-1 of the display device of Example 6.

FIG. 26 is a schematic and partial sectional view of a display device of Example 7.

FIG. 27 is a schematic and partial sectional view of Modification-1 of the display device of Example 7.

FIG. 28A is a schematic view of a lens unit and the like of one light emitting element unit in Example 7 and Modification-1 of Example 7 as viewed from above.

FIG. 28B is a schematic view of a lens unit and the like of one light emitting element unit in Example 7 and Modification-1 of Example 7 as viewed from above.

FIG. 29A is a schematic and partial sectional view of a lens unit and a base in the display device of Example 7 taken along the arrows A-A and C-C in FIG. 28A.

FIG. 29B is a schematic and partial sectional view of the lens unit and the base taken along the arrows B-B and D-D in FIG. 28A.

FIG. 30A is a schematic and partial sectional view of a lens unit and a base in Modification-1 of the display device of Example 7 taken along the arrows A-A and C-C in FIG. 28B.

FIG. 30B is a schematic and partial sectional view of the lens unit and the base taken along the arrows B-B and D-D in FIG. 28B.

FIG. 31 is a schematic and partial sectional view of Modification-2 of the display device of Example 7.

FIG. 32 is a schematic and partial sectional view of Modification-3 of the display device of Example 7.

FIG. 33A is a schematic view of a lens unit and the like of one light emitting element unit in Modification-2 and Modification-3 of Example 7 as viewed from above.

FIG. 33B is a schematic view of a lens unit and the like of one light emitting element unit in Modification-2 and Modification-3 of Example 7 as viewed from above.

FIG. 34A is a schematic and partial sectional view of a lens unit and a base in Modification-2 of the display device of Example 7 taken along the arrows A-A and C-C in FIG. 33A.

FIG. 34B is a schematic and partial sectional view of the lens unit and the base taken along the arrows B-B and D-D in FIG. 33A.

FIG. 35A is a schematic and partial sectional view of a lens unit and a base in Modification-3 of the display device of Example 7 taken along the arrows A-A and C-C in FIG. 33B.

FIG. 35B is a schematic and partial sectional view of the lens unit and the base taken along the arrows B-B and D-D in FIG. 33B.

FIG. 36A is a conceptual diagram of light emitting elements of a first example and a second example having a resonator structure.

FIG. 36B is a conceptual diagram of light emitting elements of the first example and the second example having a resonator structure.

FIG. 37A is a conceptual diagram of light emitting elements of a third example and a fourth example having a resonator structure.

FIG. 37B is a conceptual diagram of light emitting elements of the third example and the fourth example having a resonator structure.

FIG. 38A is a conceptual diagram of light emitting elements of a fifth example and a sixth example having a resonator structure.

FIG. 38B is a conceptual diagram of light emitting elements of the fifth example and the sixth example having a resonator structure.

FIG. 39A is a conceptual diagram of light emitting elements of a seventh example having a resonator structure.

FIG. 39B is a conceptual diagram of light emitting elements of an eighth example having a resonator structure.

FIG. 39C is a conceptual diagram of light emitting elements of the eighth example having a resonator structure.

FIG. 40 is a schematic and partial sectional view of a display device of Example 9.

FIG. 41A is a schematic view illustrating a positional relationship between a light emitting element and a reference point in the display device of Example 9.

FIG. 41B is a schematic view illustrating a positional relationship between a light emitting element and a reference point in the display device of Example 9.

FIG. 42A is a diagram schematically illustrating a positional relationship between a light emitting element and a reference point in Modification of the display device of Example 9.

FIG. 42B is a diagram schematically illustrating a positional relationship between a light emitting element and a reference point in Modification of the display device of Example 9.

FIG. 43A is a diagram schematically illustrating a change of D_{0-X} with respect to a change of D_{1-X} and a change of D_{0-Y} with respect to a change of D_{1-Y}.

FIG. 43B is a diagram schematically illustrating a change of D_{0-X} with respect to a change of D_{1-X} and a change of D_{0-Y} with respect to a change of D_{1-Y}.

FIG. 43C is a diagram schematically illustrating a change of D_{0-X} with respect to a change of D_{1-X} and a change of D_{0-Y} with respect to a change of D_{1-Y}.

FIG. 43D is a diagram schematically illustrating a change of D_{0-X} with respect to a change of D_{1-X} and a change of D_{0-Y} with respect to a change of D_{1-Y}.

FIG. 44A is a diagram schematically illustrating a change of D_{0-X} with respect to a change of D_{1-X} and a change of D_{0-Y} with respect to a change of D_{1-Y}.

FIG. 44B is a diagram schematically illustrating a change of D_{0-X} with respect to a change of D_{1-X} and a change of D_{0-Y} with respect to a change of D_{1-Y}.

FIG. 44C is a diagram schematically illustrating a change of D_{0-X} with respect to a change of D_{1-X} and a change of D_{0-Y} with respect to a change of D_{1-Y}.

FIG. 44D is a diagram schematically illustrating a change of D_{0-X} with respect to a change of D_{1-X} and a change of D_{0-Y} with respect to a change of D_{1-Y}.

FIG. 45A is a diagram schematically illustrating a change of D_{0-X} with respect to a change of D_{1-X} and a change of D_{0-Y} with respect to a change of D_{1-Y}.

FIG. 45B is a diagram schematically illustrating a change of D_{0-X} with respect to a change of D_{1-X} and a change of D_{0-Y} with respect to a change of D_{1-Y}.

FIG. 45C is a diagram schematically illustrating a change of D_{0-X} with respect to a change of D_{1-X} and a change of D_{0-Y} with respect to a change of D_{1-Y}.

FIG. 45D is a diagram schematically illustrating a change of D_{0-X} with respect to a change of D_{1-X} and a change of D_{0-Y} with respect to a change of D_{1-Y}.

FIG. 46A is a diagram schematically illustrating a change of D_{0-X} with respect to a change of D_{1-X} and a change of D_{0-Y} with respect to a change of D_{1-Y}.

FIG. 46B is a diagram schematically illustrating a change of D_{0-X} with respect to a change of D_{1-X} and a change of D_{0-Y} with respect to a change of D_{1-Y}.

FIG. 46C is a diagram schematically illustrating a change of D_{0-X} with respect to a change of D_{1-X} and a change of D_{0-Y} with respect to a change of D_{1-Y}.

FIG. 46D is a diagram schematically illustrating a change of D_{1-X} with respect to a change of D_{1-X} and a change of D_{0-Y} with respect to a change of D_{1-Y}.

FIG. 47A is a conceptual diagram illustrating a relationship between a normal line LN passing through the center of a light emitting unit, a normal line LN′ passing through the center of a lens unit, and a normal line LN″ passing through the center of a wavelength selection unit.

FIG. 47B is a conceptual diagram illustrating a relationship between the normal line LN passing through the center of the light emitting unit, the normal line LN′ passing through the center of the lens unit, and the normal line LN″ passing through the center of the wavelength selection unit.

FIG. 47C is a conceptual diagram illustrating a relationship between the normal line LN passing through the center of the light emitting unit, the normal line LN′ passing through the center of the lens unit, and the normal line LN″ passing through the center of the wavelength selection unit.

FIG. 48 is a conceptual diagram illustrating a relationship between the normal line LN passing through the center of the light emitting unit, the normal line LN′ passing through the center of the lens unit, and the normal line LN″ passing through the center of the wavelength selection unit.

FIG. 49A is a conceptual diagram illustrating a relationship between the normal line LN passing through the center of the light emitting unit, the normal line LN′ passing through the center of the lens unit, and the normal line LN″ passing through the center of the wavelength selection unit.

FIG. 49B is a conceptual diagram illustrating a relationship between the normal line LN passing through the center of the light emitting unit, the normal line LN′ passing through the center of the lens unit, and the normal line LN″ passing through the center of the wavelength selection unit.

FIG. 50 is a conceptual diagram illustrating a relationship between the normal line LN passing through the center of the light emitting unit, the normal line LN′ passing through the center of the lens unit, and the normal line LN″ passing through the center of the wavelength selection unit.

FIG. 51A is a schematic plan view and a schematic perspective view of a lens unit having a truncated quadrangular pyramid shape.

FIG. 51B is a schematic plan view and a schematic perspective view of a lens unit having a truncated quadrangular pyramid shape.

FIG. 52A is a schematic and partial sectional view of a base and the like for explaining a method for producing the display device of Example 1.

FIG. 52B is a schematic and partial sectional view of a base and the like for explaining a method for producing the display device of Example 1.

FIG. 52C is a schematic and partial sectional view of a base and the like for explaining a method for producing the display device of Example 1.

FIG. 52D is a schematic and partial sectional view of a base and the like for explaining a method for producing the display device of Example 1.

FIG. 53A is a schematic and partial sectional view of a base and the like for explaining a method for producing the display device of Example 1.

FIG. 53B is a schematic and partial sectional view of a base and the like for explaining a method for producing the display device of Example 1.

FIG. 53C is a schematic and partial sectional view of a base and the like for explaining a method for producing the display device of Example 1.

FIG. 54A is a diagram schematically illustrating an arrangement of light emitting elements in the display device of Example 1.

FIG. 54B is a diagram schematically illustrating an arrangement of light emitting elements in the display device of Example 1.

FIG. 54C is a diagram schematically illustrating an arrangement of light emitting elements in the display device of Example 1.

FIG. 54D is a diagram schematically illustrating an arrangement of light emitting elements in the display device of Example 1.

FIG. 55A is a front view of a digital still camera illustrating an example in which the display device of the present disclosure is applied to a mirrorless interchangeable lens digital still camera.

FIG. 55B is a back view of the digital still camera illustrating the example in which the display device of the present disclosure is applied to a mirrorless interchangeable lens digital still camera.

FIG. 56A is a diagram illustrating a state in which the luminance of a light emitting element decreases with time and a diagram illustrating a state in which the luminance of the light emitting element decreases depending on the viewing angle.

FIG. 56B is a diagram illustrating a state in which the luminance of a light emitting element decreases with time and a diagram illustrating a state in which the luminance of the light emitting element decreases depending on the viewing angle.

FIG. 57 is a schematic view for explaining that the light amount of light incident on a lens unit increases as the distance from a light emitting unit to a light exit surface of the lens unit increases.

### DESCRIPTION OF EMBODIMENTS

Hereinafter, the present disclosure will be described based on Examples with reference to the drawings. The present disclosure is not limited to Examples, and various numerical values and materials in Examples are examples. The description will be given in the following order.

1. General description of display devices according to first and second aspects of the present disclosure

2. Example 1 (display device according to first aspect of present disclosure)

3. Example 2 (modification of Example 1)

4. Example 3 (modification of Examples 1 and 2)

5. Example 4 (modification of Examples 1 to 3)

6. Example 5 (modification of Examples 1 to 4)

7. Example 6 (modification of Examples 1 to 5)

8. Example 7 (display device according to second aspect of present disclosure)

9. Example 8 (modification of Examples 1 to 7)

10. Example 9 (modification of Examples 1 to 8)

11. Others

<General Description of Display Devices According to First and Second Aspects of the Present Disclosure>

In a display device according to a first aspect of the present disclosure,

(TL₃+TB₃)≤(TL₂+TB₂)<(TL₁+TB₁)

is satisfied.

When (TL₃+TB₃)<(TL₂+TB₂) is satisfied,

specifically,

1.05≤(TL₂+TB₂)/(TL₃+TB₃)

is preferably satisfied, and

desirably,

1.05≤(TL₂+TB₂)/(TL₃+TB₃)≤2.5

is preferably satisfied. Specifically,

1.05≤(TL₁+TB₁)/(TL₂+TB₂)

1.1≤(TL₁+TB₁)/(TL₃+TB₃)

are preferably satisfied, and

desirably,

1.05≤(TL₁+TB₁)/(TL₂+TB₂)≤2.5

1.1≤(TL₁+TB₁)/(TL₃+TB₃)≤3.0

are preferably satisfied. However, the present invention is not limited to the above ranges.

In a display device according to a second aspect of the present disclosure,

TB₂<(TL₁+TB₁)

is satisfied.

Specifically,

1.1≤(TL₁+TB₁)/TB₂≤10

is preferably satisfied, and

desirably,

1.5≤(TL₁+TB₁)/TB₂≤3

is preferably satisfied. However, the present invention is not limited to the above ranges.

The display device according to the first aspect of the present disclosure may take a mode in which the bases have no side surface being in contact with a side surface of an adjacent base in each light emitting element unit. By having such a mode, it is possible to obtain a state in which a base has a side surface being in contact with a material having a refractive index n_{M} lower than the refractive index n₃ of a base constituent material, it is possible to impart a kind of lens effect or waveguide effect to the base, and it is possible to further improve the light collection effect of the lens unit. The shortest distance between side surfaces of adjacent bases may be 0.4 μm or more and 1.2 μm or less, preferably 0.6 μm or more and 1.2 μm or less, more preferably 0.8 μm or more and 1.2 μm or less, still more preferably 0.8 μm or more and 1.0 μm or less, but is not limited thereto. By defining the minimum value of the shortest distance between side surfaces of adjacent bases to be 0.4 μm, the shortest distance between the adjacent bases can be set to be about the same as the lower limit value of the wavelength band of visible light, so that it is possible to inhibit the functional degradation of the material or layer surrounding the bases, and as a result, it is possible to effectively enhance the light collection effect in the vicinity of the side surfaces of the bases. On the other hand, by defining the maximum value of the shortest distance between the side surfaces of the adjacent bases as 1.2 μm, the size of the base can be reduced, and as a result, the light collection effect in the vicinity of the side surfaces of the bases can be effectively enhanced.

In each light emitting element unit, a side surface of a base may be in contact with a side surface of an adjacent base. Such a mode can simplify the production process of the display device. In such a mode, a part of the side surfaces of some bases does not have to be in contact with a side surface of an adjacent base.

In the display device according to the first aspect of the present disclosure including the preferable mode described above, in each light emitting element unit, the light emitting unit may include a first electrode, an organic layer (including a light emitting layer), and a second electrode.

Further, in the display device according to the first aspect of the present disclosure including the preferable mode described above, a mode may be taken in which

a first light emitting unit includes a first wavelength selection unit on the light emission side,

a second light emitting unit includes a second wavelength selection unit on the light emission side, and

a third light emitting unit includes a third wavelength selection unit on the light emission side.

The wavelength selection unit may be formed of, for example, a color filter layer, and the color filter layer is formed of a resin to which a colorant including a desired pigment or dye is added. By selecting the pigment or dye, the light transmittance in a target wavelength region of red, green, blue, or the like is adjusted to be high and the light transmittance in other wavelength regions is adjusted to be low. The wavelength selection unit may also be formed of a wavelength selection element to which photonic crystal or plasmon is applied (a color filter layer having a conductor lattice structure in which a lattice-shaped hole structure is provided in a conductor thin film. For example, see JP 2008-177191 A), a thin film made of an inorganic material such as amorphous silicon, or a quantum dot. Hereinafter, the color filter layer may be described as a representative of the wavelength selection unit, but the wavelength selection unit is not limited to the color filter layer.

Forming a light absorption layer (black matrix layer) between the wavelength selection units of adjacent light emitting elements can reliably inhibit occurrence of color mixture between the adjacent light emitting elements. The size of the wavelength selection unit (for example, a color filter layer) may be appropriately changed according to light emitted from the light emitting element, or when the light absorption layer (black matrix layer) is provided between the wavelength selection units (for example, color filter layers) of adjacent light emitting elements, the size of the light absorption layer (black matrix layer) may be appropriately changed according to light emitted from the light emitting elements.

The display device according to the first or second aspect of the present disclosure includes, for example,

a first substrate and a second substrate;

a light emitting unit provided above the first substrate;

a base provided on the light emitting unit,

a lens unit provided on the base; and

a sealing resin layer provided between the lens unit and the second substrate.

Here, when the light emitting unit includes a wavelength selection unit, the base is provided on the light emitting unit, specifically, on the wavelength selection unit. However, the present invention is not limited to such a mode, and the wavelength selection unit may be provided between the second substrate and the sealing resin layer, or the wavelength selection unit may be provided between the sealing resin layers. The arrangement state of the wavelength selection unit described above may be applied to the display device according to the second aspect of the present disclosure.

In the display device according to the first aspect of the present disclosure including the preferable mode described above, in each light emitting element unit, the thickness of the light emitting unit may be the same in the first light emitting unit, the second light emitting unit, and the third light emitting unit, or the thickness of the light emitting unit may be different in the first light emitting unit, the second light emitting unit, and the third light emitting unit. Specifically, when the thickness of the first light emitting unit is t₁, the thickness of the second light emitting unit is t₂, and the thickness of the third light emitting unit is ta, there are

[a] a case where t₁=t₂, t₁=t₃, and t₂=t₃ are satisfied,

[b] a case where t₁≠t₂, t₁≠t₃, and t₂≠t₃ are satisfied,

[c] a case where t₁≠t₂, t₁=t₃, and t₂≠t₃ are satisfied,

[d] a case where t₁≠t₂, t₁≠t₃, and t₂=t₃ are satisfied,

[e] a case where t₁=t₂, t₁≠t₃, and t₂≠t₃ are satisfied,

[f] a case where t₁≠t₂, t₁=t₃, and t₂=t₃ are satisfied,

[g] a case where t₁=t₂, t₁≠t₃, and t₂=t₃ are satisfied, and

[h] a case where t₁=t₂, t₁=t₃, and t₂≠t₃ are satisfied.

In the display device according to the first aspect of the present disclosure including the preferable mode described above, in each light emitting element unit, the lens unit may be convex in a direction away from the light emitting unit. In this case, light emitted from the light emitting unit passes through the base and the lens unit, then further passes through the sealing resin layer and the second substrate to be emitted to the outside. It is desirable to lower the refractive index value in the order of the refractive index of the material constituting the base, the refractive index of the material constituting the lens unit, the refractive index of the material constituting the sealing resin layer, and the refractive index of the material constituting the second substrate. In some cases, the refractive index of the material constituting the base and the refractive index of the material constituting the lens unit may have the same value. That is,

n_{B-1}≥n_{L-1}

n_{B-2}≥n_{L-2}

n_{B-3}≥n_{L-3}

may be satisfied where

n_{B-1} is a refractive index of a first base constituent material constituting a first base,

n_{B-2} is a refractive index of a second base constituent material constituting a second base,

n_{B-3} is a refractive index of a third base constituent material constituting a third base,

n_{L-1} is a refractive index of a first lens unit constituent material constituting a first lens unit,

n_{L-2} is a refractive index of a second lens unit constituent material constituting a second lens unit, and

n_{L-3} is a refractive index of a third lens unit constituent material constituting a third lens unit. That is,

n_{B-1}=n_{L-1} (1-1)

n_{B-2}=n_{L-2} (1-2)

n_{B-3}=n_{L-3} (1-3)

may be satisfied,

or

n_{B-1}>n_{L-1} (2-1)

n_{B-2}>n_{L-2} (2-2)

n_{B-3}>n_{L-3} (2-3)

may be satisfied. There are

[A] a case where Formulas (1-1), (1-2), and (1-3) are satisfied, and

[B] a case where Formulas (2-1), (2-2), and (2-3) are satisfied,

and in some cases, there are

[C] a case where Formulas (1-1), (2-2), and (2-3) are satisfied,

[D] a case where Formulas (1-2), (2-1), and (2-3) are satisfied,

[E] a case where Formulas (1-3), (2-1), and (2-2) are satisfied,

[F] a case where Formulas (1-1), (1-2), and (2-3) are satisfied,

[G] a case where Formulas (1-1), (1-3), and (2-2) are satisfied, and

[H] a case where Formulas (1-2), (1-3), and (2-1) are satisfied.

To satisfy Formula (1-1), Formula (1-2), or Formula (1-3), for example, the same material may be used as the lens unit constituent material and the base constituent material, but the present invention is not limited thereto, and different materials may be used. To satisfy Formula (2-1), Formula (2-2), or Formula (2-3), for example, the lens unit constituent material and the base constituent material may be different materials.

Although not limited, in Formula (2-1), Formula (2-2), or Formula (2-3),

0.01≤(n_{B-1}−n_{L-1})≤0.1

0.01≤(n_{B-2}−n_{L-2})≤0.1

0.01≤(n_{B-3}−n_{L-3})≤0.1

are preferably satisfied.

In each light emitting element unit, the lens unit may be concave in a direction away from the light emitting unit. In this case, light emitted from the light emitting unit passes through the sealing resin layer, the base, and the lens unit, then further passes through the second substrate to be emitted to the outside. It is desirable to increase the value of the refractive index in the order of the refractive index of the material constituting the sealing resin layer, the refractive index of the material constituting the base, the refractive index of the material constituting the lens unit, and the refractive index of the material constituting the second substrate. In some cases, the refractive index of the material constituting the base and the refractive index of the material constituting the lens unit may have the same value. That is,

n_{B-1}≤n_{L-1}

n_{B-2}≤n_{L-2}

n_{B-3}≤n_{L-3}

may be satisfied. That is,

n_{B-1}=n_{L-1} (3-1)

n_{B-2}=n_{L-2} (3-2)

n_{B-3}=n_{L-3} (3-3)

may be satisfied,

or

n_{B-1}<n_{L-1} (4-1)

n_{B-2}<n_{L-2} (4-2)

n_{B-3}<n_{L-3} (4-3)

may be satisfied. There are

[A′] a case where Formulas (4-1), (4-2), and (4-3) are satisfied,

and in some cases, there are

[B′] a case where Formulas (3-1), (4-2), and (4-3) are satisfied,

[C′] a case where Formulas (3-2), (4-1), and (4-3) are satisfied,

[D′] a case where Formulas (3-3), (4-1), and (4-2) are satisfied,

[E′] a case where Formulas (3-1), (3-2), and (4-3) are satisfied,

[F′] a case where Formulas (3-1), (3-3), and (4-2) are satisfied, and

[G′] a case where Formulas (3-2), (3-3), and (4-1) are satisfied.

To satisfy Formula (3-1), Formula (3-2), or Formula (3-3), for example, the same material may be used as the lens unit constituent material and the base constituent material, but the present invention is not limited thereto, and different materials may be used. To satisfy Formula (4-1), Formula (4-2), or Formula (4-3), for example, the lens unit constituent material and the base constituent material may be different materials.

Although not limited, in Formula (4-1), Formula (4-2), or Formula (4-3),

0.1≤(n_{L-1}−n_{B-1})≤0.7

0.1≤(n_{L-2}−n_{B-2})≤0.7

0.1≤(n_{L-3}−n_{B-3})≤0.7

are preferably satisfied.

In each light emitting element unit, a lens unit convex in a direction away from the light emitting unit and a lens unit concave in a direction away from the light emitting unit may be mixed. In this case, for the refractive indexes of the convex lens unit and the concave lens unit, it is sufficient that each lens unit satisfies the above-described various conditions.

In the display device according to the first aspect of the present disclosure, each light emitting element unit may have a mode in which

the first base has a stacked structure of a first L base, a first M base, and a first H base from the light emitting unit side,

the second base has a stacked structure of a second L base and a second H base from the light emitting unit side,

the first L base and the second L base are configured by an extension part of the third base, and

the first M base is configured by an extension part of the second H base. The display device according to the first aspect of the present disclosure in such a mode may be referred to as a “display device according to Aspect 1-A of the present disclosure” for convenience.

In the display device according to Aspect 1-A of the present disclosure,

n_{B-3}′>n_{B-2H}′>n_{B-1H}′

is preferably satisfied where

n_{B-1H}′ is the refractive index of a first H base constituent material constituting the first H base,

n_{B-2H}′ is the refractive index of a second H base constituent material constituting the second H base and the extension part of the second H base, and

n_{B-3}′ is the refractive index of a third base constituent material constituting the third base and the extension part of the third base. Although not limited,

0.02≤(n_{B-3}′−n_{B-2H}′)

0.02≤(n_{B-2}′−n_{B-1H}′)

0.02≤(n_{B-3}′−n_{B-1H}′)

are preferably satisfied, and

0.05≤(n_{B-3}′−n_{B-2H}′)≤0.2

0.05≤(n_{B-2}′−n_{B-1H}′)≤0.2

0.05≤(n_{B-3}′−n_{B-1H}′)≤0.2

are further preferably satisfied. In this manner, light emitted from the light emitting unit passes through the base, and in the base having a stacked structure, it is desirable to sequentially lower the refractive index of the material constituting each layer with increasing distance from the light emitting unit. In this case, in each light emitting element unit, the lens unit may be convex in a direction away from the light emitting unit.

Further, in the display device according to Aspect 1-A of the present disclosure, an orthographic projection image of the first lens unit of the first light emitting element and an orthographic projection image of the lens unit of a light emitting element adjacent to the first light emitting element may partially overlap each other. The orthographic projection image is, in principle, an orthographic projection image onto the light emitting unit.

The display device according to the second aspect of the present disclosure may have a mode in which

the light emitting element unit further includes a third light emitting element including a third light emitting unit that emits light of a third color, and

in each light emitting element unit,

a third base having a thickness TB₃ is provided above the third light emitting unit, and

TB₃≤TB₂<(TL₁+TB₁)

is satisfied. Here, although not limited, when TB₃<TB₂ is satisfied, specifically,

1.05≤TB₂/TB₃

is desirably satisfied, and

preferably,

1.1≤TB₂/TB₃≤5

is desirably satisfied. In addition, specifically,

1.1≤(TL₁+TB₁)/TB₂ is desirably satisfied, and

preferably,

1.5≤(TL₁+TB₁)/TB₂≤3

is desirably satisfied.

The display device according to the second aspect of the present disclosure may also have a mode in which a second lens unit having a thickness TL₂ is provided on the second base, and

(TL₂+TB₂)<(TL₁+TB₁)

is satisfied. Here, although not limited,

specifically,

1.1≤(TL₁+TB₁)/(TL₂+TB₂)

is desirably satisfied, and

preferably,

1.5≤(TL₁+TB₁)/(TL₂+TB₂)≤3

is desirably satisfied. This case may have a mode in which

the light emitting element unit further includes a third light emitting element including a third light emitting unit that emits light of a third color, and

in each light emitting element unit,

a third base having a thickness TB₃ is provided above the third light emitting unit, and

TB₃≤TB₂<(TL₁+TB₁)

is satisfied. Here, although not limited, when TB₃<TB₂ is satisfied, specifically,

1.05≤TB₂/TB₃

is desirably satisfied, and

preferably,

1.1≤TB₂/TB₃≤5

is desirably satisfied. In addition, specifically,

1.1≤(TL₁+TB₁)/TB₂ is desirably satisfied, and

preferably,

1.5≤(TL₁+TB₁)/TB₂≤3

is desirably satisfied.

In the display device according to the second aspect of the present disclosure including the various preferable modes described above, the top surface of the second base and the top surface of the third base when the second lens unit is not provided may be flat, convex upwardly, or concave.

In the display devices according to the first and second aspect of the present disclosure including the various preferable modes described above (hereinafter, these display devices may be collectively referred to as “display device or the like of the present disclosure” for convenience),

TL₁, TL₂, and TL₃ may be the same value or different values as long as a requirement

(TL₃+TB₃)≤(TL₂+TB₂)<(TL₁+TB₁)

[excluding a case where the value of TB₃, the value of TB₂, and the value of TB₁ are the same]

is satisfied. TB₁, TB₂, and TB₃ may have the same value or different values. Specifically,

[Case 1-1] TL₁=TL₂, TL₁=TL₃, TL₂=TL₃

[Case 1-2] TL₁=TL₂, TL₁=TL₃, TL₂≠TL₃

[Case 1-3] TL₁=TL₂, TL₁≠TL₃, TL₂=TL₃

[Case 1-4] TL₁≠TL₂, TL₁=TL₃, TL₂=TL₃

[Case 1-5] TL₁≠TL₂, TL₁≠TL₃, TL₂=TL₃

[Case 1-6] TL₁≠TL₂, TL₁=TL₃, TL₂≠TL₃

[Case 1-7] TL₁=TL₂, TL₁≠TL₃, TL₂≠TL₃

[Case 1-8] TL₁≠TL₂, TL₁≠TL₃, TL₂≠TL₃

[Case 2-1] TB₁=TB₂, TB₁=TB₃, TB₂≠TB;

[Case 2-2] TB₁=TB₂, TB₁≠TB₃, TB₂=TB;

[Case 2-3] TB₁≠TB₂, TB₁=TB₃, TB₂=TB;

[Case 2-4] TB₁≠TB₂, TB₁≠TB₃, TB₂=TB;

[Case 2-5] TB₁≠TB₂, TB₁=TB₃, TB₂≠TB;

[Case 2-6] TB₁=TB₂, TB₁≠TB₃, TB₂≠TB;

[Case 2-7] TB₁≠TB₂, TB₁≠TB₃, TB₂≠TB;

are assumed, and as combinations of [Case 1] and [Case 2], there may be 8×7=56 combinations. Which case is selected may be appropriately determined according to the specifications required for the display device. From the viewpoint of simplification of the production process, it is preferable to adopt [Case 1-1], but the present invention is not limited to [Case 1-1].

In the display device or the like of the present disclosure, the light emitting unit may include an organic electroluminescence layer. That is, the display device or the like of the present disclosure may be composed of an organic electroluminescence display device (organic EL display device). Here, the display device or the like of the present disclosure is a top emission type display device that emits light from the second substrate.

Light (image) emitted from the entire display device is of a focusing system, but the degree of the focusing system depends on the specifications of the display device, and also depends on the degree of viewing angle dependency and wide viewing angle characteristic required for the display device.

In the display device or the like of the present disclosure including the various preferable modes described above, the lens unit may be formed in a hemispherical shape or a part of a sphere, or may be formed in a shape suitable for functioning as a lens in a broad sense. Specifically, the lens unit may be composed of a convex lens unit (on-chip micro-convex lens) or a concave lens unit (on-chip micro-concave lens). The lens unit may be a spherical lens or an aspherical lens. The convex lens unit may be formed of a plano-convex lens, and the concave lens unit may be formed of a plano-concave lens. The lens unit may be a refractive lens or a diffractive lens.

The lens unit may be a rounded three-dimensional shape as a whole, in which a rectangular parallelepiped having a square or rectangular bottom surface is assumed, four side surfaces and one top surface of the rectangular parallelepiped have a convex shape, a ridge part where the side surfaces intersect each other is rounded, and a ridge part where the top surface and a side surface intersect each other is also rounded. The lens unit may be assumed to be a rectangular parallelepiped (including a cube approximating a rectangular parallelepiped) having a square or rectangular bottom surface, in which the four side surfaces and one top surface of the rectangular parallelepiped have a planar shape. In this case, a ridge part where the side surfaces intersect each other may be rounded in some case, and a ridge part where the top surface and a side surface intersect each other may also be rounded in some cases. The lens unit may also include a lens unit having a rectangular or isosceles trapezoidal sectional shape cut along a virtual plane (vertical virtual plane) including its thickness direction. In other words, the sectional shape of the lens unit may be constant or may be changed along the thickness direction.

The lens unit (on-chip microlens) may be made of, for example, a transparent resin material such as an acrylic resin, an epoxy resin, a polycarbonate resin, or a polyimide resin, or a transparent inorganic material such as SiO₂, but the lens unit is not limited to these materials. The base may also be made of, for example, a transparent resin material such as an acrylic resin, an epoxy resin, a polycarbonate resin, or a polyimide resin, or a transparent inorganic material such as SiO₂, but the base is not limited to these materials.

The lens unit may be obtained by melt-flowing or etching back a transparent resin material to constitute the lens unit, by a combination of a photolithography technique using a gray tone mask or a halftone mask and an etching method, or by a method of forming a transparent resin material into a lens shape based on a nanoimprint method. Examples of the material constituting the lens unit (microlens) include a high refractive resin material (for a convex lens), a high refractive inorganic material (for a convex lens), a low refractive resin material (for a concave lens), and a low refractive inorganic material (for a concave lens).

The distance between the axes passing through the centers of adjacent lens units is preferably 1 μm or more and 10 μm or less. The center of the lens unit refers to an area centroid point of an assumed planar shape of the lens unit.

As described above, the light emitting unit includes the first electrode, the organic layer (including the light emitting layer), and the second electrode from the first substrate side. The first electrode may be in contact with a part of the organic layer, or the organic layer may be in contact with a part of the first electrode. Specifically, the size of the first electrode may be smaller than the organic layer, or the size of the first electrode may be the same as the organic layer, and an insulating layer may be formed in a part between the first electrode and the organic layer, or the size of the first electrode may be larger than the organic layer. The size of the organic layer is the size of a region (light emission region) where the first electrode and the organic layer are in contact with each other. The size of the light emission region may be changed according to the color of light to be emitted from the light emitting element.

Specifically, examples of the three-dimensional shape of the base include a cylindrical shape, an elliptical columnar shape, an oval columnar shape, a prismatic shape (including a quadrangular prism, a hexagonal prism, an octagonal prism, and a prism with rounded ridges), a truncated conical shape, and a truncated pyramidal shape (including a truncated pyramidal shape with rounded ridges). The prism shape and the truncated pyramid shape include a regular prism shape and a regular truncated pyramid shape. The ridge part where a side surface of the base intersects the top surface may be rounded. The bottom surface of the truncated pyramid may be located on the first substrate side or on the second electrode side. Specific examples of the planar shape of the base include a circle, an ellipse, and an oval, and a polygon including a triangle, a quadrangle, a hexagon, and an octagon. The polygon includes a regular polygon (including a regular polygon such as a rectangle or a regular hexagon (honeycomb shape)).

The sectional shape of the side surfaces of the base in the thickness direction may be linear, convexly curved, or concavely curved. That is, the side surfaces of the prism or the truncated pyramid may be flat, convexly curved, or concavely curved.

As described above, when the base has no side surface being in contact with a side surface of an adjacent base, the side surfaces of the base is in contact with a material having a refractive index n_{M} lower than the refractive index n₃ of the base constituent material, it is possible to impart a kind of lens effect or waveguide effect to the base, and it is possible to further improve the light collection effect of the lens unit. In geometrical optics, when a light beam is incident on a side surface of the base, the incident angle and the reflection angle become equal, and therefor it is difficult to improve the extraction of light in the front direction. However, in wave motion analysis (FDTD), the light extraction efficiency in the vicinity of a side surface of the base improves, and as a result, the light extraction efficiency in the vicinity of the outer edge of the lens unit corresponding to the side surface of the base improves. Thus, light in the vicinity of the outer edge of the light emitting element can be effectively collected, and as a result, the light extraction efficiency in the front direction of the entire light emitting element can be improved. This can achieve high light emission efficiency of the display device. That is, it is possible to realize high luminance and low power consumption of the display device.

The side surfaces of each base are preferably vertical or substantially vertical. Specifically, examples of the inclination angle of the side surfaces of the base may include 80 degrees to 100 degrees, preferably 81.8 degrees or more and 98.2 degrees or less, more preferably 84.0 degrees or more and 96.0 degrees or less, still more preferably 86.0 degrees or more and 94.0 degrees or less, particularly preferably 88.0 degrees or more and 92.0 degrees or less, and most preferably 90 degrees.

Further, in the display device or the like of the present disclosure including the various preferable modes described above, the planar shape of the lens unit is preferably similar to the light emission region. The light emission region is preferably included in an orthographic projection image of the lens unit (orthographic projection image with respect to the light emitting unit). However, the present invention is not limited to this configuration, and the orthographic projection image of the lens unit with respect to the light emitting unit may match up with an orthographic projection image of the wavelength selection unit with respect to the light emitting unit, or may be included in an orthographic projection image of the wavelength selection unit with respect to the light emitting unit. By adopting the latter configuration, the occurrence of color mixing between adjacent light emitting elements can be reliably inhibited.

The size of the planar shape of the lens unit may be changed depending on the light emitting element. For example, when one pixel is composed of three subpixels, the size of the planar shape of the lens unit may have the same value in the three subpixels constituting one pixel, may have the same value in two subpixels except for one subpixel, or may have different values in the three subpixels. The refractive index of the material constituting the lens unit may also be changed depending on the light emitting element. For example, when one pixel is composed of three subpixels, the refractive index of the material constituting the lens unit may have the same value in the three subpixels constituting one pixel, may have the same value in two subpixels except for one subpixel, or may have different values in the three subpixels.

When one pixel is composed of a plurality of subpixels, one lens unit may be provided corresponding to one subpixel, or a plurality of lens units may be provided corresponding to one subpixel.

Further, in these cases, in the light emitting element in which the value of the distance D₀ [a distance (offset amount) between the normal line passing through the center of the light emitting unit and the normal line passing through the center of the lens unit as described later] is not 0, the normal line passing through the center of the wavelength selection unit may match up with the normal line passing through the center of the light emitting unit, or in the light emitting element in which the value of the distance D₀ is not 0, the normal line passing through the center of the wavelength selection unit may match up with the normal line passing through the center of the lens unit. By adopting the latter configuration, the occurrence of color mixing between adjacent light emitting elements can be reliably inhibited.

The center of the wavelength selection unit refers to an area centroid point of a region occupied by the wavelength selection unit. When the planar shape of the wavelength selection unit is a circle, an ellipse, a square, a rectangle, or a regular polygon, the center of these figures corresponds to the center of the wavelength selection unit. When a part of these figures is a cutout figure, the center of a figure complementing the cutout portion corresponds to the center of the wavelength selection unit. When these figures are connected, the connection part is removed, and the center of a figure complementing the removed part corresponds to the center of the wavelength selection unit.

A light absorption layer (black matrix layer) may be formed between the wavelength selection units of adjacent light emitting elements.

The size of the wavelength selection unit (for example, a color filter layer) may be appropriately changed according to the distance (offset amount) d₀ between the normal line passing through the center of the light emitting unit and the normal line passing through the center of the color filter layer. The planar shape of the wavelength selection unit (for example, a color filter layer) may be the same as, similar to, or different from the planar shape of the lens unit.

The light absorption layer (black matrix layer) formed between the wavelength selection units of adjacent light emitting elements and the light absorption layer (black matrix layer) formed between the wavelength selection units of adjacent light emitting elements include, for example, a black resin film (specifically, for example, a black polyimide-based resin) mixed with a black colorant and having an optical density of 1 or more, or include a thin film filter using interference of thin films. The thin film filter is formed by, for example, stacking two or more thin films made of metal, metal nitride, or metal oxide, and it attenuates light using interference of the thin films. Specific examples of the thin film filter include a thin film filter in which Cr and chromium (III) oxide (Cr₂O₃) are alternately stacked.

In each light emitting element, when the distance (offset amount) between the normal line LN passing through the center of the light emitting unit and the normal line LN′ passing through the center of the lens unit is D₀, at least a part of the light emitting elements constituting the display device may have a mode in which the value of the distance (offset amount) D₀ is not 0. In the display device, a reference point (reference region) P is assumed, and the distance D₀ may depend on the distance D₁ from the reference point (reference region) P to the normal line LN passing through the center of the light emitting unit. The reference point (reference region) may include a certain extent of spread. These various normal lines are perpendicular lines to the light exit surface of the display device. The center of the light emitting unit refers to an area centroid point of a region where the first electrode and the organic layer are in contact with each other. The distance D₀ may be changed in the subpixels constituting one pixel. That is, the distance D₀ may be changed in the plurality of light emitting elements constituting one pixel.

For example, when one pixel is composed of three subpixels, the value of D₀ may be the same value in the three subpixels constituting one pixel, may be the same value in two subpixels except one subpixel, or may be different values in the three subpixels.

Examples of the arrangement of the pixels (or subpixels) in the display device or the like of the present disclosure include a delta arrangement, a stripe arrangement, a diagonal arrangement, a rectangle arrangement, and a PenTile arrangement. The wavelength selection units may be in a delta arrangement, a stripe arrangement, a diagonal arrangement, a rectangle arrangement, or a PenTile arrangement in accordance with the arrangement of the pixels (or subpixels).

Hereinafter, focusing on the light emitting unit, a mode in which the light emitting unit constituting the light emitting element includes an organic electroluminescence layer, that is, a mode in which the display device of the present disclosure includes an organic electroluminescence display device (organic EL display device) will be described.

The organic EL display device includes

a first substrate, a second substrate, and

a plurality of light emitting elements located between the first substrate and the second substrate and arranged two-dimensionally,

wherein

each of the light emitting elements provided on the base formed on the first substrate includes at least:

a first electrode;

a second electrode; and

an organic layer (including a light emitting layer composed of an organic electroluminescence layer) sandwiched between the first electrode and the second electrode,

wherein light from the organic layer is emitted to the outside via the second substrate.

The organic layer may emit white light, and in this case, the organic layer may include at least two light emitting layers that emit different colors. Specifically, the organic layer may have a stacked structure in which three layers of a red light emitting layer that emits red light (wavelength: 620 nm to 750 nm), a green light emitting layer that emits green light (wavelength: 495 nm to 570 nm), and a blue light emitting layer that emits blue light (wavelength: 450 nm to 495 nm) are stacked, to emit white light as a whole. The organic layer may also have a structure in which two layers of a blue light emitting layer that emits blue light and a yellow light emitting layer that emits yellow light are stacked to emit white light as a whole. The organic layer may also have a structure in which two layers of a blue light emitting layer that emits blue light and an orange light emitting layer that emits orange light are stacked to emit white light as a whole. The organic layer may be shared by a plurality of light emitting elements, or may be individually provided in each light emitting element. Such an organic layer that emits white light and a red color filter layer (or an intermediate layer that functions as a red color filter layer) are combined to form a red light emitting element, the organic layer that emits white light and a green color filter layer (or an intermediate layer that functions as a green color filter layer) are combined to form a green light emitting element, and the organic layer that emits white light and a blue color filter layer (or an intermediate layer that functions as a blue color filter layer) are combined to form a blue light emitting element. One pixel is composed of a combination of subpixels, such as a combination of a red light emitting element, a green light emitting element, and a blue light emitting element. In some cases, one pixel may be composed of a red light emitting element, a green light emitting element, a blue light emitting element, and a light emitting element that emits white light (or a fourth color) (or a light emitting element that emits complementary color light). In the mode composed of at least two light emitting layers that emit different colors, there is a case in which the light emitting layers that emit different colors may be mixed but not clearly separated into the respective layers in practice.

The organic layer may also be composed of one light emitting layer. In this case, the light emitting element may be composed of, for example, a red light emitting element having an organic layer including a red light emitting layer, a green light emitting element having an organic layer including a green light emitting layer, or a blue light emitting element having an organic layer including a blue light emitting layer. In the case of a color display device, one pixel is composed of these three types of light emitting elements (subpixels). One pixel may also have a stacked structure of a red light emitting element having an organic layer including a red light emitting layer, a green light emitting element having an organic layer including a green light emitting layer, and a blue light emitting element having an organic layer including a blue light emitting layer. In principle, formation of a color filter layer is unnecessary, but a color filter layer may be provided for improving color purity.

A combination of a light emitting element in which the organic layer is composed of one light emitting layer and a light emitting element having the above-described organic layer that emits white light may also be used. Specifically, for example, one pixel may be composed of a blue light emitting element having an organic layer including a blue light emitting layer, a red light emitting element obtained by combining an organic layer that emits white light and a red color filter layer (or an intermediate layer that functions as a red color filter layer), and a green light emitting element obtained by combining an organic layer that emits white light and a green color filter layer (or an intermediate layer that functions as a green color filter layer).

The base body is formed on or above the first substrate. Examples of the material constituting the base body include insulating materials such as SiO₂, SiN, and SiON. The base body may be formed by a forming method suitable for the material constituting the base body. Specific examples of the method include known methods such as various CVD methods, various coating methods, various PVD methods including a sputtering method and a vacuum vapor deposition method, various printing methods such as a screen printing method, a plating method, an electrodeposition method, an immersion method, and a sol-gel method.

Although not limited, a light emitting element driving unit is provided under or below the base body. The light emitting element driving unit includes, for example, a transistor (specifically, for example, a MOSFET) formed on a silicon semiconductor substrate constituting the first substrate, and a thin film transistor (TFT) provided on various substrates constituting the first substrate. The transistor or the TFT constituting the light emitting element driving unit may be connected to the first electrode via a contact hole (contact plug) formed in the base body or the like. The light emitting element driving unit may have a known circuit configuration. The second electrode is connected to the light emitting element driving unit via a contact hole (contact plug) formed in the base body or the like at the outer periphery of the display device. The light emitting elements are formed on the first substrate side. The second electrode may be a common electrode in a plurality of light emitting elements. That is, the second electrode may be a so-called solid electrode.

The first substrate or the second substrate may be made of a silicon semiconductor substrate, a high strain point glass substrate, a soda glass (Na₂O·CaO·SiO₂) substrate, a borosilicate glass (Na₂O·B₂O₃·SiO₂) substrate, a forsterite (2MgO·SiO₂) substrate, a lead glass (Na₂O·PbO·SiO₂) substrate, various glass substrates having an insulating material layer formed on the surface thereof, a quartz substrate, a quartz substrate having an insulating material layer formed on the surface thereof, or an organic polymer (having a form of a polymer material such as a flexible plastic film, a plastic sheet, or a plastic substrate made of a polymer material) exemplified by polymethyl methacrylate (PMMA), polyvinyl alcohol (PVA), polyvinylphenol (PVP), polyethersulfone (PES), polyimide, polycarbonate, polyethylene terephthalate (PET), and polyethylene naphthalate (PEN). The materials constituting the first substrate and the second substrate may be the same or different. Since the display device of the present disclosure is a top emission type display device, the second substrate is required to be transparent to light from the light emitting element.

When the first electrode functions as an anode electrode, examples of the material constituting the first electrode include a metal having a high work function such as platinum (Pt), gold (Au), silver (Ag), chromium (Cr), tungsten (W), nickel (Ni), copper (Cu), iron (Fe), cobalt (Co), or tantalum (Ta), and an alloy (for example, an Ag—Pd—Cu alloy containing silver as a main component and containing 0.3 mass % to 1 mass % of palladium (Pd) and 0.3 mass % to 1 mass % of copper (Cu), an Al—Nd alloy, an Al—Cu alloy, or an Al—Cu—Ni alloy). Further, when a conductive material having a small work function value and a high light reflectance, such as aluminum (Al) and an alloy containing aluminum, is used, the conductive material may be used as an anode electrode by improving hole injection characteristics by providing an appropriate hole injection layer or the like. The thickness of the first electrode may be 0.1 μm to 1 μm, for example. When a light reflection layer to be described later is provided, examples of the material constituting the first electrode include various transparent conductive materials such as transparent conductive materials containing, as a base layer, indium oxide, indium-tin oxide (ITO, including Sn-doped In₂O₃, crystalline ITO, and amorphous ITO), indium-zinc oxide (IZO), indium-gallium oxide (IGO), indium-doped gallium-zinc oxide (IGZO, In—GaZnO₄), IFO (F-doped In₂O₃), ITiO (Ti-doped In₂O₃), InSn, InSnZnO, tin oxide (SnO₂), ATO (Sb-doped SnO₂), FTO (F-doped SnO₂), zinc oxide (ZnO), aluminum oxide-doped zinc oxide (AZO), gallium-doped zinc oxide (GZO), B-doped ZnO, AlMgZnO (aluminum oxide and magnesium oxide-doped zinc oxide), antimony oxide, titanium oxide, NiO, spinel-type oxide, oxide having a YbFe₂O₄ structure, gallium oxide, titanium oxide, niobium oxide, nickel oxide, or the like. The first electrode may also have a structure in which a transparent conductive material having excellent hole injection characteristics, such as an oxide of indium and tin (ITO) or an oxide of indium and zinc (IZO), is stacked on a dielectric multilayer film or a reflective film having high light reflectivity, such as aluminum (Al) or an alloy thereof (for example, Al—Cu—Ni alloy). When the first electrode functions as a cathode electrode, the first electrode is desirably composed of a conductive material having a small work function value and a high light reflectance. The first electrode may also be used as a cathode electrode by improving electron injection characteristics by providing an appropriate electron injection layer in a conductive material having a high light reflectance used as an anode electrode.

When the second electrode functions as a cathode electrode, the material (semi-light transmitting material or light transmitting material) constituting the second electrode is desirably composed of a conductive material having a small work function value so as to transmit emission light and to efficiently inject electrons into the light emitting layer. Examples thereof include a metal having a small work function, such as aluminum (Al), silver (Ag), magnesium (Mg), calcium (Ca), sodium (Na), strontium (Sr), and an alloy of an alkali metal or an alkaline earth metal and silver (Ag) such as magnesium (Mg) and silver (Ag) (Mg—Ag alloy), an alloy of magnesium-calcium (Mg—Ca alloy), or an alloy of aluminum (Al) and lithium (Li) (Al—Li alloy). Among them, a Mg—Ag alloy is preferable, and the volume ratio of magnesium and silver may be, for example, Mg:Ag=5:1 to 30:1. The volume ratio of magnesium and calcium may be, for example, Mg:Ca=2:1 to 10:1. The thickness of the second electrode may be, for example, 4 nm to 50 nm, preferably 4 nm to 20 nm, more preferably 6 nm to 12 nm. Examples of the second electrode also include at least one material selected from the group consisting of Ag—Nd—Cu, Ag—Cu, Au, and Al—Cu. The second electrode may also have a stacked structure of the above-described material layer and a so-called transparent electrode (for example, having a thickness of 3×10⁻⁸ m to 1×10⁻⁶ m) made of, for example, ITO or IZO from the organic layer side. A bus electrode (auxiliary electrode) made of a low-resistance material such as aluminum, an aluminum alloy, silver, a silver alloy, copper, a copper alloy, gold, or a gold alloy may be provided to the second electrode to reduce the resistance of the second electrode as a whole. The average light transmittance of the second electrode is desirably 50% to 90%, and preferably 60% to 90%. When the second electrode functions as an anode electrode, the second electrode is desirably composed of a conductive material that transmits emitted light and has a large work function value.

Examples of a method for forming the first electrode and the second electrode include: a vapor deposition method including an electron beam vapor deposition method, a hot filament vapor deposition method, and a vacuum vapor deposition method; a sputtering method; a chemical vapor deposition method (CVD method); an MOCVD method; and a combination of an ion plating method and an etching method; various printing methods such as a screen printing method, an inkjet printing method, and a metal mask printing method; a plating method (electroplating method or electroless plating method); a lift-off method; a laser ablation method; and a sol-gel method. According to various printing methods and plating methods, it is possible to directly form the first electrode and the second electrode having a desired shape (pattern). When the second electrode is formed after the organic layer is formed, it is particularly preferable to form the second electrode based on a film forming method in which the energy of film-forming particles is small such as a vacuum vapor deposition method or a film forming method such as an MOCVD method from the viewpoint of preventing occurrence of damage to the organic layer. When the organic layer is damaged, there is a possibility that a non-light emitting pixel (or a non-light emitting subpixel) called a “blinking point” occurs because of generation of a leakage current.

The organic layer includes a light emitting layer containing an organic light emitting material. Specifically, the organic layer may have, for example, a stacked structure of a hole transport layer, a light emitting layer, and an electron transport layer, a stacked structure of a hole transport layer and a light emitting layer also serving as an electron transport layer, and a stacked structure of a hole injection layer, a hole transport layer, a light emitting layer, an electron transport layer, and an electron injection layer. Examples of a method for forming the organic layer include: a physical vapor deposition method (PVD method) such as a vacuum vapor deposition method; a printing method such as a screen printing method or an inkjet printing method; a laser transfer method in which a stacked structure of a laser absorption layer and an organic layer formed on a transfer substrate is irradiated with a laser to separate the organic layer on the laser absorption layer and transfer the organic layer; and various coating methods. When the organic layer is formed based on a vacuum vapor deposition method, for example, the organic layer may be obtained by using a so-called metal mask and depositing a material that has passed through an opening provided in the metal mask.

A light shielding unit may be provided between a light emitting element and a light emitting element. Specific examples of the light shielding material constituting the light shielding unit include materials capable of shielding light, such as titanium (Ti), chromium (Cr), tungsten (W), tantalum (Ta), aluminum (Al), and MoSi₂. The light shielding unit may be formed by a vapor deposition method including an electron beam vapor deposition method, a hot filament vapor deposition method, and a vacuum vapor deposition method, a sputtering method, a CVD method, an ion plating method, or the like.

Examples of the material constituting the sealing resin layer include: thermosetting adhesives such as an acrylic adhesive, an epoxy-based adhesive, a urethane-based adhesive, a silicone-based adhesive, and a cyanoacrylate-based adhesive; and ultraviolet-curable adhesives.

An intermediate layer (also referred to as a protective layer) may be formed on the first substrate side of the sealing resin layer. In some cases, the intermediate layer may have a function as a color filter layer. Such an intermediate layer may be made of a known color resist material. In a light emitting element that emits white light, a transparent filter layer may be disposed.

Examples of the material constituting the intermediate layer (protective layer) include acrylic resins, epoxy resins, and various inorganic materials (SiN, SiON, SiO, Al₂O₃, TiO₂, etc.). The intermediate layer may be formed by a known method such as various CVD methods, various coating methods, various PVD methods including a sputtering method and a vacuum vapor deposition method, and various printing methods such as a screen printing method. The intermediate layer may be shared by a plurality of light emitting elements, or may be individually provided in each light emitting element.

On the outermost surface (specifically, for example, the outer surface of the second substrate) of the display device from which light is emitted, an ultraviolet absorbing layer, a contamination preventing layer, a hard coat layer, and an antistatic layer may be formed, or a protective member (for example, cover glass) may be disposed.

In the display device, an insulating layer and an interlayer insulating layer are formed. Examples of the insulating material constituting the insulating layer and the interlayer insulating layer include: SiO_{X}-based materials (materials constituting a silicon-based oxide film) such as SiO₂, non-doped silicate glass (NSG), boron-phosphorus silicate glass (BPSG), PSG, BSG, AsSG, SbSG, PbSG, spin-on glass (SOG), low temperature oxide (LTO), low temperature CVD-SiO₂, low-melting-point glass, and glass paste; SiN-based materials including SiON-based materials; SiOC; SiOF; and SiCN. Examples of the material also include inorganic insulating materials such as titanium oxide (TiO₂), tantalum oxide (Ta₂O₅), aluminum oxide (Al₂O₃), magnesium oxide (MgO), chromium oxide (CrOₓ), zirconium oxide (ZrO₂), niobium oxide (Nb₂O₅), tin oxide (SnO₂), and vanadium oxide (VO). Examples of the material also include various resins such as a polyimide-based resin, an epoxy-based resin, and an acryl-based resin, and low dielectric constant insulating materials such as SiOCH, organic SOG, and a fluorine-based resin (for example, a material having a dielectric constant k (=ε/ε₀) of, for example, 3.5 or less, and specific examples thereof include fluorocarbon, a cycloperfluorocarbon polymer, benzocyclobutene, a cyclic fluorine-based resin, polytetrafluoroethylene, amorphous tetrafluoroethylene, polyaryl ether, fluorinated aryl ether, fluorinated polyimide, amorphous carbon, parylene (polyparaxylylene), and fluorinated fullerene), Silk (coating-type low-dielectric-constant interlayer insulating film material, a trademark of The Dow Chemical Company), and Flare (polyallyl ether (PAE)-based material, a trademark of Honeywell Electronic Materials Co.). These materials may be used alone or in appropriate combination. In some cases, the base body may be made of the material described above. The insulating layer, the interlayer insulating layer, and the base body may be formed based on known methods such as various CVD methods, various coating methods, various PVD methods including a sputtering method and a vacuum vapor deposition method, various printing methods such as a screen printing method, a plating method, an electrodeposition method, an immersion method, and a sol-gel method.

In the organic EL display device, it is desirable that the thickness of the hole transport layer (hole supply layer) and the thickness of the electron transport layer (electron supply layer) are substantially equal. Alternatively, the electron transport layer (electron supply layer) may be thicker than the hole transport layer (hole supply layer), which makes it possible to sufficiently supply electrons necessary for high efficiency at a low drive voltage to the light emitting layer. That is, supply of holes can be increased by disposing the hole transport layer between the first electrode corresponding to the anode electrode and the light emitting layer and forming the hole transport layer with a film thickness thinner than the electron transport layer. As a result, it is possible to obtain a carrier balance in which there is no excess or deficiency of holes and electrons and the carrier supply amount is sufficiently large, resulting in a high luminous efficiency. In addition, since there is no excess or deficiency of holes and electrons, carrier balance is hardly lost, drive deterioration is inhibited, and a light emission lifetime can be extended.

The display device may be used as, for example, a monitor device constituting a personal computer, or may be used as a television receiver, a mobile phone, a personal digital assistant (PDA), a monitor device incorporated in a game device, or a display device incorporated in a projector. The display device may also be applied to an electronic view finder (EVF) or a head mounted display (HMD), or may be applied to a display device for virtual reality (VR), mixed reality (MR), or augmented reality (AR). It is also possible to configure an image display device in an electronic book, an electronic paper such as an electronic newspaper, a bulletin board such as a signboard, a poster, or a blackboard, a rewritable paper as a substitute for printer paper, a display unit of a home appliance, a card display unit such as a loyalty card, an electronic advertisement, or an electronic POP advertisement. Various lighting devices including a backlight device for a liquid crystal display device and a planar light source device can be configured by using the display device of the present disclosure as a light emitting device.

### Example 1

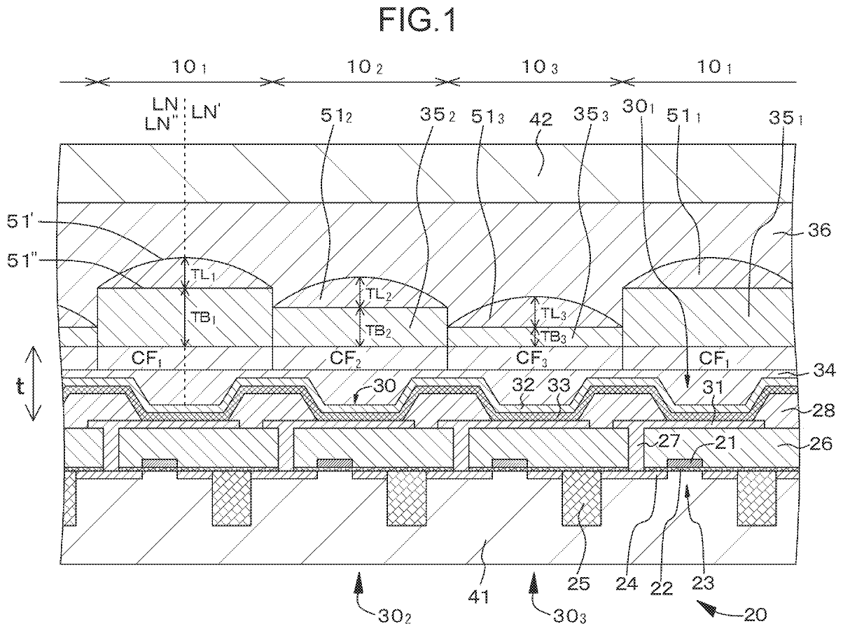

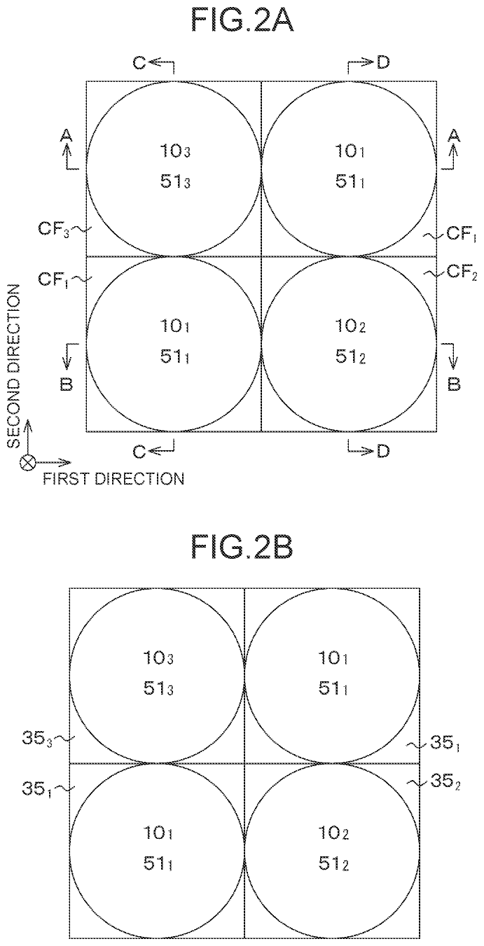

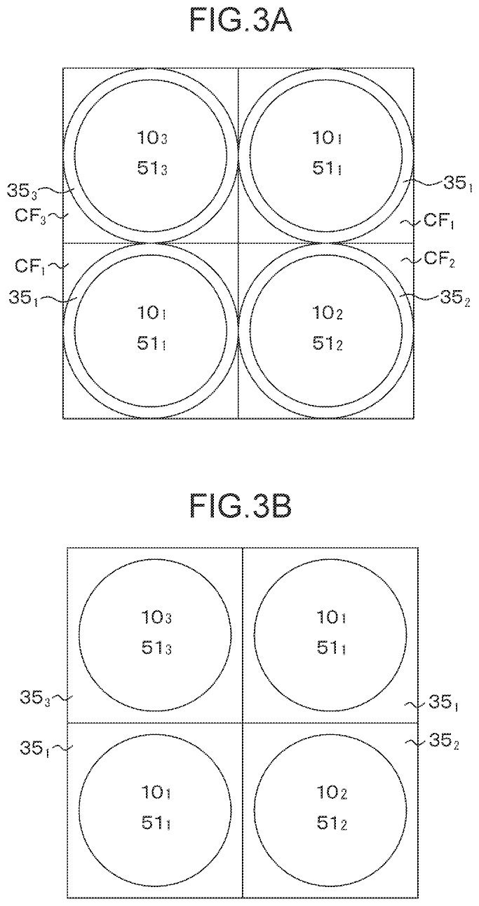

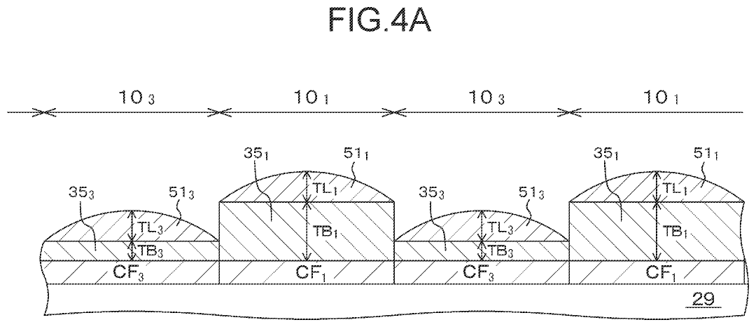

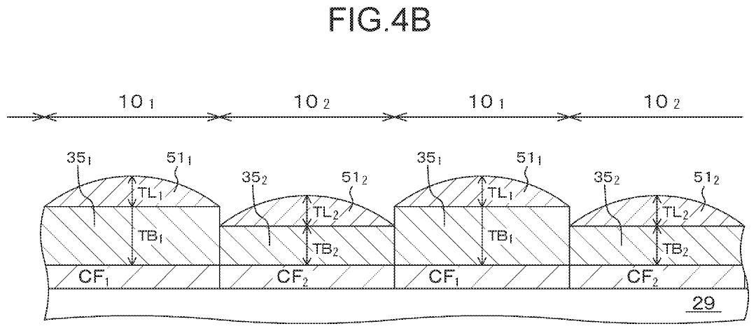

A display device of Example 1 is the display device according to the first aspect of the present disclosure. FIG. 1 is a schematic and partial sectional view of the display device of Example 1. FIGS. 2A, 2B, 3A, and 3B are schematic views of a lens unit and the like of one light emitting element unit in Example 1 as viewed from above. FIG. 4A is a schematic and partial sectional view of the lens unit and a base taken along the arrows A-A and C-C in FIG. 2A. FIG. 4B is a schematic and partial sectional view of the lens unit and the base taken along the arrows B-B and D-D in FIG. 2A. Various components of the display device located below the base body (interlayer insulating layer) 26 may be collectively denoted by reference numeral 29 for convenience to simplify the drawings.

The display device of Example 1 includes a plurality of light emitting element units (pixels) including a first light emitting element 10₁ having a first light emitting unit 30₁ that emits light of a first color, a second light emitting element 10₂ having a second light emitting unit 30₂ that emits light of a second color, and a third light emitting element 10₃ having a third light emitting unit 30₃ that emits light of a third color.

Here, except for Example 3, the first light emitting element 10₁ emits blue light, the second light emitting element 10₂ emits green light, and the third light emitting element 10₃ emits red light.

In each light emitting element unit (pixel),

a first base 35₁ having a thickness TB₁ is provided on the first light emitting unit 30₁ (including above the first light emitting unit 30₁, in the example illustrated in FIG. 1, directly above the first light emitting unit 30₁),

a second base 35₂ having a thickness TB₂ is provided on the second light emitting unit 30₂ (including above the second light emitting unit 30₂, in the example illustrated in FIG. 1, directly above the second light emitting unit 30₂), and

a third base 35₃ having a thickness TB₃ is provided on the third light emitting unit 30₃ (including above the third light emitting unit 30₃, in the example illustrated in FIG. 1, directly above the third light emitting unit 30₃).

A first lens unit 51 having a thickness TL₁ is provided on the first base 35₁,

a second lens unit 51₂ having a thickness TL₂ is provided on the second base 35₂, and

a third lens unit 51₃ having a thickness TL₃ is provided on the third base 35₃.

Then,

(TL₃+TB₃)≤(TL₂+TB₂)<(TL₁+TB₁)

is satisfied. However, a case where the value of TB₃, the value of TB₂, and the value of TB₁ are the same is excluded. In the example illustrated in FIG. 1,

(TL₃+TB₃)≤(TL₂+TB₂)<(TL₁+TB₁)

is satisfied. As described above, TL₁, TL₂, and TL₃ may be the same value or different values. TB₁, TB₂, and TB₃ may have the same value or different values.

Note that, in the technique disclosed in JP 2012-109213 A,

(TL₃+TB₃)≤(TL₂+TB₂)<(TL₁+TB₁) is satisfied,

where the value of TB₃, the value of TB₂, and the value of TB₁ are the same. Further, in the technique disclosed in JP 2012-089474 A,

(TL₃+TB₃)=(TL₂+TB₂)=(TL₁+TB₁)

is satisfied.

In each light emitting element unit, a side surface of the base 35 is in contact with a side surface of adjacent base 35.

In each light emitting element unit, the light emitting unit 30 (30₁, 30₂, 30₃) includes a first electrode 31, an organic layer (including a light emitting layer) 33, and a second electrode 32. That is, each light emitting element 10 (10₁, 10₂, 10₃) provided on the base body 26 formed on the first substrate 41 includes at least:

the first electrode 31;

the second electrode 32; and

the organic layer (including a light emitting layer formed of an organic electroluminescence layer) 33 sandwiched between the first electrode 31 and the second electrode 32, and

in Example 1, light from the organic layer 33 is emitted to the outside via the second substrate 42. Specifically, the plurality of light emitting elements 10₁, 10₂, 10₃ are arranged two-dimensionally (specifically, in a first direction and a second direction different from the first direction).

Further,

the first light emitting unit 30₁ includes a first wavelength selection unit CF₁ on the light emission side,

the second light emitting unit 30₂ includes a second wavelength selection unit CF₂ on the light emission side, and

the third light emitting unit 30₃ includes a third wavelength selection unit CF₃ on the light emission side.

The light emitting unit 30 is covered with an intermediate layer 34. Wavelength selection units (specifically, the first color filter layer CF₁ that selectively allows blue color to pass, the second color filter layer CF₂ that selectively allows green color to pass, and the third color filter layer CF₃ that selectively allows red color to pass) made of a known material are formed on the intermediate layer 34. The color filter layers CF₁, CF₂, CF₃ are on-chip color filter layers (OCCF) formed on the first substrate side. This configuration can shorten the distance between the organic layer 33 and the color filter layer CF, can inhibit light emitted from the organic layer 33 from entering an adjacent color filter layer CF of another color to cause color mixture, and can make a wide range of lens design of the lens unit 51.

In the example illustrated in FIG. 1, the thickness of the light emitting unit is the same in the first light emitting unit 30₁, the second light emitting unit 30₂, and the third light emitting unit 30₃ in each light emitting element unit. Here, the thicknesses being the same is a concept including variations in production of the first light emitting unit 30₁, the second light emitting unit 30₂, and the third light emitting unit 30₃. When the thickness of the first light emitting unit 30₁ is t₁, the thickness of the second light emitting unit 30₂ is t₂, and the thickness of the third light emitting unit 30₃ is t₃, t₁=t₂, t₁=t₃, t₂=t₃, or t₁≈t₂, t₁≈t₃, t₂≈t₃ are satisfied. In FIG. 1, the thickness of the light emitting unit 30 is represented by “t”.

In the light emitting element 10 of Example 1, a light exit surface (outer surface) 51′ of the lens units 51₁, 51₂, 51₃ is convex in a direction away from the light emitting unit 30₁, 30₂, 30₃. A light incident surface 51″ of the lens units 51₁, 51₂, 51₃ is in contact with the top surface of the base 35. The lens units 51₁, 51₂, 51₃ have positive optical power, or the lens units 51₁, 51₂, 51₃ are composed of a convex lens unit (on-chip micro-convex lenses), specifically, plano-convex lenses. The light exit surface (outer surface) 51′ constitutes a lens surface.

In the display device of Example 1,

n_{B-1}≥n_{L-1}

n_{B-2}≥n_{L-2}

n_{B-3}≥n_{L-3}

are satisfied where

n_{B-1} is a refractive index of a material constituting the first base 35₁ constituting the first base 35₁ (first base constituent material),

n_{B-2} is a refractive index of a material constituting the second base 35₂ constituting the second base 35₂ (second base constituent material),

n_{B-3} is a refractive index of a material constituting the third base 35₃ constituting the third base 35₃ (third base constituent material),

n_{L-1} is a refractive index of a material constituting the first lens unit 51₁ constituting the first lens unit 51₁ (first lens unit constituent material),

n_{L-2} is a refractive index of a material constituting the second lens unit 51₂ constituting the second lens unit 51₂ (second lens unit constituent material), and

n_{L-3} is a refractive index of a material constituting the third lens unit 51₃ constituting the third lens unit 51₃ (third lens unit constituent material). Specifically,

n_{B-1}>n_{L-1} (2-1)

n_{B-2}>n_{L-2} (2-2)

n_{B-3}>n_{L-3} (2-3)

are satisfied. This is “[B] a case where Formulas (2-1), (2-2), and (2-3) are satisfied” described above. Here, the material constituting the lens units 51₁, 51₂, 51₃ and the material constituting the base 35₁, 35₂, 35₃ are different materials. This configuration can expand the selection ranges of the material constituting the lens unit 51 and the material constituting the base 35. More specifically, an acrylic-based transparent resin is used as the material constituting the lens units 51₁, 51₂, 51₃, and an acrylic-based transparent resin having a different refractive index is used as the material constituting the bases 35₁, 35₂, 35₃. In this case, light emitted from the light emitting unit 30 passes through the base 35 and the lens unit 51, then further passes through the sealing resin layer 36 and the second substrate 42 to be emitted to the outside. The refractive index value is lowered in the order of the refractive index of the material constituting the base 35, the refractive index of the material constituting the lens unit 51, the refractive index of the material constituting the sealing resin layer 36, and the refractive index of the material constituting the second substrate 42.

In the example illustrated in FIGS. 1, 2A, and 2B, the top surfaces of the bases 35₁, 35₂, 35₃ are covered with the lens units 51₁, 51₂, 51₃, respectively. As illustrated in FIG. 3A, the lens units 51₁, 51₂, 51₃ cover a part of the top surface of the bases 35₁, 35₂, 35₃, respectively. As illustrated in FIGS. 2A and 3A, the planar shape of the bases 35₁, 35₂, 35₃ is the same circular shape as the planar shape of the lens units 51₁, 51₂, 51₃. In this case, the bases 35₁, 35₂, 35₃ are in contact with a part of the first wavelength selection unit CF₁, the second wavelength selection unit CF₂, and the third wavelength selection unit CF₃, respectively, and the rest of the first wavelength selection unit CF₁, the second wavelength selection unit CF₂, and the third wavelength selection unit CF₃ is in contact with the sealing resin layer 36. Alternatively, as illustrated in FIGS. 2B and 3B, the planar shape of the lens units 51₁, 51₂, 51₃ is circular, and the planar shape of the bases 35₁, 35₂, 35₃ is square. In this case, the bases 35₁, 35₂, 35₃ are in contact with the first wavelength selection unit CF₁, the second wavelength selection unit CF₂, and the third wavelength selection unit CF₃, respectively. In the example illustrated in FIG. 3B, the bases 35 are in contact with each other, but the lens units 51 are not in contact with each other. The sealing resin layer 36 is located above the paper surfaces of FIGS. 2A, 2B, 3A, and 3B.

In the light emitting element 10 (10₁, 10₂, 10₃) of Example 1 or Examples 2 to 9 described later, the light emitting unit 30 (30₁, 30₂, 30₃) includes an organic electroluminescence layer (light emitting layer) 33. That is, the display device is composed of an organic electroluminescence display device (organic EL display device), and the light emitting element is composed of an organic electroluminescence element (organic EL element). The display device is a top emission type display device that emits light from the second substrate 42. The light emitting unit 30 further includes the first electrode 31 and the second electrode 32.

That is, the display device of Example 1 or Examples 2 to 9 described later includes:

the first substrate 41 and the second substrate 42;

the bases 35₁, 35₂, 35₃ provided on the light emitting units 30₁, 30₂, 30₃;

the lens units 51₁, 51₂, 51₃ provided on the bases 35₁, 35₂, 35₃; and

the sealing resin layer 36 provided between the lens units 51₁, 51₂, 51₃ and the second substrate 42.

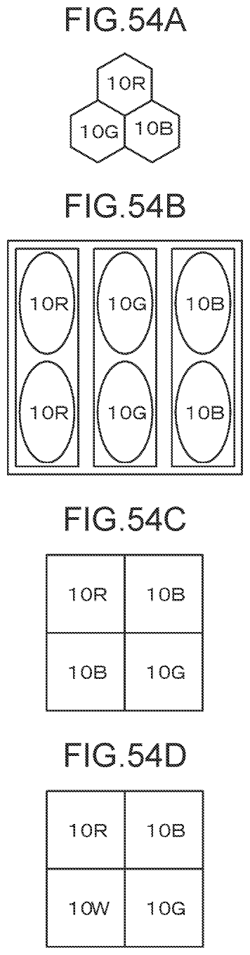

In the light emitting element 10 of Example 1 composed of an organic EL element, the organic layer 33 has a stacked structure of a red light emitting layer, a green light emitting layer, and a blue light emitting layer. One pixel is composed of three light emitting elements of the first light emitting element (blue light emitting element) 10₁, the second light emitting element (green light emitting element) 10₂, and the third light emitting element (red light emitting element) 10₃. The organic layer 33 constituting the light emitting element 10 emits white light, and the light emitting elements 10₁, 10₂, 10₃ are composed of a combination of the organic layer 33 emitting white light and the color filter layers CF₁, CF₂, CF₃. The first light emitting element (blue light emitting element) 10₁ to display blue color is provided with the first color filter layer (blue color filter layer) CF₁, the second light emitting element (green light emitting element) 10₂ to display green color is provided with the second color filter layer (green color filter layer) CF₂, and the third light emitting element (red light emitting element) 10₃ to display red color is provided with the third color filter layer (red color filter layer) CF₃. The first light emitting element 10₁, the second light emitting element 10₂, and the third light emitting element 10₃ have substantially the same configuration and structure except for the locations of the color filter layer CF and the light emitting layer in the organic layer 33. The number of pixels is, for example, 1920×1080, one light emitting element (display element) constitutes one subpixel, and the number of light emitting elements (specifically, organic EL elements) is three times the number of pixels. In the display device of Example 1, the arrangement of the subpixels may be a delta arrangement illustrated in FIG. 54A, a stripe arrangement as illustrated in FIG. 54B, a diagonal arrangement illustrated in FIG. 54C, or a rectangle arrangement. In some cases, as illustrated in FIG. 54D, one pixel may be composed of the first light emitting element 10₁, the second light emitting element 10₂, the third light emitting element 10₃, and a fourth light emitting element that emits white light (or the fourth light emitting element that emits complementary color light). In the fourth light emitting element that emits white light, a transparent filter layer may be provided instead of providing the color filter layer.

A light emitting element driving unit is provided below the base body (interlayer insulating layer) 26 made of SiO₂ that is formed based on a CVD method. The light emitting element driving unit may have a known circuit configuration. The light emitting element driving unit is composed of a transistor (specifically, a MOSFET) formed on a silicon semiconductor substrate corresponding to the first substrate 41. The transistor 20 composed of a MOSFET includes a gate insulating layer 22 formed on the first substrate 41, a gate electrode 21 formed on the gate insulating layer 22, a source/drain regions 24 formed on the first substrate 41, a channel formation region 23 formed between the source/drain regions 24, and an element isolation region 25 surrounding the channel formation region 23 and the source/drain region 24. The transistor 20 and the first electrode 31 are electrically connected via a contact plug 27 provided in the base body 26. In the drawings, one transistor 20 is illustrated for one light emitting element driving unit.

The second electrode 32 is connected to the light emitting element driving unit via a contact hole (contact plug) (not illustrated) formed in the base body (interlayer insulating layer) 26 at the outer periphery of the display device. In the outer periphery of the display device, an auxiliary electrode connected to the second electrode 32 may be provided below the second electrode 32, and the auxiliary electrode may be connected to the light emitting element driving unit.

The first electrode 31 functions as an anode electrode, and the second electrode 32 functions as a cathode electrode. The first electrode 31 is composed of a light reflecting material layer, specifically, for example, a stacked structure of an Al—Nd alloy layer, an Al—Cu alloy layer, an Al—Ti alloy layer, and an ITO layer. The second electrode 32 is composed of a transparent conductive material such as ITO. The first electrode 31 is formed on the base body (interlayer insulating layer) 26 based on a combination of a vacuum vapor deposition method and an etching method. The second electrode 32 is formed by a film forming method in which the energy of film-forming particles is small, such as a vacuum vapor deposition method, and is not patterned. The organic layer 33 is not patterned either. However, the present invention is not limited to this configuration, and the organic layer 33 may be patterned. That is, the organic layer 33 may be applied separately for each subpixel. The organic layer 33 of the blue light emitting element may be composed of an organic layer that emits blue light, the organic layer 33 of the green light emitting element may be composed of an organic layer that emits green light, and the organic layer 33 of the red light emitting element may be composed of an organic layer that emits red light.

In Example 1, the organic layer 33 has a stacked structure of a hole injection layer (HIL), a hole transport layer (HTL), a light emitting layer, an electron transport layer (ETL), and an electron injection layer (EIL). The light emitting layer includes at least two light emitting layers that emit different colors, and as described above, the organic layer 33 emits white light. Specifically, the organic layer has a structure in which three layers of a red light emitting layer that emits red light, a green light emitting layer that emits green light, and a blue light emitting layer that emits blue light are stacked. The organic layer may have a structure in which two layers of a blue light emitting layer that emits blue light and a yellow light emitting layer that emits yellow light are stacked, or a structure in which two layers of a blue light emitting layer that emits blue light and an orange light emitting layer that emits orange light are stacked.

The hole injection layer is a layer that improves hole injection efficiency and functions as a buffer layer that prevents leakage. The hole injection layer has a thickness of, for example, about 2 nm to 10 nm. The hole injection layer includes, for example, a hexaazatriphenylene derivative represented by the following Formula (A) or Formula (B). When an end surface of the hole injection layer contacts the second electrode, it becomes a main cause of occurrence of luminance variation between pixels, leading to deterioration of display image quality.

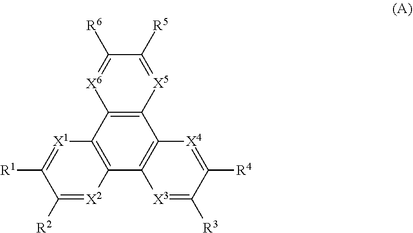

Here, R¹ to R⁶ are each independently a substituent selected from hydrogen, halogen, a hydroxy group, an amino group, an arylamino group, a substituted or unsubstituted carbonyl group having 20 or less carbon atoms, a substituted or unsubstituted carbonyl ester group having 20 or less carbon atoms, a substituted or unsubstituted alkyl group having 20 or less carbon atoms, a substituted or unsubstituted alkenyl group having 20 or less carbon atoms, a substituted or unsubstituted alkoxy group having 20 or less carbon atoms, a substituted or unsubstituted aryl group having 30 or less carbon atoms, a substituted or unsubstituted heterocyclic group having 30 or less carbon atoms, a nitrile group, a cyano group, a nitro group, or a silyl group, and adjacent R^{m} (m=1 to 6) may be bonded to each other via a cyclic structure. X¹ to X⁶ are each independently a carbon atom or a nitrogen atom.

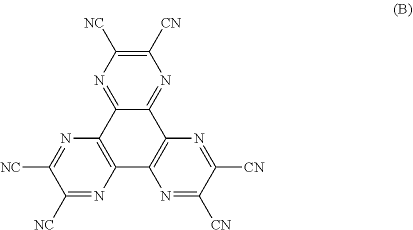 [SMILES: N#Cc1nc2c3nc(C#N)c(C#N)nc3c3nc(C#N)c(C#N)nc3c2nc1C#N]

The hole transport layer is a layer that improves hole transport efficiency to the light emitting layer. In the light emitting layer, when an electric field is applied, recombination of electrons and holes occurs, and light is generated. The electron transport layer is a layer that improves electron transport efficiency to the light emitting layer, and the electron injection layer is a layer that improves electron injection efficiency to the light emitting layer.

The hole transport layer is made of, for example, 4,4′,4″-tris(3-methylphenylphenylamino)triphenylamine (m-MTDATA) or α-naphthylphenyldiamine (αNPD) having a thickness of about 40 nm.

The light emitting layer is a light emitting layer that generates white light through color mixing, and is formed by for example, as described above, stacking a red light emitting layer, a green light emitting layer, and a blue light emitting layer.

In the red light emitting layer, application of an electric field causes some of the holes injected from the first electrode 31 and some of the electrons injected from the second electrode 32 to recombine to generate red light. Such a red light emitting layer contains, for example, at least one type of material among a red light emitting material, a hole transporting material, an electron transporting material, and a both charge transporting material. The red light emitting material may be a fluorescent material or a phosphorescent material. The red light emitting layer having a thickness of about 5 nm is formed by mixing 30 mass % of 2,6-bis[(4′-methoxydiphenylamino)styryl]-1,5-dicyanonaphthalene (BSN) with 4,4-bis(2,2-diphenylvinin)biphenyl (DPVBi), for example.

In the green light emitting layer, application of an electric field causes some of the holes injected from the first electrode 31 and some of the electrons injected from the second electrode 32 to recombine to generate green light. Such a green light emitting layer contains, for example, at least one kind of material among a green light emitting material, a hole transporting material, an electron transporting material, and a both charge transporting material. The green light emitting material may be a fluorescent material or a phosphorescent material. The green light emitting layer having a thickness of about 10 nm is formed by mixing 5 mass % of coumarin 6 with DPVBi, for example.

In the blue light emitting layer, application of an electric field causes some of the holes injected from the first electrode 31 and some of the electrons injected from the second electrode 32 to recombine to generate blue light. Such a blue light emitting layer contains, for example, at least one kind of material among a blue light emitting material, a hole transporting material, an electron transporting material, and a both charge transporting material. The blue light emitting material may be a fluorescent material or a phosphorescent material. The blue light emitting layer having a thickness of about 30 nm is formed by mixing 2.5 mass % of 4,4′-bis[2-{4-(N,N-diphenylamino)phenyl}vinyl]biphenyl (DPAVBi) with DPVBi, for example.

The electron transport layer having a thickness of about 20 nm is made of, for example, 8-hydroxyquinoline aluminum (Alq3). The electron injection layer having a thickness of about 0.3 nm is made of, for example, LiF or Li₂O.

The materials constituting each layer are merely examples, and are not limited to these materials. Further, for example, as described above, the light emitting layer may be composed of a blue light emitting layer and a yellow light emitting layer, or may be composed of a blue light emitting layer and an orange light emitting layer.

Hereinafter, an outline of a method for producing the light emitting element 10 of Example 1 illustrated in FIG. 1 will be described.

[Step-100A]

First, a light emitting element driving unit is formed on a silicon semiconductor substrate (the first substrate 41) based on a known MOSFET production process.

[Step-100B]

Next, the base body (interlayer insulating layer) 26 is formed on the entire surface by a CVD method.

[Step-100C]

Then, a connection hole is formed in a portion of the base body 26 located above one source/drain region of the transistor 20 based on a photolithography technique and an etching technique. Next, a metal layer is formed on the base body 26 including the connection hole based on, for example, a sputtering method, and then the metal layer is patterned based on a photolithography technique and an etching technique, whereby the first electrode 31 may be formed on a part of the base body 26. The first electrode 31 is separated for each light emitting element. In addition, a contact hole (contact plug) 27 that electrically connects the first electrode 31 and the transistor 20 may be formed in the connection hole.

[Step-110A]

Next, the insulating layer 28 is formed on the entire surface based on a CVD method for example, and then the insulating layer 28 is left on the base body 26 between the first electrode 31 and the first electrode 31 based on a photolithography technique and an etching technique.

[Step-110B]

Thereafter, the organic layer 33 is formed on the first electrode 31 and the insulating layer 28 by, for example, a PVD method such as a vacuum vapor deposition method or a sputtering method, a coating method such as a spin coating method or a die coating method, or the like. The organic layer 33 may be patterned into a desired shape in some cases.

[Step-110C]

Next, the second electrode 32 is formed on the entire surface based on, for example, a vacuum vapor deposition method or the like. The second electrode 32 may be patterned into a desired shape in some cases. The organic layer 33 and the second electrode 32 may be formed on the first electrode 31 in this manner.

[Step-110D]

Thereafter, a protective film (not illustrated) made of an inorganic material is formed based on a CVD method, and then the intermediate layer 34 is formed on the entire surface based on a coating method, thereafter the top surface of the intermediate layer 34 is flattened. Since the intermediate layer 34 may be formed based on a coating method, there are few in-process restrictions, a wide selection of material is made, and a high refractive index material can be used. Thereafter, the color filter layers CF₁, CF₂, CF₃ are formed on the intermediate layer 34 by a known method.

[Step-120]

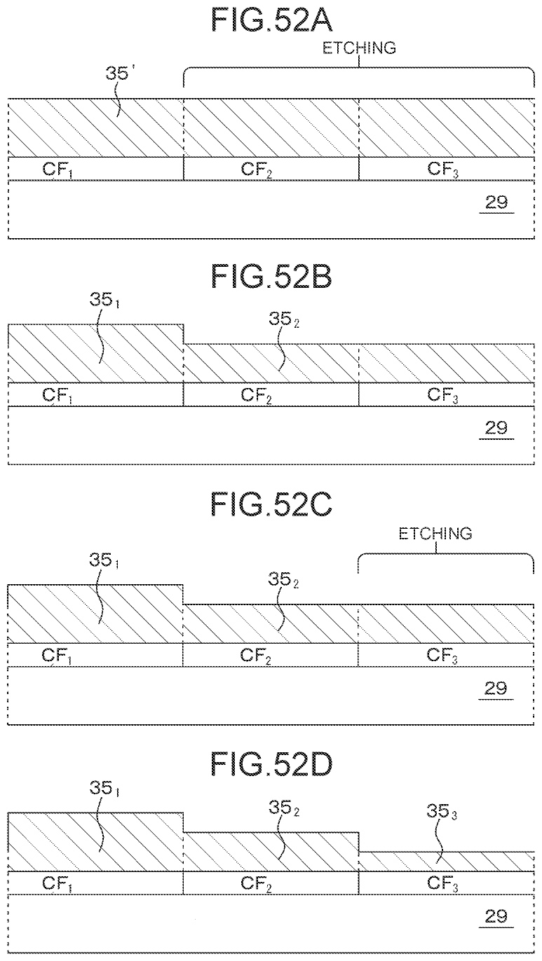

Next, the base 35 (35₁, 35₂, 35₃) is formed on the color filter layer CF (CF₁, CF₂, CF₃). Specifically, a base constituent material layer 35′ for forming the base 35₁ is formed on the entire surface (see FIG. 52A). Next, the base constituent material layer 35′ is patterned based on a photolithography technique and an etching technique to obtain the first base 35₁ (see FIG. 52B). Thereafter, the base constituent material layer 35′ is patterned again based on a photolithography technique and an etching technique to obtain the second base 35₂ with the first base 35₁ left as it is (see FIG. 52C). Thereafter, the base constituent material layer 35′ is patterned again based on a photolithography technique and an etching technique to obtain the third base 35₃ with the first base 35₁ and the second base 35₂ left as they are (see FIG. 52D). The first base 35₁, the second base 35₂, and the third base 35₃ may be thus obtained.

[Step-130]

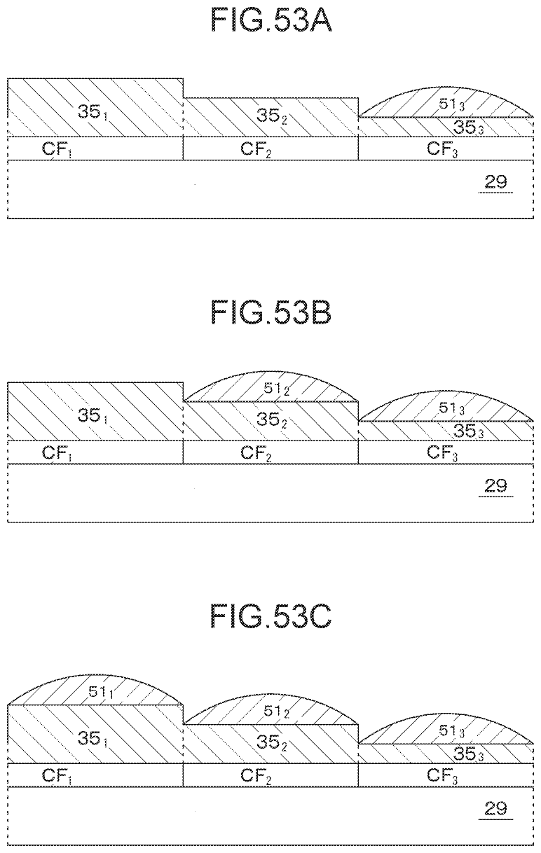

Next, for example, the third lens unit 51₃ is formed on the third base 35₃ (see FIG. 53A), the second lens unit 51₂ is formed on the second base 35₂ (see FIG. 53B), and the first lens unit 51₁ is formed on the first base 35₁ (see FIG. 53C). Specifically, a lens unit forming layer for forming the lens unit 51 is formed on the entire surface, and a resist material layer is formed thereon. Then, the third lens unit 51₃ may be formed by patterning the resist material layer, leaving the resist material layer on the third base 35₃, and heating the resist material layer to form the resist material layer into the shape of the lens unit. Similarly, the second lens unit 51₂ may be formed on the second base 35₂, and the first lens unit 51₁ may be formed on the first base 35₁.

[Step-140]

Next, the lens unit 51 (51₁,51₂,51₃) and the second substrate 42 are bonded together by the sealing resin layer 36 made of an acrylic adhesive. The light emitting element (organic EL element) and the display device of Example 1 illustrated in FIG. 1 may be obtained in this manner. As described above, by adopting the so-called OCCF type in which the color filter layer CF is provided on the first substrate side instead of providing the color filter layer CF on the second substrate side, the distance between the organic layer 33 and the color filter layer CF can be shortened, a wide range of and more free design of the lens unit 51 is obtained. With adoption of the so-called OCCF type, there is little possibility that a problem occurs in alignment with the organic layer 33.

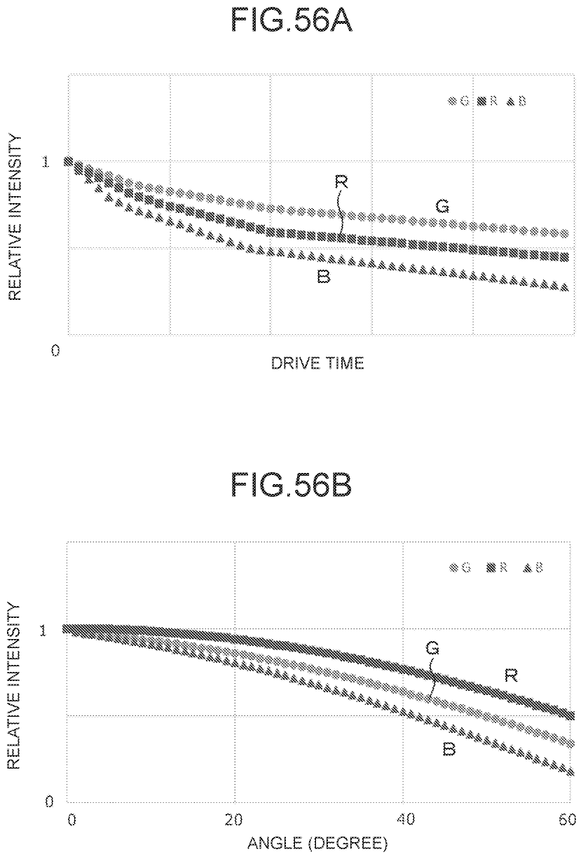

Meanwhile, as illustrated in the light emission life (life time) test result of the light emitting element in FIG. 56A, the luminance of the light emitting element decreases depending on the drive time of the light emitting element, and the decrease in luminance becomes large in the order of the green light emitting element (indicated by circles with “G” in FIG. 56A), the red light emitting element (indicated by squares with “R” in FIG. 56A), and the blue light emitting element (indicated by triangles with “B” in FIG. 56A). Thus, in a light emitting element that emits white light with a light emitting layer formed by stacking a red light emitting layer, a green light emitting layer, and a blue light emitting layer, a change state of luminance in the red light emitting layer, the green light emitting layer, and the blue light emitting layer is different over time, and as a result, white light emitted from the light emitting element becomes reddish or greenish light. In addition, as illustrated in the viewing angle dependency of FIG. 56B, depending on the angle (viewing angle) from the normal line of the light emitting element, the decrease in luminance becomes large in the order of the red light emitting element, the green light emitting element, and the blue light emitting element. The result of the green light emitting element is indicated by circles with “G” in FIG. 56B, the result of the red light emitting element is indicated by squares with “R” in FIG. 56B, and the result of the blue light emitting element is indicated by triangles with “B” in FIG. 56B. Thus, in a light emitting element that emits white light with a light emitting layer formed by stacking a red light emitting layer, a green light emitting layer, and a blue light emitting layer, a change state of luminance in the red light emitting layer, the green light emitting layer, and the blue light emitting layer is different depending on the viewing angle (that is, when the display device is viewed obliquely but not from the front), and as a result, the luminance is deviated from desired chromaticity, and white light emitted from the light emitting element also becomes reddish or greenish light. That is, so-called viewing angle coloring occurs.

A lens surface of the on-chip micro-convex lens having a large curvature radius can increase the amount of light emitted from the light emitting element to the outside. However, as the miniaturization of the pixels progresses, the size of the light emitting unit also decreases, and as a result, the size of the on-chip micro-convex lens also decreases, and it becomes difficult to increase the curvature radius of the lens surface.

In the display device of Example 1, the value of (TL+TB), which is the distance from the light emitting unit to the light exit surface of the lens unit, satisfies

(TL₃+TB₃)≤(TL₂+TB₂)<(TL₁+TB₁)

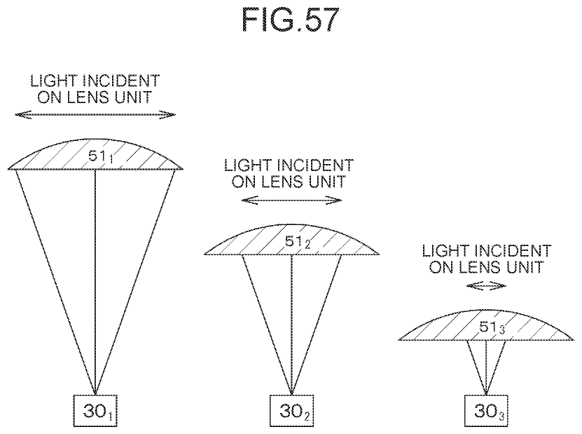

excluding a case where the value of TB₃, the value of TB₂, and the value of TB₁ are the same. Specifically, the distance from the light emitting unit of the light emitting element that emits blue light to the light exit surface of the lens unit is longer than the distance from the light emitting unit of the light emitting element that emits green light and red light to the light exit surface of the lens unit. As illustrated in the conceptual diagram of FIG. 57, as the value of (TL+TB), which is the distance from the light emitting unit 30 to the light exit surface of the lens unit 51, increases, that is, by considering not only the curvature radius of the lens surface of the lens unit but also the height of the base, the amount of light incident on the lens unit 51 can be increased, and as a result, the luminance of the first light emitting element can be increased.

In a display device requiring high luminance or a display device for, for example, a wearable display device, a head mounted display (HMD), virtual reality (VR), mixed reality (MR), or augmented reality (AR), when the current flowing through a light emitting element that emits blue light is increased to avoid the state illustrated in FIG. 56A, a light emission life of the light emitting element becomes short. Thus, in the display device of Example 1, a configuration of

(TL₃+TB₃)≤(TL₂+TB₂)<(TL₁+TB₁)

is adopted. Since it is possible to increase the amount of light incident on the lens unit of the light emitting element that emits blue light, the luminance of the light emitting element that emits blue light can be maintained even with a reduced value of the current flowing through the light emitting element that emits blue light. As a result, the light emitting element that emits blue light can be inhibited from degrading over time, and white light emitted from the light emitting element can be inhibited from changing. Thus, the display device of Example 1 is suitable for application to the above-described display device requiring high luminance, a wearable display device, and the like.

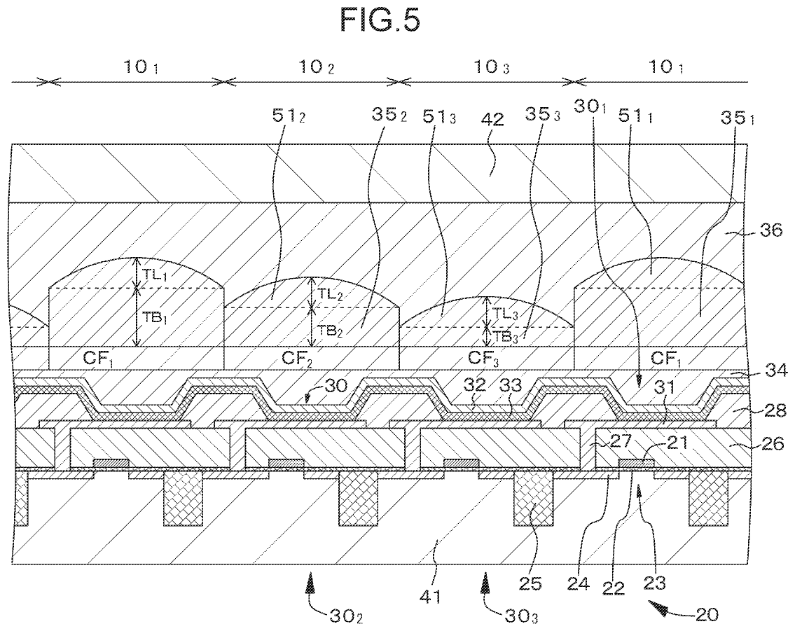

FIG. 5 is a schematic and partial sectional view of Modification-1 of the display device of Example 1. In Modification-1 of the display device of Example 1, the base 35 and the lens unit 51 are made of the same material, for example, an acrylic transparent resin having a refractive index of 1.55. This configuration can simplify the production process. In FIG. 5, the boundaries between the lens unit 51 and the base 35 are indicated by dotted lines.

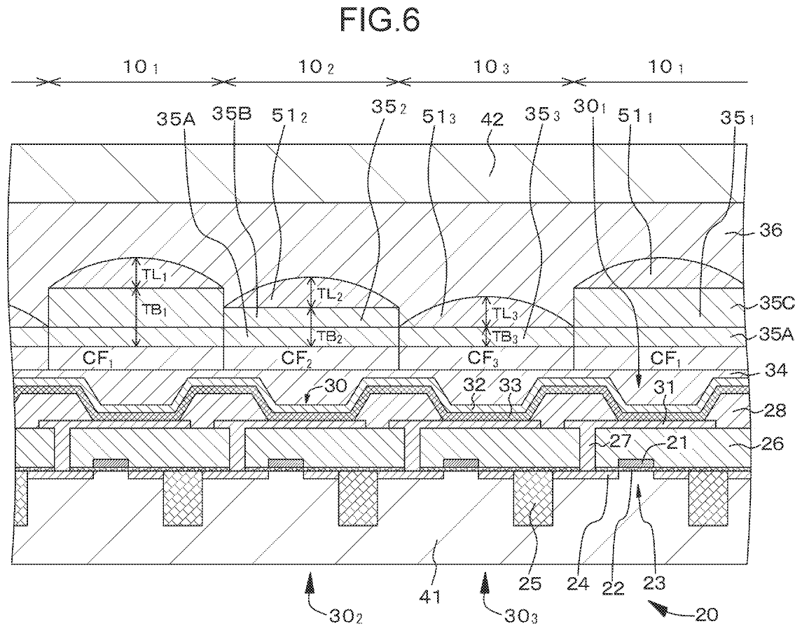

FIG. 6 is a schematic and partial sectional view of Modification-2 of the display device of Example 1. Modification-2 of the display device of Example 1 includes a base having a multilayer structure. Specifically, the third base 35₃ of the third light emitting element (red light emitting element) 10₃ is made of an acrylic transparent resin. The second base 35₂ of the second light emitting element (green light emitting element) 10₂ is composed of an extension part 35A of the third base 35₃ and a second base constituent layer 35B made of an acrylic transparent resin. The first base 35₁ of the first light emitting element (blue light emitting element) 10₁ is composed of an extension part 35A of the third base 35₃ and the first base constituent layer 35C made of an acrylic transparent resin.

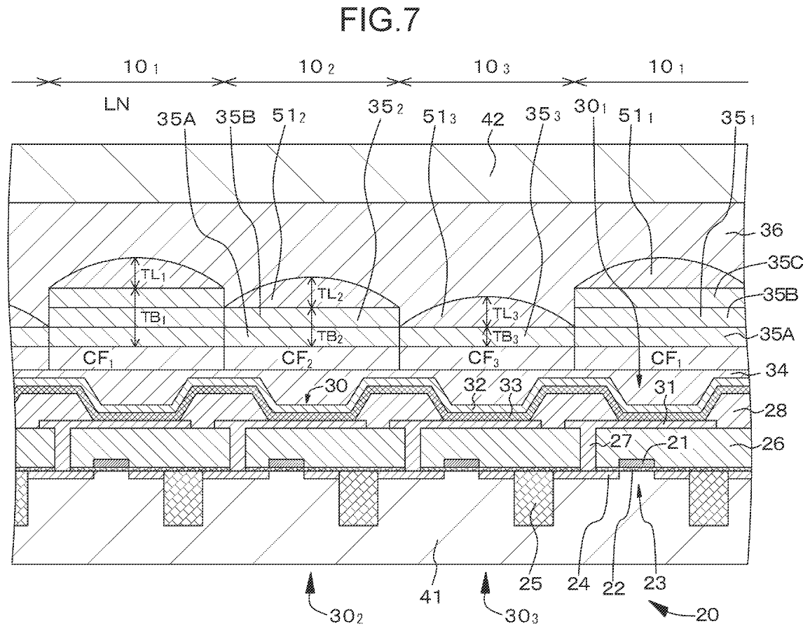

FIG. 7 is a schematic and partial sectional view of Modification-3 of the display device of Example 1. Modification-3 of the display device of Example 1 also includes a base having a multilayer structure.

Specifically, the third base 35₃ of the third light emitting element (red light emitting element) 10₃ is made of an acrylic transparent resin. The second base 35₂ of the second light emitting element (green light emitting element) 10₂ is composed of an extension part 35A of the third base 35₃ and a second base constituent layer 35B made of an acrylic transparent resin. Further, the first base 35₁ of the first light emitting element (blue light emitting element) 10₁ is composed of an extension part 35A of the third base 35₃, an extension part (second base constituent layer 35B) of the second base 35₂, and the first base constituent layer 35C made of an acrylic transparent resin.

Other configurations and structures of Modification-1, Modification-2, and Modification-3 of the display device of Example 1 described above may be the same as the configurations and structures of the display device of Example 1.

### Example 2

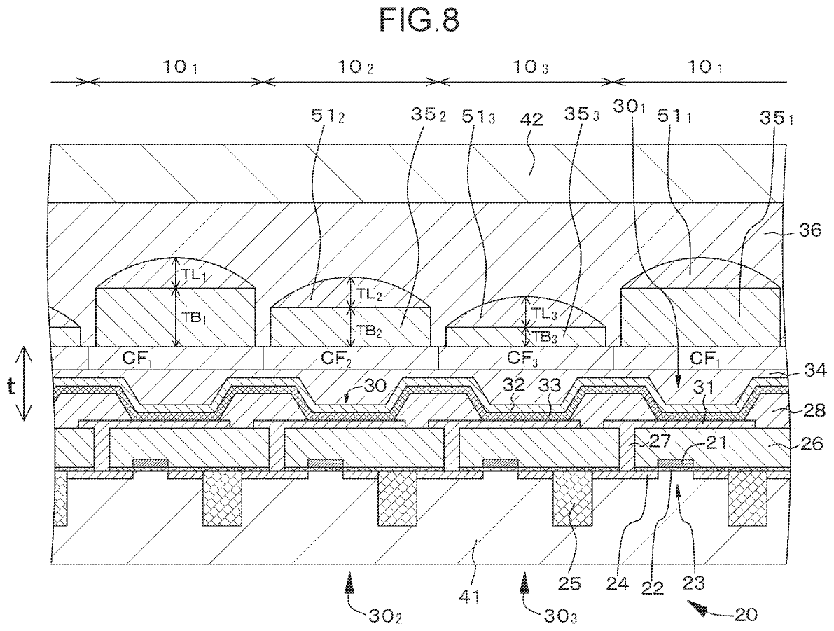

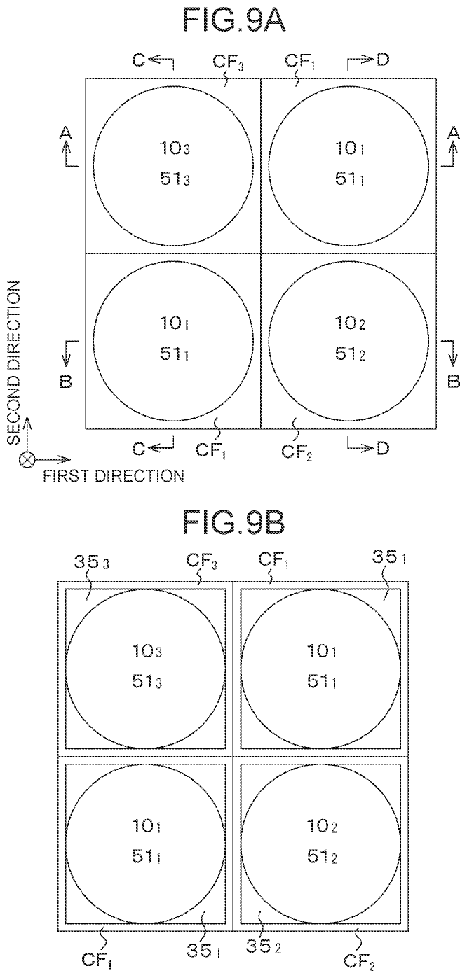

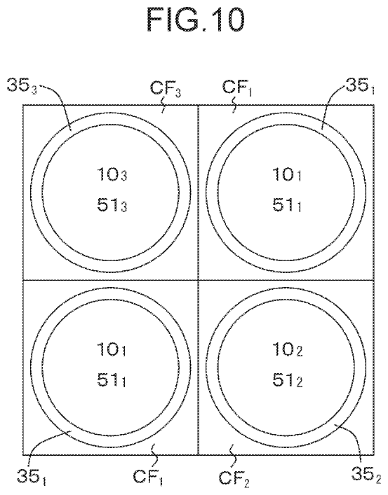

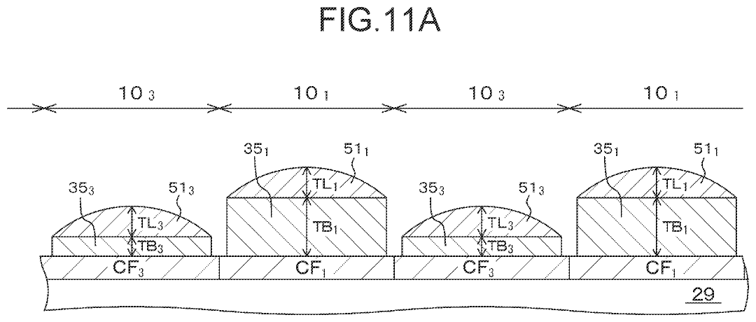

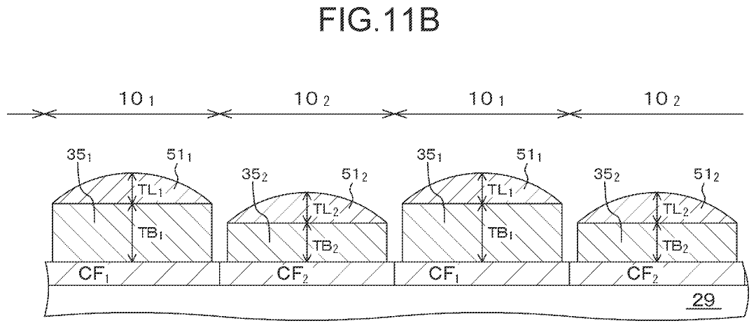

Example 2 is a modification of Example 1. FIG. 8 is a schematic and partial sectional view of a display device of Example 2. FIGS. 9A, 9B, and 10 are schematic views of a lens unit and the like of one light emitting element unit in Example 2 as viewed from above. FIG. 11A is a schematic and partial sectional view of a lens unit and a base taken along the arrows A-A and C-C in FIG. 9A. FIG. 11B is a schematic and partial sectional view of the lens unit and the base taken along the arrows B-B and D-D in FIG. 9A.

In the display device of Example 2, in each light emitting element unit, the base 35 has no side surface being in contact with a side surface of an adjacent base 35. With such a structure, it is possible to obtain a state in which the side surfaces of the base 35 are in contact with a material having a refractive index n_{M} lower than the refractive index n_{B} of the base constituent material. Thus, a kind of lens effect or waveguide effect can be imparted to the base 35, and the light collection effect of the lens unit 51 can be further improved. In Example 2, specifically, a portion between a side surface of a base 35 and a side surface of another base 35 is filled with the sealing resin layer 36 including a material having a refractive index n_{M} lower than the refractive index n_{N} of the material constituting the bases 35. The shortest distance between the side surfaces of adjacent bases 35 was set to, for example, 0.5 μm.

In the example illustrated in FIGS. 8, 9A, and 9B, the top surfaces of the bases 35₁, 35₂, 35₃ are covered with the lens units 51₁, 51₂, 51₃, respectively. As illustrated in FIG. 10, the lens units 51₁, 51₂, 51₃ cover a part of the top surface of the bases 35₁, 35₂, 35₃, respectively. As illustrated in FIGS. 9A and 10, the planar shape of the bases 35₁, 35₂, 35₃ is the same circular shape as the planar shape of the lens units 51₁, 51₂, 51₃. In this case, the bases 35₁, 35₂, 35₃ are in contact with a part of the first wavelength selection unit CF₁, the second wavelength selection unit CF₂, and the third wavelength selection unit CF₃, respectively, and the rest of the first wavelength selection unit CF₁, the second wavelength selection unit CF₂, and the third wavelength selection unit CF₃ is in contact with the sealing resin layer 36. Alternatively, as illustrated in FIG. 9B, the planar shape of the lens units 51₁, 51₂, 51₃ is a circular shape, and the planar shape of the bases 35₁, 35₂, 35₃ is a square shape. In this case, the bases 35₁, 35₂, 35₃ are in contact with the first wavelength selection unit CF₁, the second wavelength selection unit CF₂, and the third wavelength selection unit CF₃, respectively. The sealing resin layer 36 is located above the paper surfaces of FIGS. 9A, 9B, and 10.

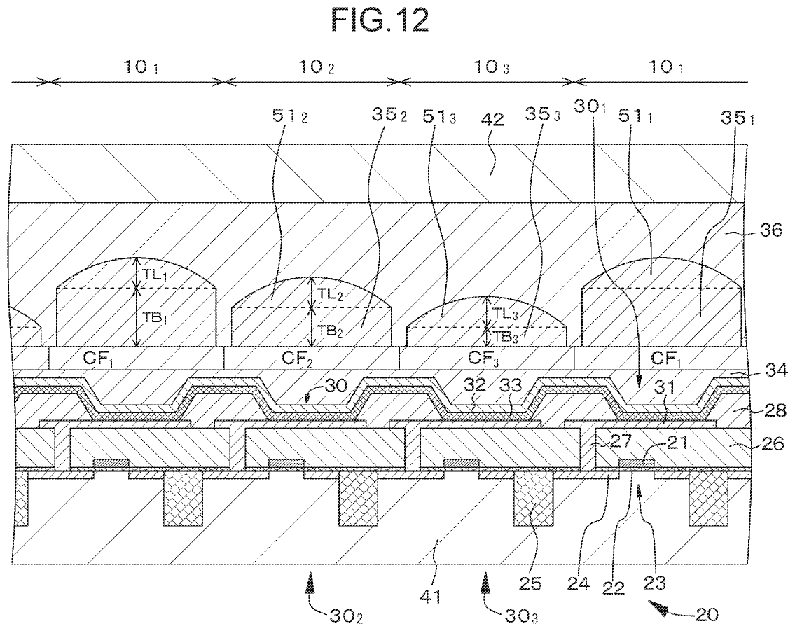

FIG. 12 is a schematic and partial sectional view of Modification-1 of the display device of Example 2. In Modification-1 of the display device of Example 2, the base 35 and the lens unit 51 are made of the same material, for example, an acrylic transparent resin having a refractive index of 1.55. In FIG. 12, the boundaries between the lens unit 51 and the base 35 are indicated by dotted lines.

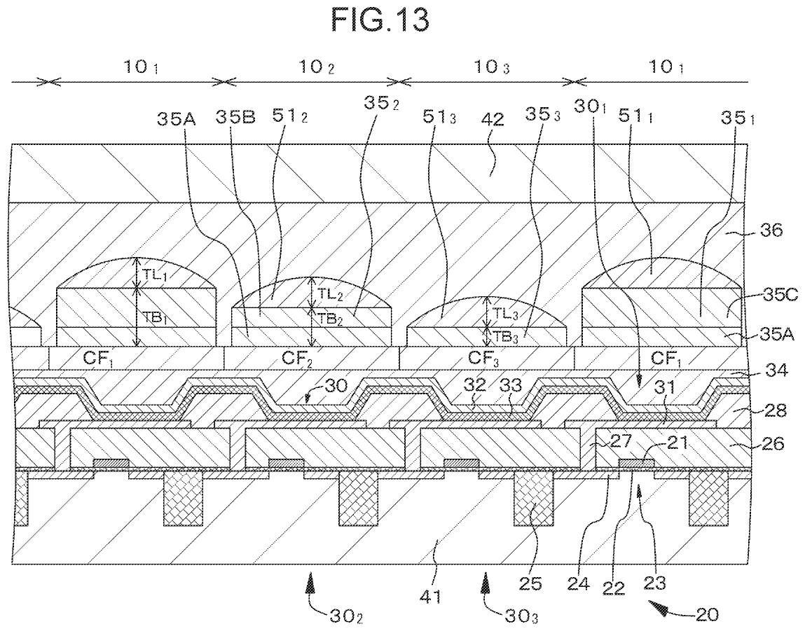

FIG. 13 is a schematic and partial sectional view of Modification-2 of the display device of Example 2. Modification-2 of the display device of Example 2 includes a base having a multilayer structure. Specifically, the third base 35₃ of the third light emitting element (red light emitting element) 10₃ is made of the same material as the third base 35₃ in Modification-2 of Example 1. The second base 35₂ of the second light emitting element (green light emitting element) 10₂ is made of the same material as the extension part 35A of the third base 35₃ and the second base 35₂ (second base constituent layer 35B) in Modification-2 of Example 1. The first base 35₁ of the first light emitting element (blue light emitting element) 10₁ is made of the same material as the extension part 35A of the third base 35₃ and the first base 35₁ (first base constituent layer 35C) in Modification-2 of Example 1.

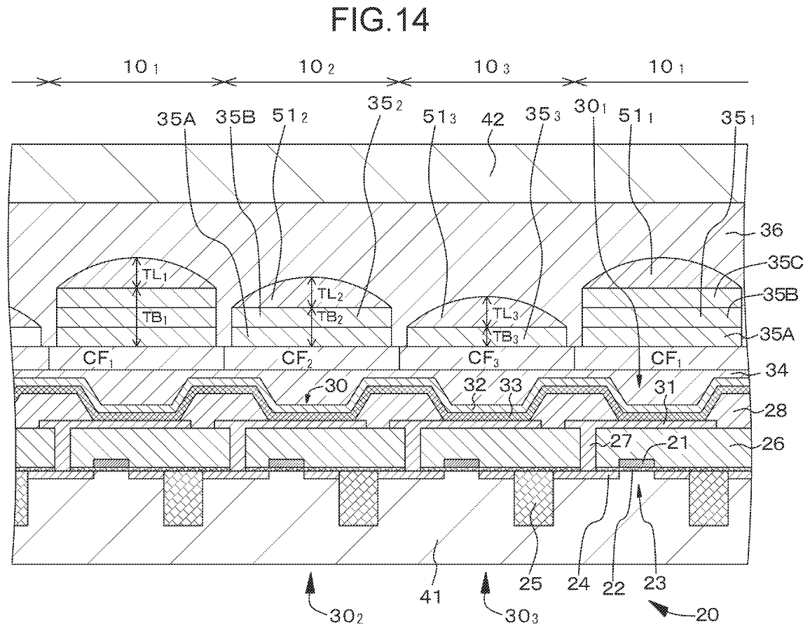

FIG. 14 is a schematic and partial sectional view of Modification-3 of the display device of Example 2. Modification-3 of the display device of Example 2 includes a base having a multilayer structure. Specifically, the third base 35₃ of the third light emitting element (red light emitting element) 10₃ is made of the same material as the third base 35₃ in Modification-3 of Example 1. The second base 35₂ of the second light emitting element (green light emitting element) 10₂ is made of the same material as the extension part 35A of the third base 35₃ and the second base 35₂ (second base constituent layer 35B) in Modification-3 of Example 1. The first base 35₁ of the first light emitting element (blue light emitting element) 10₁ is made of the same material as the extension part 35A of the third base 35₃, the extension part (second base constituent layer 35B) of the second base 35₂, and the first base 35₁ (first base constituent layer 35C) in Modification-3 of Example 1.

### Example 3

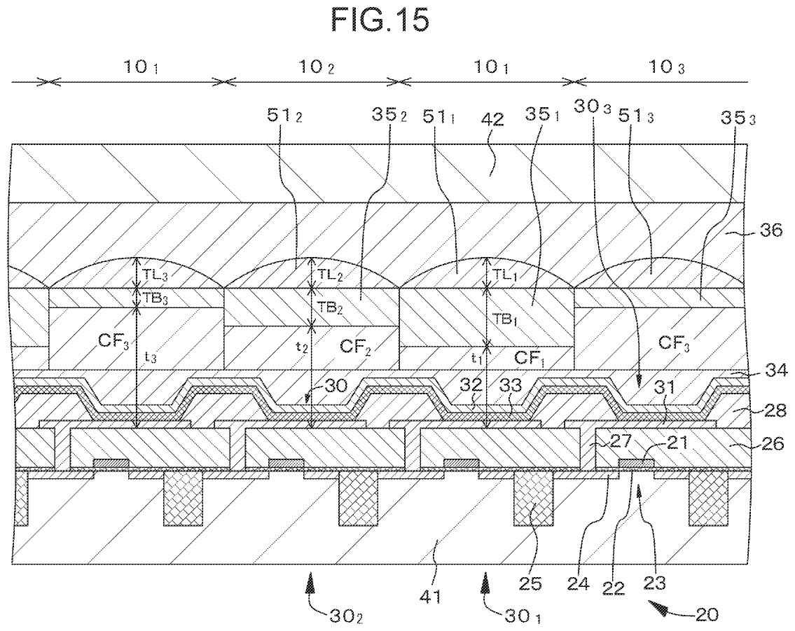

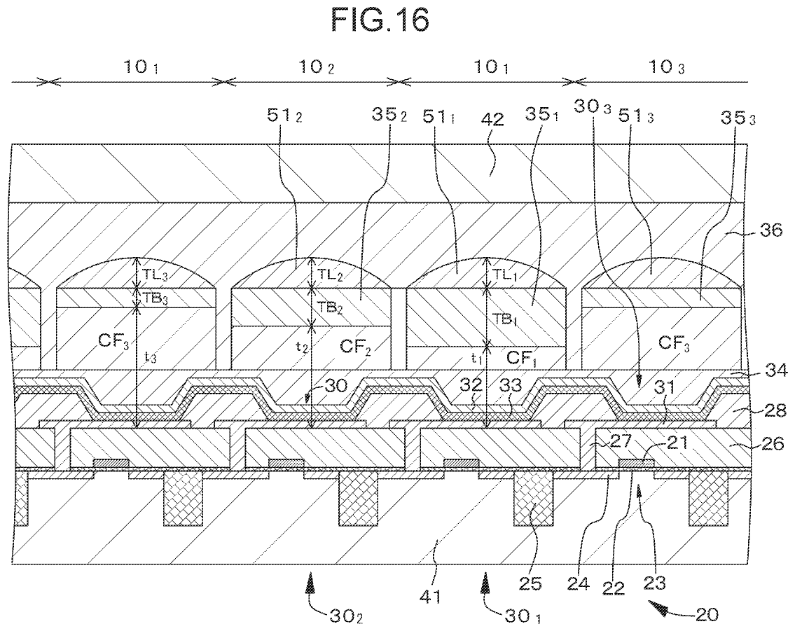

Example 3 is a modification of Examples 1 and 2. FIGS. 15 and 16 are schematic and partial sectional views of a display device of Example 3.

In Examples 1 and 2, the thickness of the light emitting unit is substantially the same in the first light emitting unit 30₁, the second light emitting unit 30₂, and the third light emitting unit 30₃. In Example 3, the thickness of the light emitting unit is different in the first light emitting unit 30₁, the second light emitting unit 30₂, and the third light emitting unit 30₃. In the example illustrated in FIGS. 15 and 16, t₁≠t₂, t₁≠t₃, and t₂≠t₃ are satisfied where the thickness of the first light emitting unit 30₁ is t₁, the thickness of the second light emitting unit 30₂ is t₂, and the thickness of the third light emitting unit 30₃ is t₃. More specifically,

t₁>t₂>t₃

is satisfied.

In addition, unlike Examples 1 and 2, the first light emitting element 10₁ emits red light, the second light emitting element 10₂ emits green light, and the third light emitting element 10₃ emits blue light.

Except for the above configuration and structure, the display device of Example 3 may have substantially the same configurations and structures as the display devices of Examples 1 and 2, and thus detailed description thereof is omitted. In addition, various modifications of the display device of Example 1 and various modifications of the display device of Example 2 may be applied to the display device of Example 3.

In the display device of Example 3 as well, the value of (TL+TB), which is the distance from the light emitting unit 30 to the light exit surface of the lens unit 51, satisfies

(TL₃+TB₃)≤(TL₂+TB₂)<(TL₁+TB₁). Specifically, the distance from the third light emitting unit 30₃ of the third light emitting element 10₃ that emits blue light to the light exit surface of the third lens unit 51₃ is shorter than the distance from the first light emitting unit 30₁ of the first light emitting element 10₁ that emits red light to the light exit surface of the first lens unit 51₁ (and, in some cases, shorter than the distance from the second light emitting unit 30₂ of the second light emitting element 10₂ that emits green to the light exit surface of the second lens unit 51₂). As a result, the light emitting element that emits blue light can efficiently cause more light to converge than the light emitting element that emits red light (and, in some cases, than the light emitting element that emits green light), and the viewing angle dependency of the luminance of the light emitting element that emits blue light can be reduced. For example, in a display device with which view points shift (that is, applications where viewing angle coloring is concerned) such as an electronic view finder, or in a display device in which color is important, the occurrence of deviation from desired chromaticity can be inhibited by using the display device of Example 3, and the occurrence of viewing angle coloring such as turning of white light emitted from a light emitting element into red or greenish light can be inhibited.

In the display device according to the first aspect of the present disclosure in which the value of (TL+TB), which is the distance from the light emitting unit 30 to the light exit surface of the lens unit 51, satisfies

(TL₃+TB₃)≤(TL₂+TB₂)<(TL₁+TB₁),

whether the first light emitting element is a light emitting element that emits blue light (Example 1) or the third light emitting element is a light emitting element that emits blue light (Example 3) may be appropriately determined according to the specifications required for the display device.

The display device of Example 3 illustrated in FIG. 15 is provided with one lens unit for one light emitting unit, but in some cases, one lens unit may be shared by a plurality of light emitting elements. For example, a light emitting element may be arranged at each corner of an equilateral triangle (a total of three light emitting elements are arranged), and one lens unit may be shared by these three light emitting elements, or a light emitting element may be arranged at each corner of a rectangle (a total of four light emitting elements are arranged), and one lens unit may be shared by these four light emitting elements. Alternatively, a plurality of lens units may be provided for one light emitting unit.

### Example 4

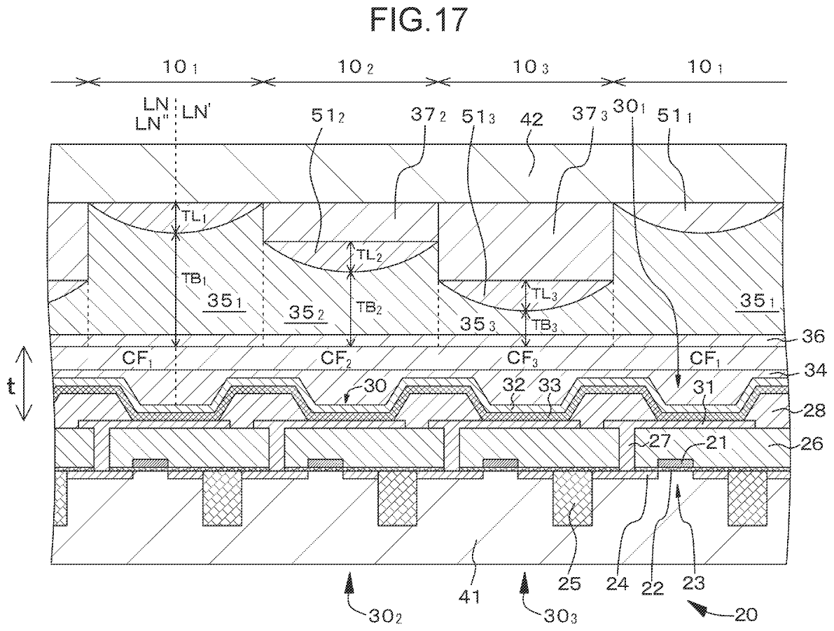

Example 4 is a modification of Examples 1 to 3. As illustrated in the schematic and partial sectional view of FIG. 17, in the display device of Example 4, in each light emitting element unit, the lens unit 51 is concave in a direction away from the light emitting unit 30. In this case, light emitted from the first light emitting unit 30₁ passes through the sealing resin layer 36, the first base 35₁, the first lens unit 51₁, and the second substrate 42 to be emitted to the outside in a converged state. Light emitted from the second light emitting unit 30₂ passes through the sealing resin layer 36, the second base 35₂, the second lens unit 51₂, the second support unit 37₂, and the second substrate 42 to be emitted to the outside in a converged state. Light emitted from the third light emitting unit 30₃ passes through the sealing resin layer 36, the third base 35₃, the third lens unit 51₃, the third support unit 37₃, and the second substrate 42 to be emitted to the outside in a converged state. The refractive index of the material constituting the lens unit 51 is set to be higher than the refractive index of the material constituting the base 35. That is,

n_{B-1}≤n_{L-1}

n_{B-2}≤n_{L-2}

n_{B-3}≤n_{L-3}

are satisfied. Specifically, it is preferable to increase the value of the refractive index in the order of the refractive index of the material constituting the sealing resin layer 36, the refractive index of the material constituting the base 35, the refractive index of the material constituting the lens unit 51, the refractive index of the material constituting the support unit 37, and the refractive index of the material constituting the second substrate 42. In some cases, the refractive index of the material constituting the support unit 37 and the refractive index of the material constituting the lens unit 51 may have the same value.

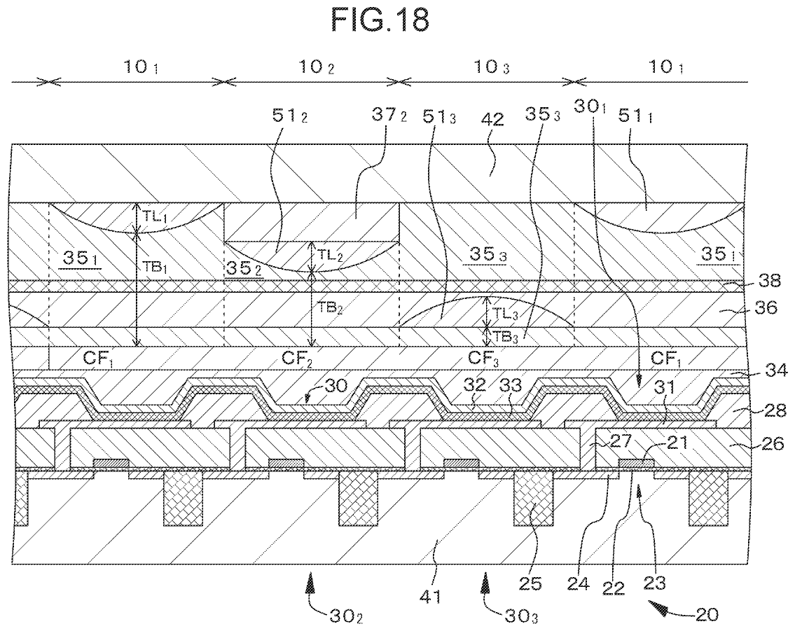

Alternatively, as illustrated in the schematic and partial sectional view of Modification-1 of the display device of Example 4 in FIG. 18, in each light emitting element unit, a lens unit 51 convex in a direction away from the light emitting unit 30 and a lens unit 51 concave in a direction away from the light emitting unit 30 are mixed. In the illustrated example, the first lens unit 51₁ and the second lens unit 51₂ are concave in a direction away from the first light emitting unit 30₁ and the second light emitting unit 30₂, and the third lens unit 51₃ is convex in a direction away from the third light emitting unit 30₃, but the present invention is not limited to this configuration. Reference numeral 38 denotes a flattening layer.

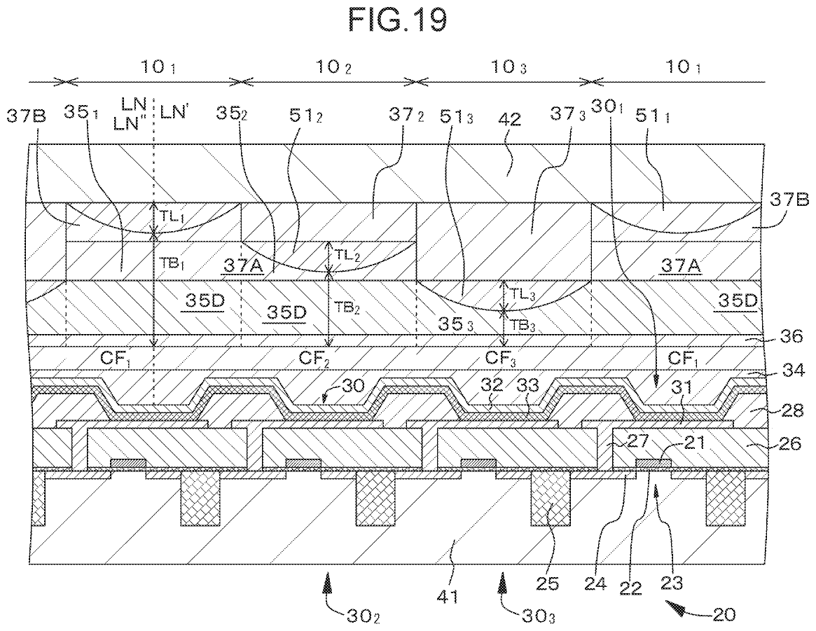

Alternatively, as illustrated in the schematic and partial sectional view of Modification-2 of the display device of Example 4 in FIG. 19, the base 35 stacked with the support unit 37 may be present in each light emitting element unit. That is, the first base 35₁ constituting the first light emitting element 10₁ has a stacked structure of the base constituent layer 35D, a support unit constituent material layer 37A, and a support unit constituent material layer 37B. The second base 35₂ constituting the second light emitting element 10₂ has a stacked structure of the base constituent layer 35D and the support unit constituent material layer 37A. Light emitted from the first light emitting unit 30₁ passes through the sealing resin layer 36, the base constituent layer 35D, the support unit constituent material layer 37A, the support unit constituent material layer 37B, the first lens unit 51₁, and the second substrate 42 to be emitted to the outside in a converged state. The light emitted from the second light emitting unit 30₂ passes through the sealing resin layer 36, the base constituent layer 35D, the support unit constituent material layer 37A, the second lens unit 51₂, the second support unit 37₂, and the second substrate 42, and is emitted to the outside in a converged state. Light emitted from the third light emitting unit 30₃ passes through the sealing resin layer 36, the third base 35₃ (base constituent layer 35D), the third lens unit 51₃, the third support unit 37₃, and the second substrate 42 to be emitted to the outside in a converged state.

In any case, the refractive index of the material constituting each member is selected such that the lens unit 51 has a light collection function.

Except for the above configuration and structure, the display device of Example 4 may have substantially the same configurations and structures as the display devices of Examples 1 to 3, and thus detailed description thereof is omitted. In addition, various modifications of the display device of Example 1, various modifications of the display device of Example 2, and various modifications of the display device of Example 3 may be applied to the display device of Example 4.

In the display device of Example 4, since all or some of the lens units are formed on the second substrate side, it is easier to form the lens units than forming the lens units on the first substrate side on which the light emitting unit is formed. In addition, when the base and the lens unit are formed on the first substrate side on which the light emitting unit is formed, selection of materials constituting the base and the lens unit and a forming process may be restricted. However, when all or some of the lens units are formed on the second substrate side, a degree of freedom in selection of materials constituting the base and the lens unit can be increased, and restrictions on the production process can be reduced.

### Example 5

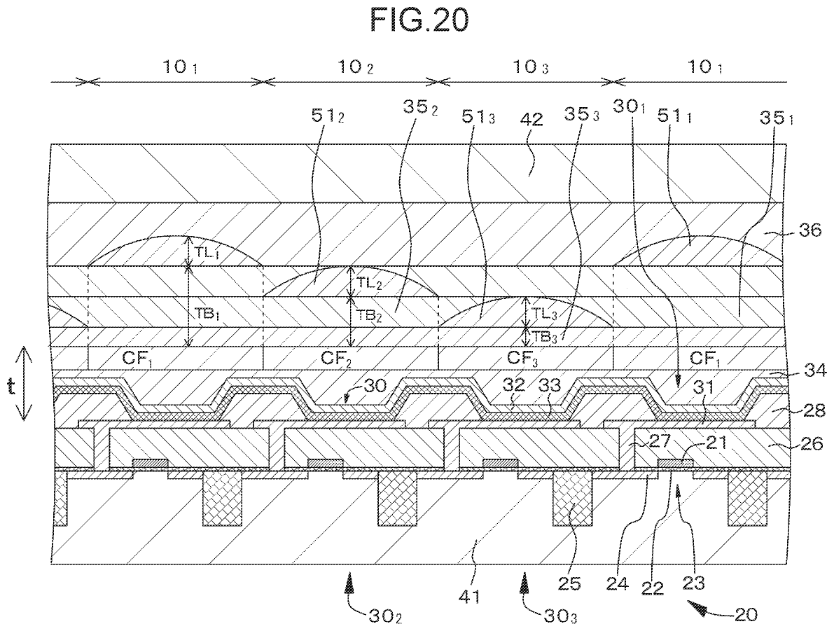

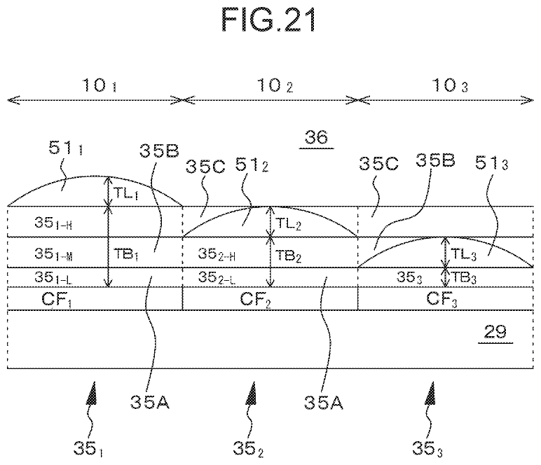

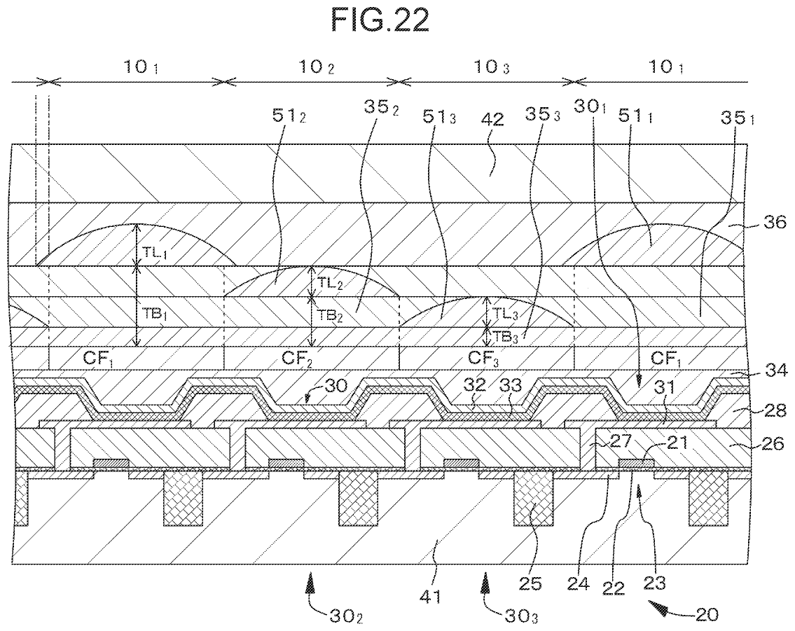

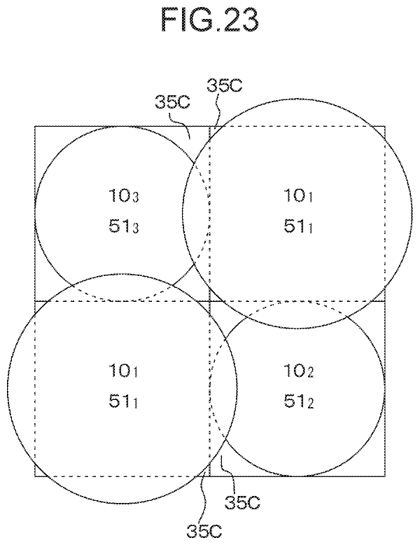

A display device of Example 5 is a modification of Examples 1 to 4, and it specifically relates to a display device according to Aspect 1-A of the present disclosure. FIG. 20 is a schematic and partial sectional view of the display device of Example 5. FIG. 21 is a schematic and partial sectional view of a base and the like constituting the display device of Example 5. FIG. 22 is a schematic and partial sectional view of Modification-1 of the display device of Example 5. FIG. 23 is a schematic view of a lens unit and the like of one light emitting element unit in Modification-1 of the display device of Example 5 as viewed from above.

As illustrated in schematic and partial sectional views of FIGS. 20 and 21, in the display device of Example 5,

the first base 35₁ has a stacked structure of a first L base 35_{1-L}, a first M base 35_{1-M}, and a first H base 35_{1-H} from the light emitting unit side,

the second base 35₂ has a stacked structure of a second L base 35_{2-L} and a second H base 35_{2-F} from the light emitting unit side,

the first L base 35_{1-L} and the second L base 35_{2-L} are composed of the extension part 35A of the third base, and

the first M base 35_{1-M} is composed of an extension part (second base constituent layer 35B) of the second H base.

FIG. 21 is a partial sectional view, in which hatching lines are omitted. Although the top of the light emission surface of the third lens unit 51₃ is in contact with the extension part 35C of the first H base in FIG. 20, the extension part (second base constituent layer 35B) of the second H base may be present between the top of the light emission surface of the third lens unit 51₃ and the extension part 35C of the first H base. Although the top of the light emission surface of the second lens unit 51₂ is in contact with the sealing resin layer 36 in the drawing, the extension part 35C of the first H base may be present between the top of the light emission surface of the third lens unit 51₃ and the sealing resin layer 36.

In the display device of Example 5,

n_{B-3}′>n_{B-2H}′>n_{B-1H}′

is satisfied where

n_{B-1H}′ is a refractive index of a first H base constituent material constituting the first H base 35_{1-H},

n_{B-2H}′ is a refractive index of a second H base constituent material constituting the second H base 35_{2-H} and the extension part of the second H base (second base constituent layer 35B), and

n_{B-3}′ is a refractive index of a third base constituent material constituting the third base 35₃ and the extension part 35A of the third base. Light emitted from the light emitting unit 30 passes through the base 35. In the base 35 having the stacked structure, the refractive index of the material constituting each layer is sequentially lowered as it goes away from the light emitting unit 30 in this manner. In this case, in each light emitting element unit, the lens unit 51 is convex in a direction away from the light emitting unit 30.

In such a display device of Example 5, in the first light emitting element 10₁, light emitted from the first light emitting unit 30₁ passes through the first L base 35_{1-L} (extension part 35A of the third base), the first M base 35_{1-M} [extension part of the second base (second base constituent layer 35B)], the first H base 35_{1-H}, and the first lens unit 51₁, and further passes through the sealing resin layer 36 and the second substrate 42 to be emitted to the outside. In the second light emitting element 10₂, light emitted from the second light emitting unit 30₂ passes through the second L base 35_{2-L} (extension part 35A of the third base) and the second H base 35_{2-H}, further passes through the second lens unit 51₂ and the extension part 35C of the first H base, then passes through the sealing resin layer 36 and the second substrate 42 to be emitted to the outside. In the third light emitting element 10₃, light emitted from the third light emitting unit 30₃ passes through the third base 35₃, further passes through the third lens unit 51₂, the extension part of the second L base (second base constituent layer 35B), the extension part 35C of the first H base, the sealing resin layer 36, and the second substrate 42 to be emitted to the outside. A schematic view of a lens unit and the like of one light emitting element unit in Example 5 as viewed from above is similar to that illustrated in FIG. 2A, for example.

Further, as in the schematic and partial sectional view of Modification-1 of the display device of Example 5 in FIG. 22 and the schematic view of a lens unit and the like of one light emitting element unit as viewed from above in FIG. 23, an orthogonal projection image of the first lens unit 51₁ of the first light emitting element 10₁ and an orthogonal projection image of the lens unit 51 of the light emitting element adjacent to the first light emitting element 10₁ partially overlap each other. In FIG. 22, the partially overlapping region is sandwiched by a one-dot chain line and a two-dot chain line. In FIG. 23, boundaries of the light emitting elements are indicated by a solid line and a dotted line. The structure of the lens unit of Modification-1 of the display device of Example 5 illustrated in FIG. 22 may also be applied to Modification-2 of Example 4 illustrated in FIG. 19.

In the display device of Example 5, the lens unit is hardly affected by the base and the lens unit constituting an adjacent light emitting element when the lens unit is formed, and the lens unit is more easily formed. As illustrated in Modification-1, by making the size of the first lens unit of the first light emitting element larger than the size of the lens unit of the light emitting element adjacent to the first light emitting element, the light collection efficiency of the lens unit can be improved. In addition, by making the size of the third lens unit the smallest and sequentially increasing the size of the second lens unit and the size of the first lens unit, it is possible to improve the light collection efficiency of the lens unit.

### Example 6

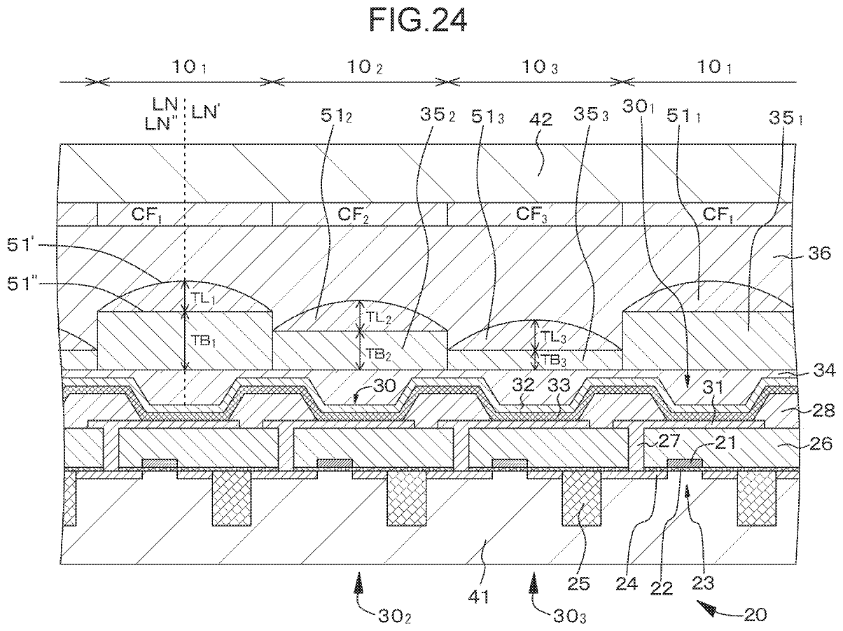

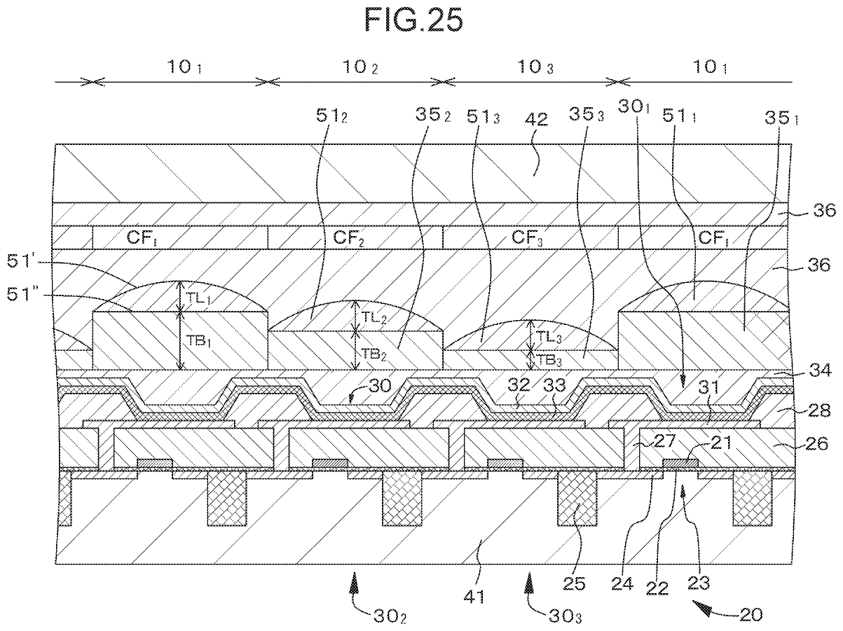

Example 6 is a modification of Examples 1 to 5. For example, in the display device of Example 1 illustrated in FIG. 1, the light emitting unit 30 includes the wavelength selection unit CF. On the other hand, as illustrated in the schematic and partial sectional view of FIG. 24, in a display device of Example 6, the wavelength selection unit CF is provided between the second substrate 42 and the sealing resin layer 36. Alternatively, as illustrated in the schematic and partial sectional view of FIG. 25, the wavelength selection unit CF may be provided between the sealing resin layers 36.

Except for the above points, the configuration and structure of the display device of Example 6 may be the same as the configuration and structure of the display device of Example 1, and thus detailed description is omitted. The configuration and structure of the display device of Example 6 may also be applied to a modification of Example 1, the display devices of Examples 2 to 5, and modifications thereof.

### Example 7

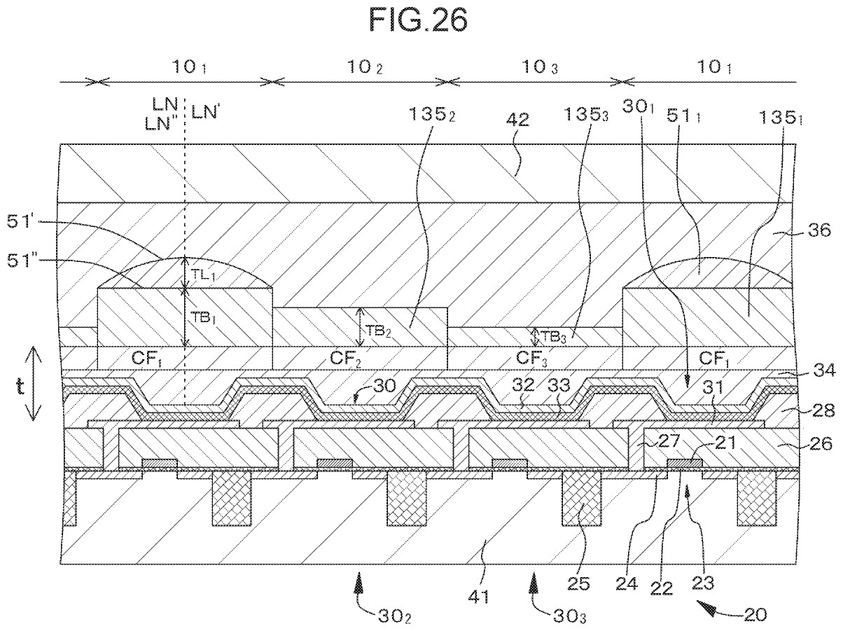

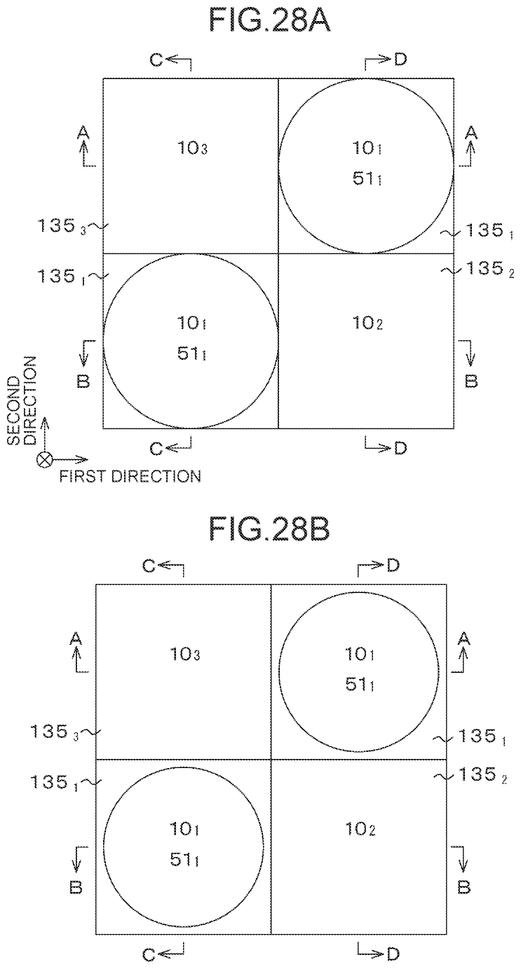

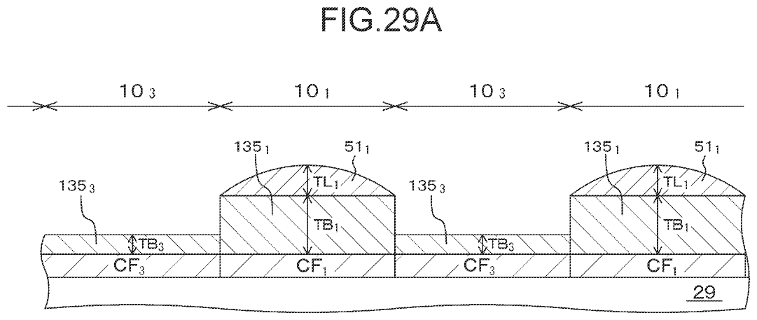

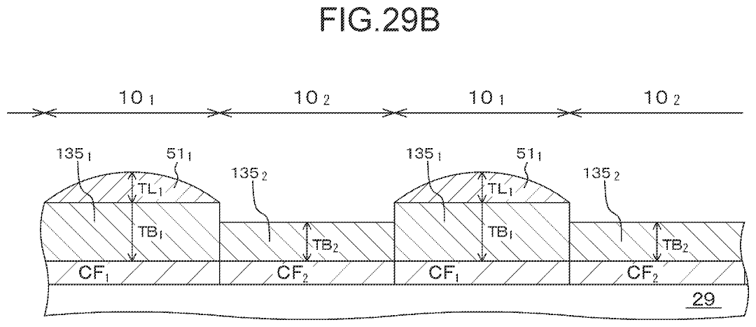

Example 7 relates to a display device according to the second aspect of the present disclosure. FIG. 26 is a schematic and partial sectional view of a display device of Example 7. FIG. 28A is a schematic view of a lens unit and the like of one light emitting element unit in Example 7. FIG. 29A is a schematic and partial sectional view of a lens unit and a base in the display device of Example 7 taken along the arrows A-A and C-C in FIG. 28A. FIG. 29B is a schematic and partial sectional view of the lens unit and the base taken along the arrows B-B and D-D in FIG. 28A.

The display device of Example 7 includes a plurality of light emitting element units (pixels) each including at least a first light emitting element 10₁ having a first light emitting unit 30₁ that emits light of a first color and a second light emitting element 10₂ having a second light emitting unit 30₂ that emits light of a second color,

wherein

in each light emitting element unit (pixel),

a first base 135₁ having a thickness TB₁ is provided above the first light emitting unit 30₁,

a second base 135₂ having a thickness TB₂ is provided above the second light emitting unit 30₂, and

a first lens unit 51₁ having a thickness TL₁ is provided on the first base 135₁, and

TB₂<(TL₁+TB₁)

is satisfied.

In the display device of Example 7,

each of the light emitting element units further includes a third light emitting element 10₃ having a third light emitting unit 30₃ that emits light of a third color,

in each light emitting element unit,

a third base 135₃ having a thickness TB₃ is provided above the third light emitting unit 30₃, and

TB₃≤TB₂<(TL₁+TB₁)

is satisfied.

The display device of Example 7 substantially has a configuration and a structure obtained by removing the second lens unit 51₂ and the third lens unit 51₃ from the display device described in Example 1.

Here, the planar shapes of the first base 135₁, the second base 135₂, and the third base 135₃ are squares.

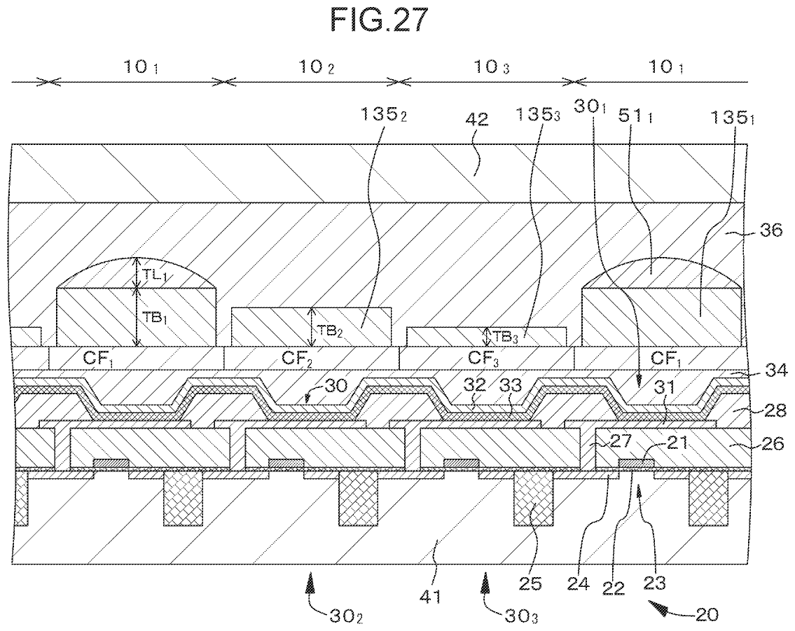

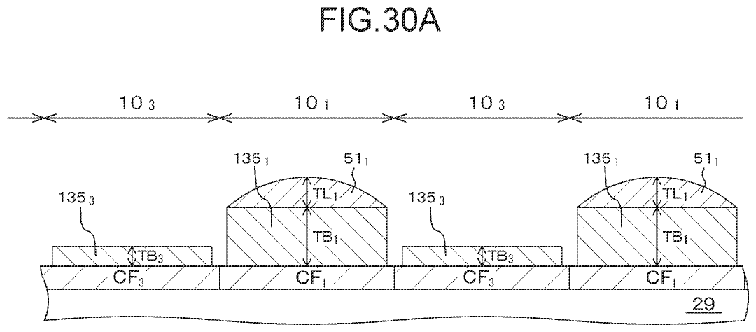

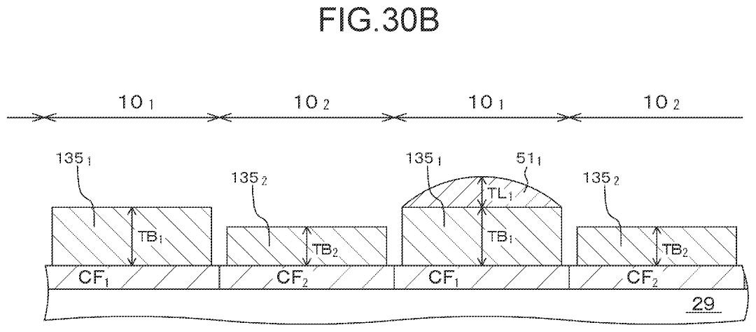

FIG. 27 is a schematic and partial sectional view of Modification-1 of the display device of Example 7. FIG. 28B is a schematic view of a lens unit and the like of one light emitting element unit in Modification-1 of the display device of Example 7 as viewed from above. FIG. 30A is a schematic and partial sectional view of a lens unit and a base in Modification-1 of the display device of Example 7 taken along the arrows A-A and C-C in FIG. 28B. FIG. 30B is a schematic and partial sectional view of the lens unit and the base taken along the arrows B-B and D-D in FIG. 28B. Modification-1 of the display device of Example 7 substantially has a configuration and a structure obtained by removing the second lens unit 51₂ and the third lens unit 51₃ from the display device described in Example 2.

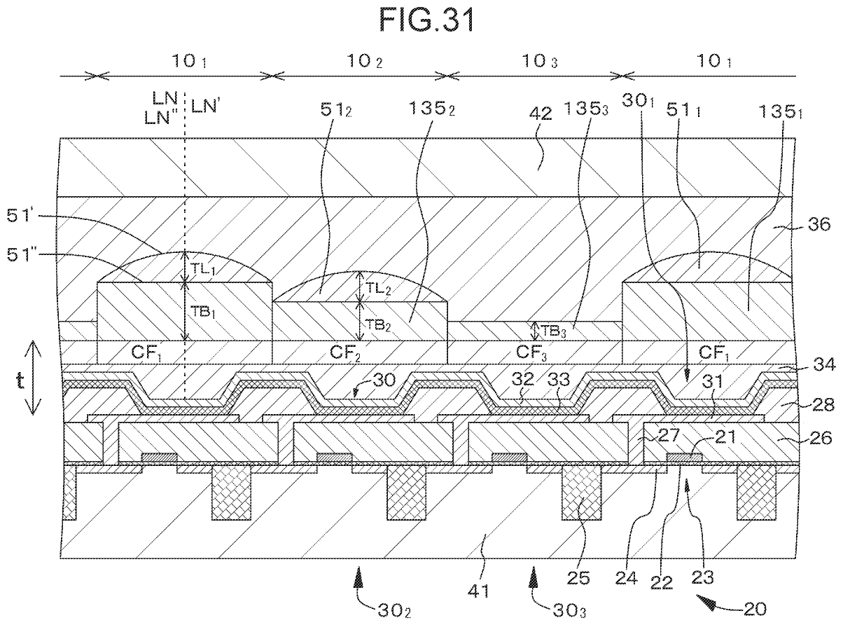

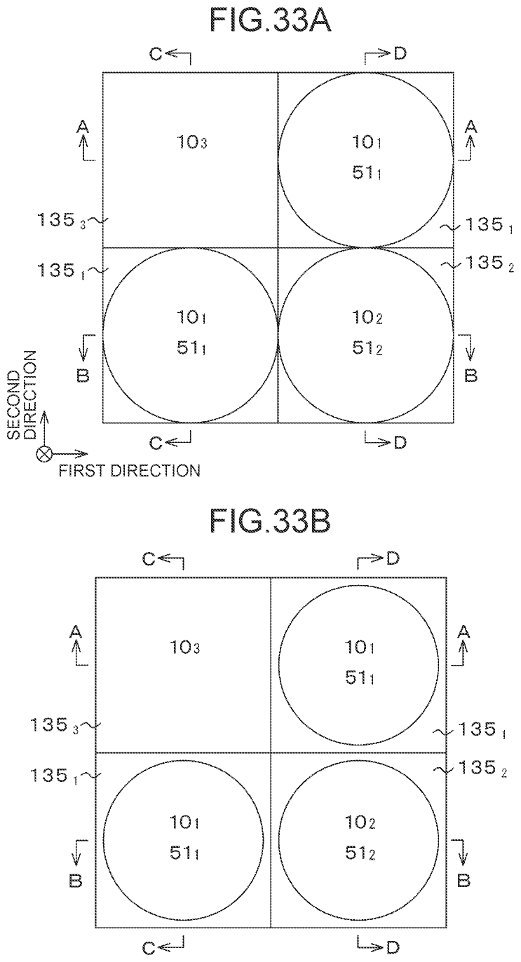

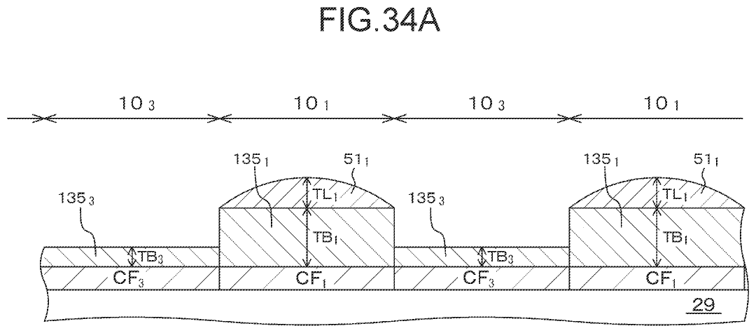

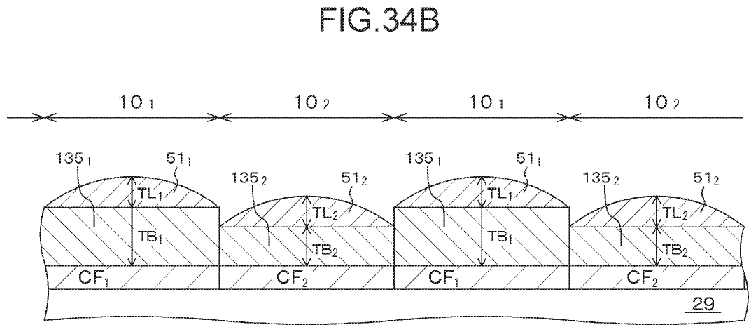

FIG. 31 is a schematic and partial sectional view of Modification-2 of the display device of Example 7. FIG. 33A is a schematic view of a lens unit and the like of one light emitting element unit as viewed from above. FIG. 34A is a schematic and partial sectional view of a lens unit and a base taken along the arrows A-A and C-C in FIG. 33A. FIG. 34B is a schematic and partial sectional view of the lens unit and the base taken along the arrows B-B and D-D in FIG. 33A.

In Modification-2 of the display device of Example 7,

a second lens unit 51₂ having a thickness TL₂ is provided on the second base 135₂, and

(TL₂+TB₂)<(TL₁+TB₁)

is satisfied.

In Modification-2 of the display device of Example 7,

each of the light emitting element units further includes a third light emitting element 10₃ having a third light emitting unit 30₃ that emits light of a third color, and

in each light emitting element unit,

a third base 135₃ having a thickness TB₃ is provided above the third light emitting unit 30₃, and

TB₃≤TB₂<(TL₁+TB₁)

is satisfied.

Modification-2 of the display device of Example 7 substantially has a configuration and a structure obtained by removing the third lens unit 51₃ from the display device described in Example 1.

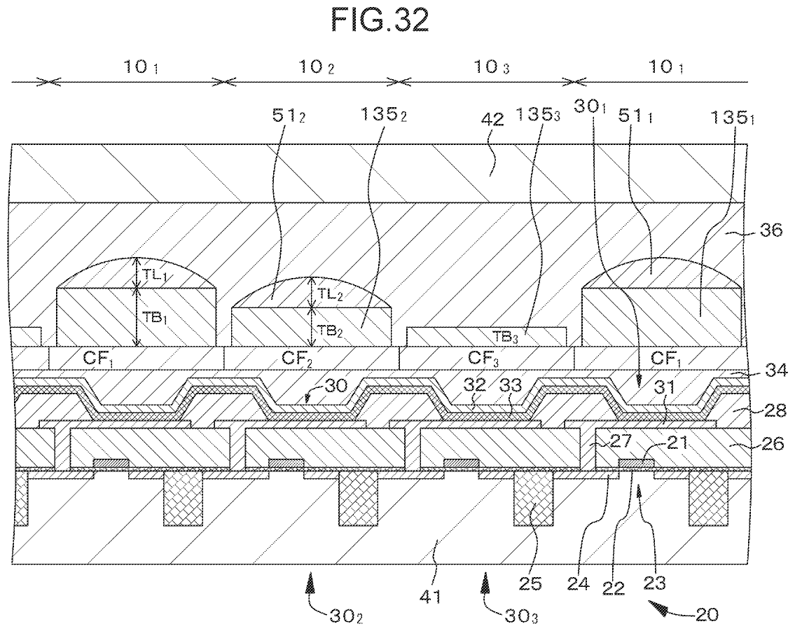

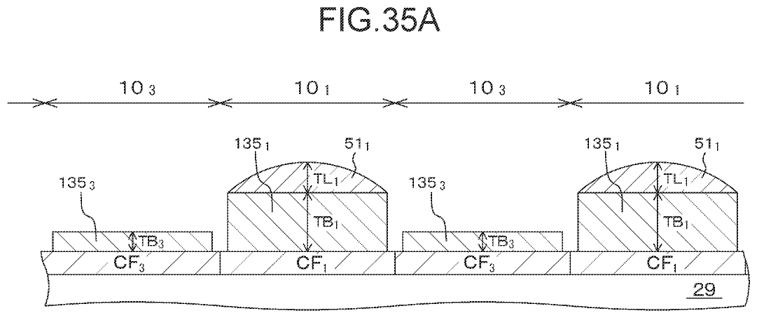

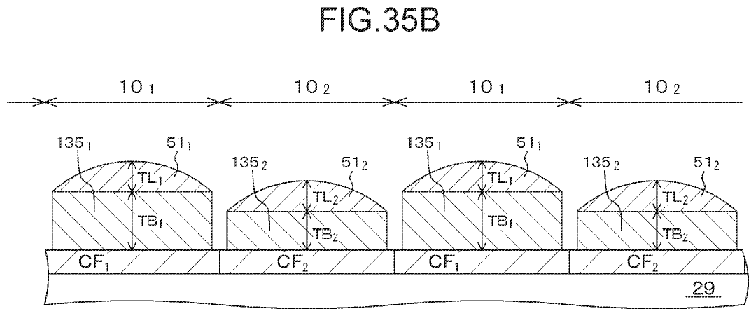

FIG. 32 is a schematic and partial sectional view of Modification-3 of the display device of Example 7. FIG. 33B is a schematic view of a lens unit and the like of one light emitting element unit in Modification-3 of Example 7 as viewed from above. FIG. 35A is a schematic and partial sectional view of a lens unit and a base in Modification-3 of the display device of Example 7 taken along the arrows A-A and C-C in FIG. 33B. FIG. 35B is a schematic and partial sectional view of the lens unit and the base taken along the arrows B-B and D-D in FIG. 33B. Modification-3 of the display device of Example 7 substantially has a configuration and a structure obtained by removing the third lens unit 51₃ from the display device described in Example 2.

In the display device of Example 7 or Modification-1 to Modification-3 of Example 7, by setting the refractive index of the material constituting the second base 135₂ and the refractive index of the material constituting the third base 135₃ to be higher than the refractive index of the material constituting the first base 135₁, the light extraction efficiency in the vicinity of the side surfaces of the second base 135₂ and the third base 135₃ is improved, and as a result, light in the vicinity of the outer edge of the second light emitting element and the third light emitting element can be effectively collected, the function as the lens unit can be imparted to the second base 135₂ and the third base 135₃ (or the third base 135₃), that is, the function of collecting light can be imparted, and as a result, the light extraction efficiency in the front direction of the entire light emitting element can be improved. In addition, by setting the refractive index of the material constituting the second base 135₂ and the refractive index of the material constituting the third base 135₃ to be lower than the refractive index of the material constituting the first base 135₁, the light extraction efficiency in the vicinity of the side surfaces of the first base 135₁ is improved, and as a result, light in the vicinity of the outer edge of the first base 135₁ can be effectively collected. In the example illustrated in FIG. 32, the space between the bases is filled with the sealing resin layer 36, and it is more effective to make the refractive index of the sealing resin layer 36 the lowest.

### Example 8

Example 8 is a modification of Examples 1 to 7.

An organic EL display device preferably includes a resonator structure to further improve the light extraction efficiency. Specifically, light emitted from the light emitting layer is caused to resonate between a first interface constituted by an interface between the first electrode and the organic layer (alternatively, in a structure in which an interlayer insulating layer is provided under the first electrode and a light reflection layer is provided under the interlayer insulating layer, an interface formed of an interface between the light reflection layer and the interlayer insulating layer) and a second interface constituted by an interface between the second electrode and the organic layer, and part of the light is emitted from the second electrode. Then, the following Formulas (1-1) and (1-2) can be satisfied where a distance from the maximum light emission position of the light emitting layer to the first interface is L₁, an optical distance is OL₁, a distance from the maximum light emission position of the light emitting layer to the second interface is L₂, an optical distance is OL₂, and m₁ and m₂ are integers.

0.7{−(Φ₁/(2π)+m₁}2×OL₁/λ≤1.2{−Φ₁/(2π)+m₁} (1-1)

0.7{−Φ₂/(2π)+m₂}≤2×OL₂/λ≤1.2{−Φ₂/(2π)+m₂} (1-2)

where

λ: a maximum peak wavelength of spectrum of light generated in the light emitting layer (alternatively, a desired wavelength of light generated in the light emitting layer)

Φ₁: a phase shift amount (unit: radian) of light reflected at the first interface where −2π<Φ₁≤0

Φ₂: a phase shift amount (unit: radian) of light reflected at the second interface where −2π<Φ₂≤0

The value of m₁ is a value of 0 or more, and the value of m₂ is a value of 0 or more independently of the value of m₁. Examples thereof include (m₁, m₂)=(0, 0), (m₁, m₂)=(0, 1), (m₁, m₂)=(1, 0), and (m₁, m₂)=(1, 1).

The distance L₁ from the maximum light emission position of the light emitting layer to the first interface refers to an actual distance (physical distance) from the maximum light emission position of the light emitting layer to the first interface. The distance L₂ from the maximum light emission position of the light emitting layer to the second interface refers to an actual distance (physical distance) from the maximum light emission position of the light emitting layer to the second interface. The optical distance is also referred to as an optical path length, and generally refers to n×L when a light beam passes through a medium having a refractive index n by a distance L. The same applies hereinafter. Thus,

OL₁=L₁×nₐᵥₑ

OL₂=L₂×nₐᵥₑ

are satisfied where nₐᵥₑ is an average refractive index. Here, the average refractive index nₐᵥₑ is obtained by summing up the product of the refractive index and the thickness of each layer constituting the organic layer (or, the organic layer, the first electrode, and the interlayer insulating layer) and dividing the sum by the thickness of the organic layer (or, the organic layer, the first electrode, and the interlayer insulating layer).

The light emitting element may be designed by determining a desired wavelength λ (specifically, for example, a red wavelength, a green wavelength, or a blue wavelength) in light generated in the light emitting layer and obtaining various parameters such as OL₁ and OL₂ in the light emitting element based on Formulas (1-1) and (1-2).

The first electrode or the light reflection layer and the second electrode absorb part of incident light and reflect the rest. Thus, a phase shift occurs in the reflected light. The phase shift amounts Φ₁ and Φ₂ may be obtained by measuring the values of the real number part and the imaginary number part of the complex refractive index of the materials constituting the first electrode or the light reflection layer and the second electrode using, for example, an ellipsometer, and performing calculation based on these values (see, for example, “Principles of Optic”, Max Born and Emil Wolf, 1974 (PERGAMON PRESS)). The refractive index of the organic layer, the interlayer insulating layer, or the like may also be determined by a measurement using an ellipsometer when the first electrode absorbs part of incident light and reflects the rest.

Examples of a material constituting the light reflection layer include aluminum, an aluminum alloy (for example, Al—Nd or Al—Cu), an Al/Ti stacked structure, an Al—Cu/Ti stacked structure, chromium (Cr), silver (Ag), and a silver alloy (for example, Ag—Cu, Ag—Pd—Cu, or Ag—Sm—Cu). The light reflecting layer may be formed by for example, a vapor deposition method including an electron beam vapor deposition method, a hot filament vapor deposition method, and a vacuum vapor deposition method; a sputtering method; a CVD method; an ion plating method; a plating method (electroplating method or electroless plating method); a lift-off method; a laser ablation method; a sol-gel method, or the like. Depending on the material constituting the light reflection layer, it is preferable to form a foundation layer made of, for example, TiN, to control the crystalline state of the light reflection layer to be formed.

In this manner, in the organic EL display device having the resonator structure, in practice, a red light emitting element including an organic layer that emits white light [in some cases, a red light emitting element configured by combining an organic layer that emits white light and a red color filter layer (or an intermediate layer that functions as a red color filter layer)] causes red light emitted from the light emitting layer to resonate, and emits reddish light (light having a light spectrum peak in a red region) from the second electrode. A green light emitting element including an organic layer that emits white light [in some cases, a green light emitting element configured by combining an organic layer that emits white light and a green color filter layer (or an intermediate layer that functions as a green color filter layer)] causes green light emitted from the light emitting layer to resonate, and emits greenish light (light having a light spectrum peak in a green region) from the second electrode. A blue light emitting element including an organic layer that emits white light [in some cases, a blue light emitting element configured by combining an organic layer that emits white light and a blue color filter layer (or an intermediate layer that functions as a blue color filter layer)] causes blue light emitted from the light emitting layer to resonate, and emits bluish light (light having a light spectrum peak in a blue region) from the second electrode. That is, the desired wavelength λ (specifically, a red wavelength, a green wavelength, or a blue wavelength) of light generated in the light emitting layer may be determined, and various parameters such as OL₁ and OL₂ in each of the red light emitting element, the green light emitting element, and the blue light emitting element may be obtained based on Formulas (1-1) and (1-2) to design each light emitting element. For example, paragraph [(0041] of JP 2012-216495 A discloses an organic EL element having a resonator structure in which an organic layer is a resonance unit, and it describes that a film thickness of the organic layer is preferably 80 nm or more and 500 nm or less, and more preferably 150 nm or more and 350 nm or less because a distance from a light emitting point (light emitting surface) to a reflection surface can be appropriately adjusted. Usually, the value of (L₁+L₂=L₀) is different in the red light emitting element, the green light emitting element, and the blue light emitting element.

The light emitting element 10 has a resonator structure in which the organic layer 33 is a resonance unit. To appropriately adjust the distance from the light emitting surface to the reflection surface (specifically, the distance from the light emitting surface to the first electrode 31 and the second electrode 32), the thickness of the organic layer 33 is preferably 8×10⁻⁸ m or more and 5×10⁻⁷ m or less, and more preferably 1.5×10⁻⁷ m or more and 3.5×10⁻⁷ m or less. In an organic EL display device having a resonator structure, in practice, the red light emitting element 10₃ causes red light emitted from the light emitting layer to resonate, and emits reddish light (light having a light spectrum peak in a red region) from the second electrode 32. The green light emitting element 10₂ causes green light emitted from the light emitting layer to resonate, and emits greenish light (light having a light spectrum peak in a green region) from the second electrode 32. The blue light emitting element 10₁ causes blue light emitted from the light emitting layer to resonate, and emits bluish light (light having a light spectrum peak in a blue region) from the second electrode 32.

When the resonator structure is provided, the organic layer 33 may be a resonator structure sandwiched between the first electrode 31 and the second electrode 32, or a light reflection layer 61 may be formed below the first electrode 31 (on the first substrate 41 side), and the organic layer 33 may be a resonator structure sandwiched between the light reflection layer 61 and the second electrode 32. That is, when the light reflection layer 61 is provided on the base body 26, an interlayer insulating layer 62 is provided on the light reflection layer 61, and the first electrode 31 is provided on the interlayer insulating layer 62, the first electrode 31, the light reflection layer 61, and the interlayer insulating layer 62 may be made of the above-described materials. The light reflection layer 61 may be connected to the contact hole (contact plug) 27 but does not have to be connected to the contact hole 27.

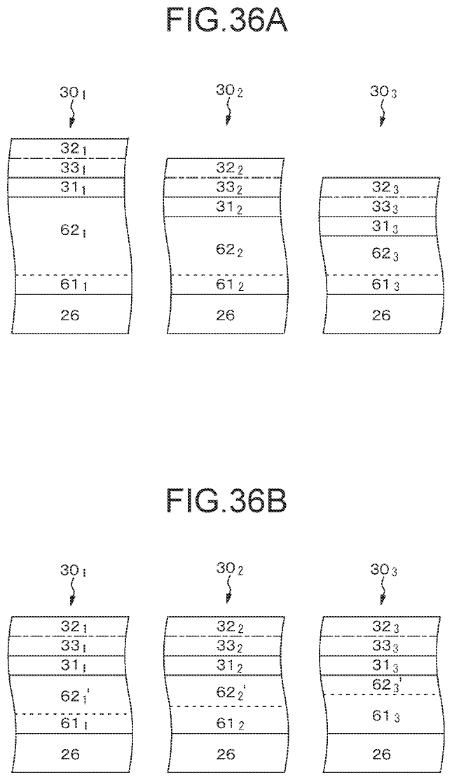

Hereinafter, the resonator structure will be described based on first to eighth examples with reference to FIGS. 36A (first example), 36B (second example), 37A (third example), 37B (fourth example), 38A (fifth example), 38B (sixth example), 39A (seventh example), and 39B and 39C (eighth example). In the first to fourth examples and the seventh example, the first electrode has the same thickness in the light emitting units, and the second electrode has the same thickness in the light emitting units. In the fifth to sixth examples, the first electrode has different thicknesses in the light emitting units, and the second electrode has the same thickness in the light emitting units. In the eighth example, the first electrode may have different thicknesses or may have the same thickness in the light emitting units, and the second electrode has the same thickness in the light emitting units.

In the following description, the light emitting units constituting the first light emitting element 10₁, the second light emitting element 10₂, and the third light emitting element 10₃ are denoted by reference numerals 30₁, 30₂, 30₃, the first electrode is denoted by reference numerals 31₁, 31₂, 31₃, the second electrode is denoted by reference numerals 32₁, 32₂, 32₃, the organic layer is denoted by reference numerals 33₁, 33₂, 33₃, the light reflection layer is denoted by reference numerals 61₁, 61₂, 61₃, and the interlayer insulating layer is denoted by reference numerals 62₁, 62₂, 62₃, 62₁′, 62₂′, 62₃′. In the following description, materials to be used are examples, and they may be changed as appropriate.

In the illustrated examples, the resonator lengths of the first light emitting element 10₁, the second light emitting element 10₂, and the third light emitting element 10₃ derived from Formulas (1-1) and (1-2) are shortened in the order of the first light emitting element 10₁, the second light emitting element 10₂, and the third light emitting element 10₃, that is, the value of L₀ is shortened in the order of the first light emitting element 10₁, the second light emitting element 10₂, and the third light emitting element 10₃, but the present invention is not limited thereto, and the optimum resonator length may be determined by appropriately setting the values of m₁ and m₂.

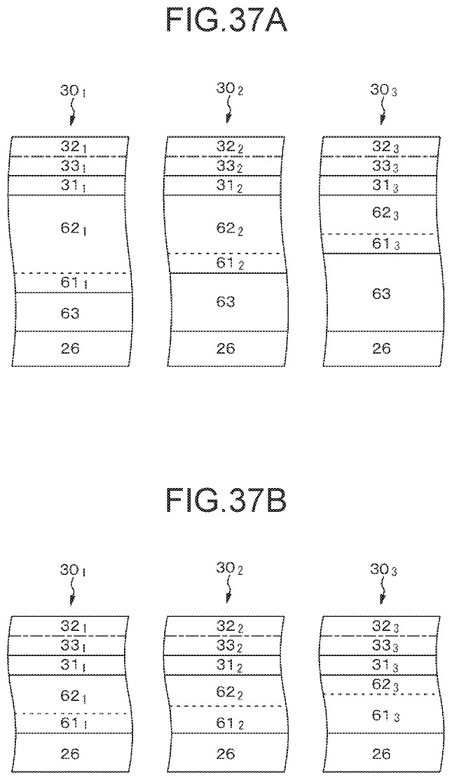

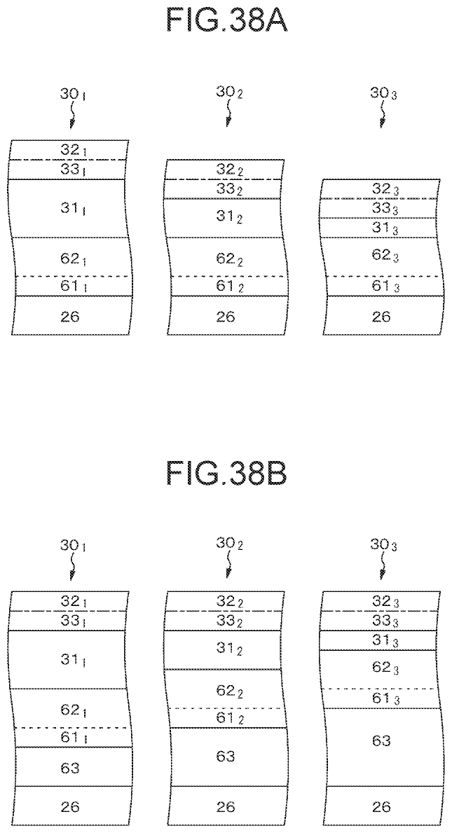

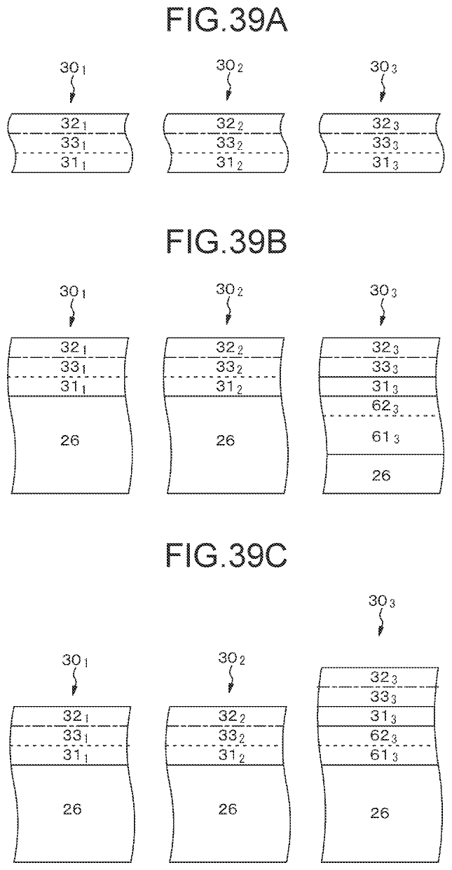

FIG. 36A is a conceptual diagram of light emitting elements of a first example having a resonator structure. FIG. 36B is a conceptual diagram of light emitting elements of a second example having a resonator structure. FIG. 37A is a conceptual diagram of light emitting elements of a third example having a resonator structure. FIG. 37B is a conceptual diagram of light emitting elements of a fourth example having a resonator structure. In some of the first to sixth examples and the eighth example, the interlayer insulating layers 62, 62′ are formed under the first electrode 31 of the light emitting unit 30, and the light reflection layer 61 is formed under the interlayer insulating layers 62, 62′. In the first to fourth examples, the thicknesses of the interlayer insulating layers 62, 62′ are different in the light emitting units 30₁, 30₂, 30₃. By appropriately setting the thicknesses of the interlayer insulating layers 62₁, 62₂, 62₃, 62₁′, 62₂′, 62₃′, it is possible to set an optical distance at which optimum resonance is generated with respect to the emission wavelength of the light emitting unit 30.

In the first example, in the light emitting units 30₁, 30₂, 30₃, the first interface (indicated by a dotted line in the drawings) is at the same level, while the level of the second interface (indicated by one-dot chain line in the drawings) is different in the light emitting units 30₁, 30₂, 30₃. In the second example, the first interface is set to different levels in the light emitting units 30₁, 30₂, 30₃, while the level of the second interface is the same in the light emitting units 30₁, 30₂, 30₃.

In the second example, the interlayer insulating layers 62₁′, 62₂′, 62₃′ are made of an oxide film in which the surface of the light reflection layer 61 is oxidized. The interlayer insulating layer 62′ made of an oxide film is made of, for example, aluminum oxide, tantalum oxide, titanium oxide, magnesium oxide, zirconium oxide, or the like depending on the material constituting the light reflection layer 61. The surface of the light reflection layer 61 may be oxidized by, for example, the following method. That is, the first substrate 41 on which the light reflection layer 61 is formed is immersed in an electrolytic solution filled in a container. A cathode is disposed to face the light reflection layer 61. Then, the light reflection layer 61 is anodized using the light reflection layer 61 as an anode. The film thickness of the oxide film formed through the anodization is proportional to the potential difference between the light reflection layer 61 as an anode and the cathode. Thus, anodization is performed in a state where voltages corresponding to the light emitting units 30₁, 30₂, 30₃ are applied to the light reflection layers 61₁, 62₂, 62₃, respectively. As a result, the interlayer insulating layers 62₁′, 62₂′, 62₃′ made of oxide films having different thicknesses can be collectively formed on the surface of the light reflection layer 61. The thicknesses of the light reflection layers 61₁, 62₂, 62₃ and the thicknesses of the interlayer insulating layers 62₁′, 62₂′, 62₃′ are different in the light emitting units 30₁, 30₂, 30₃.

In the third example, a foundation film 63 is disposed under the light reflection layer 61, and the foundation film 63 has different thicknesses in the light emitting units 30₁, 30₂, 30₃. That is, in the illustrated example, the thickness of the foundation film 63 is increased in the order of the light emitting unit 30₁, the light emitting unit 30₂, and the light emitting unit 30₃.

In the fourth example, the thicknesses of the light reflection layers 61₁, 61₂, 61₃ at the time of film formation are different in the light emitting units 30₁, 30₂, 30₃. In the third and fourth examples, the second interface is set to the same level in the light emitting units 30₁, 30₂, 30₃, while the level of the first interface is different in the light emitting units 30₁, 30₂, 30₃.

In the fifth and sixth examples, the thicknesses of the first electrodes 31₁, 31₂, 31₃ are different in the light emitting units 30₁, 30₂, 30₃. The light reflection layer 61 has the same thickness in each light emitting unit 30.

In the fifth example, the level of the first interface is the same in the light emitting units 30₁, 30₂, 30₃, while the level of the second interface is different in the light emitting units 30₁, 30₂, 30₃.

In the sixth example, the foundation film 63 is disposed under the light reflection layer 61, and the foundation film 63 has different thicknesses in the light emitting units 30₁, 30₂, 30₃. That is, in the illustrated example, the thickness of the foundation film 63 is increased in the order of the light emitting unit 30₁, the light emitting unit 30₂, and the light emitting unit 30₃. In the sixth example, in the light emitting units 30₁, 30₂, 30₃, the second interface is set to the same level, while the level of the first interface is different in the light emitting units 30₁, 30₂, 30₃.

In the seventh example, the first electrodes 31₁, 31₂, 31₃ also serve as light reflection layers, and the optical constant (specifically, the phase shift amount) of the material constituting the first electrodes 31₁, 31₂, 31₃ is different in the light emitting units 30₁, 30₂, 30₃. For example, the first electrode 31₁ of the light emitting unit 30₁ may be made of copper (Cu), and the first electrode 31₂ of the light emitting unit 30₂ and the first electrode 31₃ of the light emitting unit 30₃ may be made of aluminum (Al).

In the eighth example, the first electrodes 31₁, 31₂ also serve as light reflection layers, and the optical constant (specifically, the phase shift amount) of the material constituting the first electrodes 31₁, 31₂ is different in the light emitting units 30₁, 30₂. For example, the first electrode 31₁ of the light emitting unit 30₁ may be made of copper (Cu), and the first electrode 31₂ of the light emitting unit 30₂ and the first electrode 31₃ of the light emitting unit 30₃ may be made of aluminum (Al). In the eighth example, for example, the seventh example is applied to the light emitting units 30₁, 30₂, and the first example is applied to the light emitting unit 30₃. The thicknesses of the first electrodes 31₁, 31₂, 31₃ may be different or the same.

### Example 9

Example 9 is a modification of Examples 1 to 8. In Example 9, a relationship between the normal line LN passing through the center of the light emitting unit, the normal line LN′ passing through the center of the optical path control unit (lens unit 51), and the normal line LN″ passing through the center of the wavelength selection unit (color filter layer CF), and modifications thereof will be described.

In a display panel (region for displaying an image) constituting a display device of Example 9, a reference point (reference region) P is assumed, and the distance (offset amount) D₀ between the normal line LN passing through the center of the light emitting unit and the normal line LN′ passing through the center of the lens unit depends on the distance D₁ from the reference point (reference region) P to the normal line LN passing through the center of the light emitting unit. The distance D₀ may be changed in a plurality of light emitting elements constituting one pixel.

The reference point P may be assumed in the display panel constituting the display device. In this case, the reference point P may be configured not to be located in the center region of the display panel. Alternatively, the reference point P may be configured to be located in the center region of the display panel. Further, in these cases, one reference point P may be assumed, or a plurality of reference points P may be assumed. These cases may have a configuration in which the value of the distance D₀ is 0 (see FIG. 1 for example) in some light emitting elements, and the value of the distance D₀ is not 0 in the remaining light emitting elements.

Alternatively, when one reference point P is assumed, a configuration in which the reference point P is not included in the center region of the display panel may be taken, or a configuration in which the reference point P is included in the center region of the display panel may be taken. When a plurality of reference points P are assumed, a configuration in which at least one reference point P is not included in the center region of the display panel may be taken.

Alternatively, the reference point P may be assumed to be outside the display panel. In this case, one reference point P may be assumed, or a plurality of reference points P may be assumed. These cases may have a configuration in which the value of the distance D₀ is not 0 in all the light emitting elements.

Further, light emitted from each light emitting element and passing through the lens unit may be caused to converge (collected) in a certain region of a space outside the display device, or light emitted from each light emitting element and passing through the lens unit may be diverged in a space outside the display device, or light emitted from each light emitting element and passing through the lens unit may be parallel light.

Further, in the display device of Example 9, the value of the distance (offset amount) D₀ may be different according to the location occupied by the light emitting element in the display panel. Specifically, a mode is taken in which

the reference point P is set, and

the plurality of light emitting elements are arranged in a first direction and a second direction different from the first direction,

when a distance from the reference point P to a normal line LN passing through the center of the light emitting unit is D₁, values of the distance D₀ in the first direction and the second direction are D_{0-X} and D_{0-Y}, respectively, and values of the distance D₁ in the first direction and the second direction are D_{1-X} and D_{1-Y}, respectively,

D_{0-X} changes linearly with respect to a change of D_{1-X}, and D_{0-Y} changes linearly with respect to a change of D_{1-Y}, or

D_{0-X} changes linearly with respect to a change of D_{1-X}, and D_{0-Y} changes nonlinearly with respect to a change of D_{1-Y}, or

D_{0-X} changes nonlinearly with respect to a change of D_{1-X}, and D_{0-Y} changes linearly with respect to a change of D_{1-Y}, or

D_{0-X} changes nonlinearly with respect to a change of D_{1-X}, and D_{0-Y} changes nonlinearly with respect to a change of D_{1-Y}.

Alternatively, the display device of Example 9 may have a mode in which

a reference point P is set, and

when a distance from the reference point P to a normal line LN passing through the center of the light emitting unit is D₁, a value of the distance D₀ increases as a value of the distance D₁ increases.

Here, the fact that D_{0-X} changes linearly with respect to a change of D_{1-X}, and D_{0-Y} changes linearly with respect to a change of D_{1-Y} means that

D_{0-X}=k_{X}·D_{1-X}

D_{0-Y}=k_{Y}·D_{1-Y}

are formed. Here, k_{X} and k_{Y} are constants. That is, D_{0-X} and D_{0-Y} change based on a linear function. On the other hand, the fact that D_{0-X} changes nonlinearly with respect to a change of D_{1-X}, and D_{0-Y} changes linearly with respect to a change of D_{1-Y} means that

D_{0-X}=f_{X}(D_{1-X})

D_{0-Y}=f_{Y}(D_{1-Y})

are formed. Here, f_{X} and f_{Y} are functions that are not linear functions (for example, a quadratic function).

Alternatively, the change of D_{0-X} with respect to a change of D_{1-X} and the change of D_{0-Y} with respect to a change of D_{1-Y} may also be stepwise changes. In this case, when the stepwise change is viewed as a whole, the change may be a linear change, or the change may be a nonlinear change. Further, when the display panel is divided into M×N regions, the change of D_{0-X} with respect to a change of D_{1-X} and the change of D_{0-Y} with respect to a change of D_{1-Y} may be unchanged or constant in one region. The number of light emitting elements in one region may be, but is not limited to, 10×10.

Further, in the display device of Example 9, the orthographic projection image of the lens unit may match up with the orthographic projection image of the wavelength selection unit, or may be included in the orthographic projection image of the wavelength selection unit. By adopting the latter configuration, the occurrence of color mixing between adjacent light emitting elements can be reliably inhibited. Further, in these cases, the light emitting element in which the value of the distance D₀ is not 0 may have,

(a) a mode in which the normal line LN″ passing through the center of the wavelength selection unit matches up with the normal line LN passing through the center of the light emitting unit,

(b) a mode in which the normal line LN″ passing through the center of the wavelength selection unit matches up with the normal line LN′ passing through the center of the lens unit, and

(c) a mode in which the normal line LN″ passing through the center of the wavelength selection unit does not match up with the normal line LN passing through the center of the light emitting unit, and the normal line LN″ passing through the center of the wavelength selection unit does not match up with the normal line LN′ passing through the center of the lens unit. By adopting (b) or (c) the latter configuration, occurrence of color mixing between adjacent light emitting elements can be reliably inhibited.

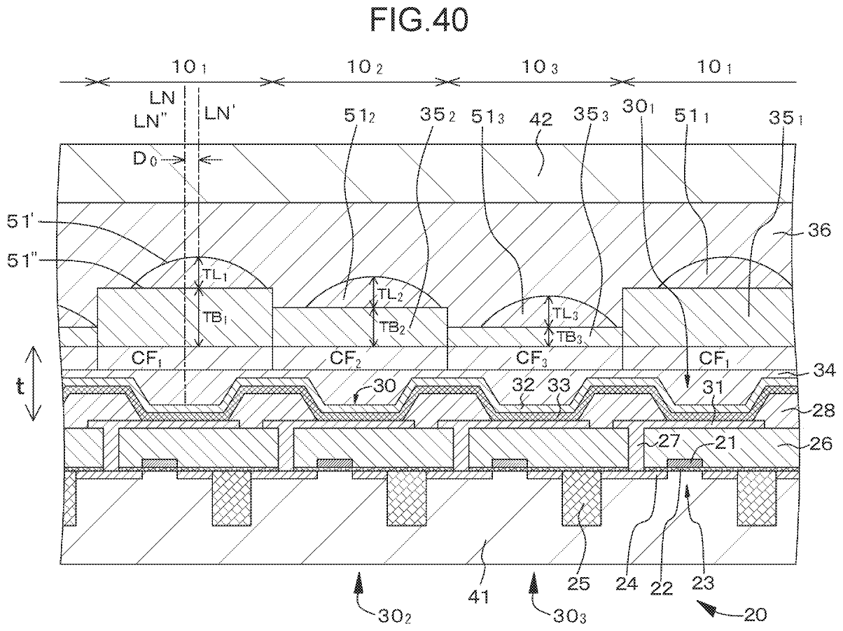

FIG. 40 is a schematic and partial sectional view of the display device of Example 9.

In Example 9, when the distance (offset amount) between the normal line LN passing through the center of the light emitting unit and the normal line LN′ passing through the center of the lens unit is D₀, the value of the distance (offset amount) D₀ is not 0 in at least some of the light emitting elements 10 provided in the display panel constituting the display device. In the display device, the reference point (reference region) P is assumed, and the distance D₀ may depend on the distance D₁ from the reference point (reference region) to the normal line LN passing through the center of the light emitting unit.

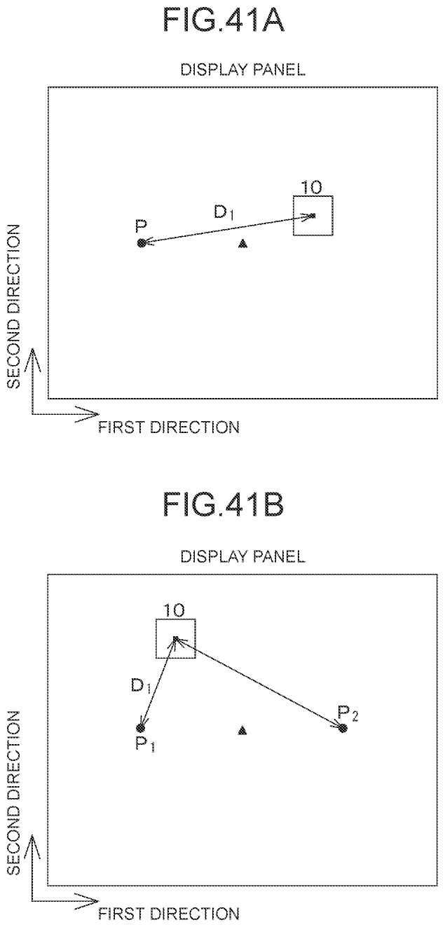

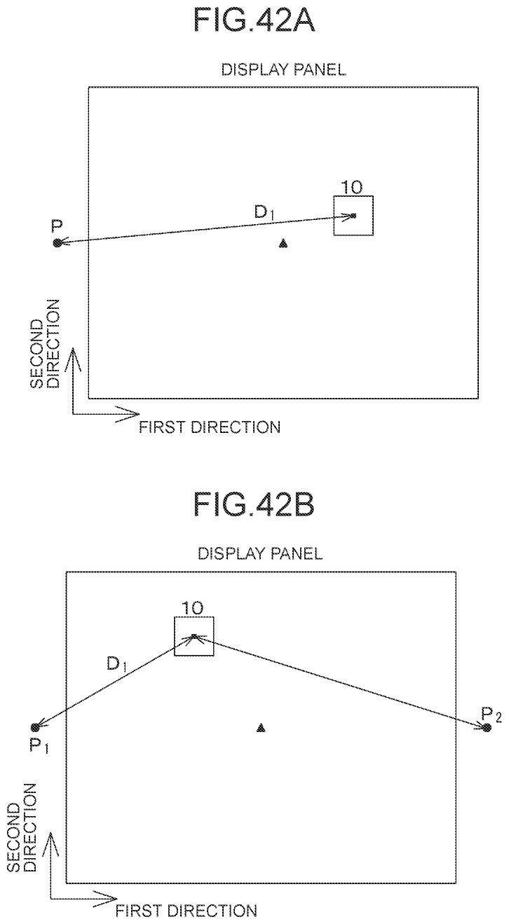

In the display device of Example 9, the reference point P is assumed in the display panel. However, the reference point P is not located (not included) in the center region of the display panel. In FIGS. 41A, 41B, 42A, and 42B, the center region of the display panel is indicated by a black triangle, the light emitting element 10 is indicated by a square, the center of the light emitting unit 30 is indicated by a black square, and the reference point P is indicated by a black circle. The positional relationship between the light emitting element 10 and the reference point P is schematically illustrated in FIG. 41A, in which one reference point P is assumed. Since the reference point P may include a certain extent of spread, the value of the distance D₀ is 0 in some light emitting elements 10 (specifically, one or a plurality of light emitting elements 10 included in the reference point P), and the value of the distance D₀ is not 0 in the remaining light emitting elements 10. The value of the distance (offset amount) D₀ varies depending on the location occupied by the light emitting element in the display panel.

In the display devices of Examples, light emitted from each light emitting element 10 and passing through the lens unit 51 is caused to converge (collected) to a certain region in a space outside the display device. Alternatively, light emitted from each light emitting element 10 and passing through the lens unit 51 diverges in a space outside the display device. Alternatively, light emitted from each light emitting element 10 and passing through the lens unit 51 is parallel light. Whether the light passing through the lens unit 51 is to be converged light, divergent light, or parallel light is based on the specifications required for the display device. The power or the like of the lens unit 51 may be designed based on these specifications. When the light passing through the lens unit 51 is converged light, the location of the space in which the image emitted from the display device is formed may be on the normal line of the reference point P or is not on the normal line of the reference point P in some cases, which depends on the specifications required for the display device. An optical system through which the image emitted from the display device passes may be arranged to control a display dimension, a display location, and the like of the image emitted from the display device. What kind of optical system is disposed depends on the specifications required for the display device, and for example, an imaging lens system may be exemplified.

In the display device of Example 9, the reference point P is set, and the plurality of light emitting elements 10 are arranged in a first direction (specifically, X direction) and a second direction (specifically, Y direction) different from the first direction. When the distance from the reference point P to the normal line LN passing through the center of the light emitting unit 30 is D₁, values of the distance D₀ in the first direction (X direction) and the second direction (Y direction) are D_{0-X} and D_{0-Y}, respectively, and values of the distance D₁ in the first direction (X direction) and the second direction (Y direction) are D_{1-X} and D_{1-Y}, respectively, the display device may have

[A] a design in which D_{0-X} changes linearly with respect to a change of D_{1-X}, and D_{0-Y} changes linearly with respect to a change of D_{1-Y},

[B] a design in which D_{0-X} changes linearly with respect to a change of D_{1-X}, and D_{0-Y} changes nonlinearly with respect to a change of D_{1-Y},

[C] a design in which D_{0-X} changes nonlinearly with respect to a change of D_{1-X}, and D_{0-Y} changes linearly with respect to a change of D_{1-Y}, or

[D] a design in which D_{0-X} changes nonlinearly with respect to a change of D_{1-X}, and D_{0-Y} changes nonlinearly with respect to a change of D_{1-Y}.

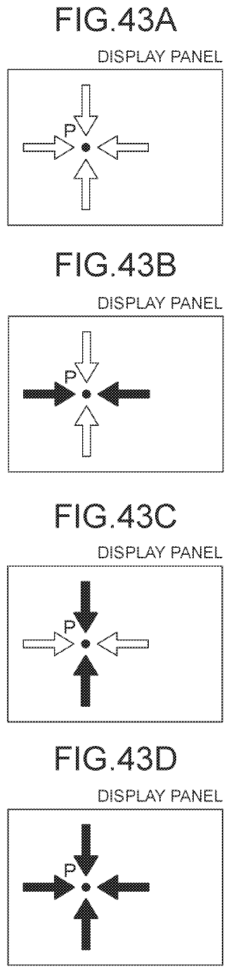

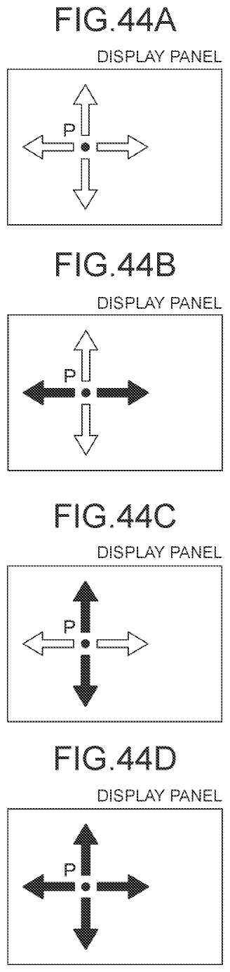

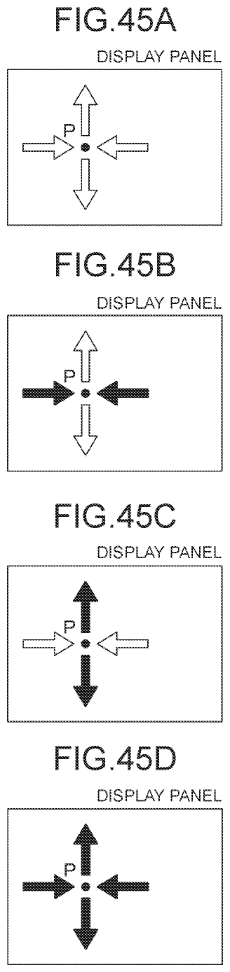

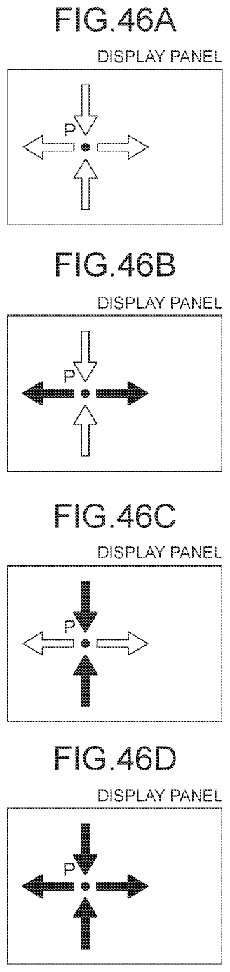

FIGS. 43A, 43B, 43C, 43D, 44A, 44B, 44C, 44D, 45A, 45B, 45C, 45D, 46A, 46B, 46C, and 46D schematically illustrate a change of D_{0-X} with respect to a change of D_{1-X} and a change of D_{0-Y} with respect to a change of D_{1-Y}. In these drawings, outlined arrows indicate linear changes and black arrows indicate non-linear changes. When the arrows are directed to the outside of the display panel, it indicates that light passing through the lens unit 51 is divergent light, and when the arrows are directed to the inside of the display panel, it indicates that light passing through the lens unit 51 is converged light or parallel light.

Alternatively, when the reference point P is set and the distance from the reference point P to the normal line LN passing through the center of the light emitting unit 30 is D₁, the value of the distance D₀ may be designed to increase as the value of the distance D₁ increases.

That is, the changes of D_{0-X}, D_{0-Y} depending on the changes of D_{1-X}, D_{1-Y} may be determined based on the specifications required for the display device.

The display device of Example 9 may have a configuration in which a plurality of reference points P are assumed. The plurality of reference points P are disposed in the display area of the display panel. The positional relationship between the light emitting element 10 and the reference points P₁, P₂ is schematically illustrated in FIG. 41B, in which two reference points P₁, P₂ are assumed. Specifically, with the center of the display panel as a symmetry point, the two reference points P₁, P₂ are arranged in two-fold rotational symmetry. Here, at least one reference point P is not included in the center region of the display panel. In the illustrated example, two reference points P₁, P₂ are not included in the center region of the display panel. The value of the distance D₀ is 0 in some light emitting elements (specifically, one or a plurality of light emitting elements included in the reference point P), and the value of the distance D₀ is not 0 in the remaining light emitting elements. For the distance D₁ from the reference point P to the normal line LN passing through the center of the light emitting unit 30, the distance between the reference point P closer to the normal line LN passing through the center of a certain light emitting unit 30 is defined as the distance D₁.

In the display device of a modification of Example 9, the reference point P is assumed to be outside the display panel. FIGS. 42A and 42B schematically illustrate the positional relationship between the light emitting element 10 and the reference points P, P₁, P₂. However, a configuration in which one reference point P is assumed may be taken (see FIG. 42A), or a configuration in which a plurality of reference points P (FIG. 42B illustrates two reference points P₁, P₂) is assumed may be taken. With the center of the display panel as a symmetry point, the two reference points P₁, P₂ are arranged in two-fold rotational symmetry. The value of the distance D₀ is not 0 in all the light emitting elements. For the distance D₁ from the reference point P to the normal line LN passing through the center of the light emitting unit 30, the distance between the reference point P closer to the normal line LN passing through the center of a certain light emitting unit 30 is defined as the distance D₁. In these cases, light emitted from each light emitting element 10 and passing through the lens unit 51 is caused to converge (collected) to a certain region of the space outside the display device. Alternatively, light emitted from each light emitting element 10 and passing through the lens unit 51 diverges in a space outside the display device.

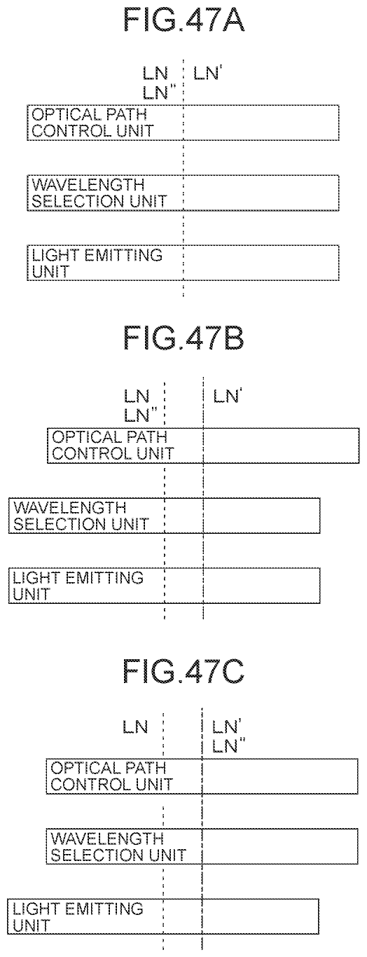

As illustrated in the conceptual diagram of FIG. 47A, the normal line LN passing through the center of the light emitting unit, the normal line LN″ passing through the center of the wavelength selection unit, and the normal line LN′ passing through the center of the lens unit 51 may match up with each other. That is, D₀=d₀=0 (See FIG. 1 for example). As described above, d₀ is the distance (offset amount) between the normal line LN passing through the center of the light emitting unit and the normal line LN″ passing through the center of the wavelength selection unit.

In the example illustrated in FIG. 40, as illustrated in the conceptual diagram of FIG. 47B, the normal line LN passing through the center of the light emitting unit matches up with the normal line LN″ passing through the center of the wavelength selection unit, but the normal line LN passing through the center of the light emitting unit and the normal line LN″ passing through the center of the wavelength selection unit do not match up with the normal line LN′ passing through the center of the lens unit 51. That is, D₀≠d₀=0.

Further, as illustrated in the conceptual diagram of FIG. 47C, the normal line LN passing through the center of the light emitting unit does not match up with the normal line LN″ passing through the center of the wavelength selection unit or the normal line LN′ passing through the center of the lens unit 51, and the normal line LN″ passing through the center of the wavelength selection unit matches up with the normal line LN′ passing through the center of the lens unit 51 in some cases. That is, D₀=d₀>0.

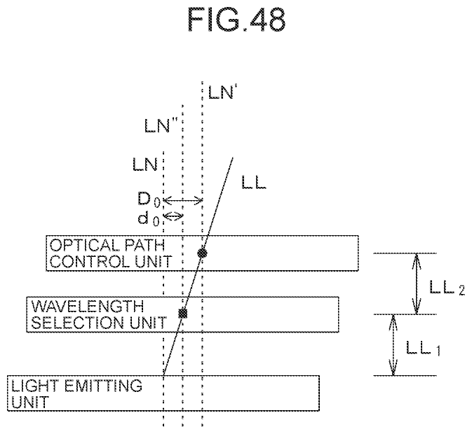

Further, as illustrated in the conceptual diagram of FIG. 48, the normal line LN passing through the center of the light emitting unit does not match up with the normal line LN″ passing through the center of the wavelength selection unit or the normal line LN′ passing through the center of the lens unit 51, and the normal line LN′ passing through the center of the lens unit 51 does not match up with the normal line LN passing through the center of the light emitting unit or the normal line LN″ passing through the center of the wavelength selection unit in some cases. Here, the center (indicated by a black square in FIG. 48) of the wavelength selection unit is preferably located on a straight line LL connecting the center of the light emitting unit and the center (indicated by a black circle in FIG. 48) of the lens unit 51. Specifically, when the distance from the center of the light emitting unit in the thickness direction to the center of the wavelength selection unit is LL₁, and the distance from the center of the wavelength selection unit in the thickness direction to the center of the lens unit 51 is LL₂,

D₀>d₀>0

is satisfied, and considering variations in production,

d₀:D₀=LL₁:(LL₁+LL₂)

is preferably satisfied.

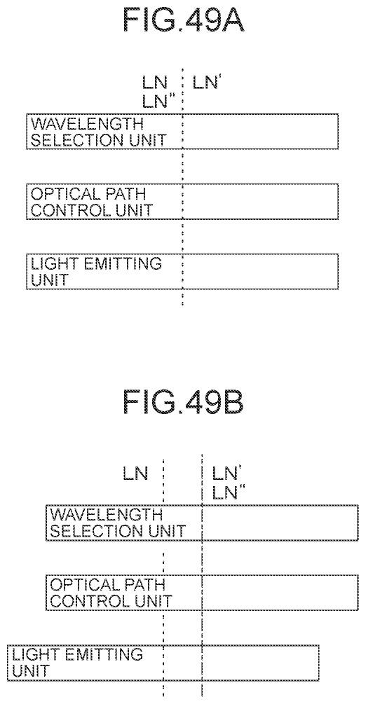

Alternatively, as illustrated in the conceptual diagram of FIG. 49A, the normal line LN passing through the center of the light emitting unit, the normal line LN″ passing through the center of the wavelength selection unit, and the normal line LN′ passing through the center of the lens unit 51 match up with each other in some cases. That is, D₀=d₀=0.

Further, as illustrated in the conceptual diagram of FIG. 49B, the normal line LN passing through the center of the light emitting unit does not match up with the normal line LN″ passing through the center of the wavelength selection unit or the normal line LN′ passing through the center of the lens unit 51, and the normal line LN″ passing through the center of the wavelength selection unit matches up with the normal line LN′ passing through the center of the lens unit 51 in some cases. That is, D₀=d₀>0.

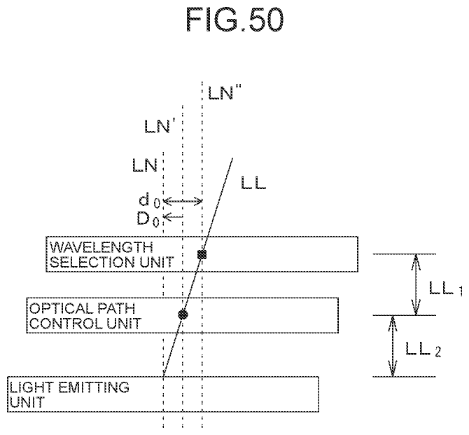

Further, as illustrated in the conceptual diagram of FIG. 50, the normal line LN passing through the center of the light emitting unit does not match up with the normal line LN″ passing through the center of the wavelength selection unit or the normal line LN′ passing through the center of the lens unit 51, and the normal line LN′ passing through the center of the lens unit 51 does not match up with the normal line LN passing through the center of the light emitting unit or the normal line LN″ passing through the center of the wavelength selection unit in some cases. Here, the center of the wavelength selection unit is preferably located on the straight line LL connecting the center of the light emitting unit and the center of the lens unit 51. Specifically, when the distance from the center of the light emitting unit in the thickness direction to the center (indicated by a black square in FIG. 50) of the wavelength selection unit is LL₁, and the distance from the center of the wavelength selection unit in the thickness direction to the center (indicated by a black circle in FIG. 50) of the lens unit 51 is LL₂,

d₀>D₀>0

is satisfied, and considering variations in production,

D₀:d₀=LL₂:(LL₁+LL₂)

is preferably satisfied.

The present disclosure has been described above based on preferred Examples. The present disclosure is not limited to these Examples. The configurations and structures of the display device (organic EL display device) and the light emitting element (organic EL element) described in Examples are examples and may be appropriately changed, and the production method of the display device is also an example and may be appropriately changed. In Examples, the light emitting element driving unit is composed of a MOSFET, but it may be composed of a TFT. The first electrode and the second electrode may have a single-layer structure or a multilayer structure. In Examples, the display device that emits light of three colors is configured, but a display device that emits light of four colors or more may be configured, a display device that emits light of three colors and white light may be configured, or a display device that emits light of two colors (for example, red and green) may be configured.

A light absorption layer (black matrix layer) may be formed between color filter layers CF of adjacent light emitting elements. The black matrix layer includes, for example, a black resin film (specifically, for example, a black polyimide-based resin) mixed with a black colorant and having an optical density of 1 or more.

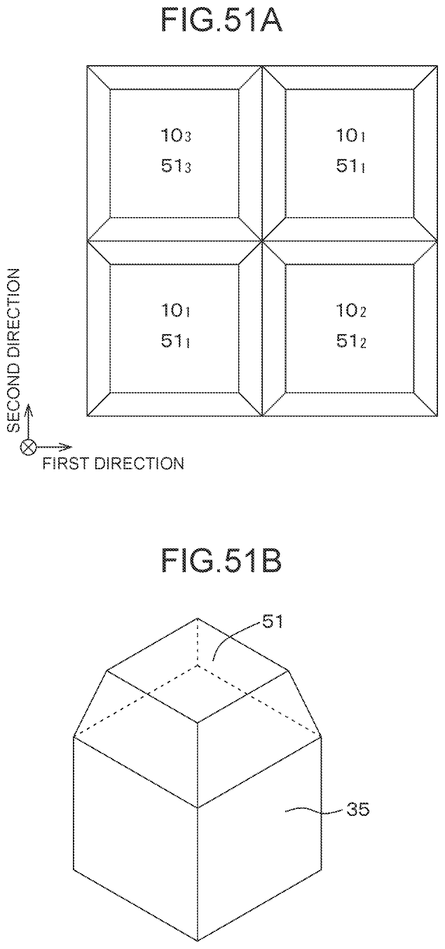

In Examples, the planar shape of the lens unit is a circular shape. The present invention is not limited to this, and the lens unit may have a truncated quadrangular pyramid shape as illustrated in FIGS. 51A and 51B in a modification of FIG. 2A. FIG. 51A is a schematic plan view of a lens unit having a truncated quadrangular pyramid shape, and FIG. 51B is a schematic perspective view thereof.

A light shielding unit may be provided between the light emitting elements to prevent light emitted from a certain light emitting element from entering a light emitting element adjacent to the certain light emitting element to cause optical crosstalk. That is, a groove may be formed between the light emitting elements, and the light shielding unit may be formed by embedding the groove with a light shielding material. By providing the light shielding unit in this manner, a ratio at which light emitted from a certain light emitting element enters an adjacent light emitting element can be reduced, and it is possible to inhibit occurrence of a phenomenon in which color mixing occurs and chromaticity of the entire pixel deviates from desired chromaticity. Then, since color mixing can be prevented, the color purity when the pixel emits light in a single color is increased, and the chromaticity point is deepened. Thus, the color gamut is widened, and the range of color representation of the display device is widened. In addition, the color filter layer disposed for each pixel to improve the color purity may be thinned or omitted depending on the configuration of the light emitting element, which enables light absorbed in the color filter layer to be extracted, resulting in improvement in the light emission efficiency. Alternatively, a light shielding property may be imparted to the light absorption layer (black matrix layer).

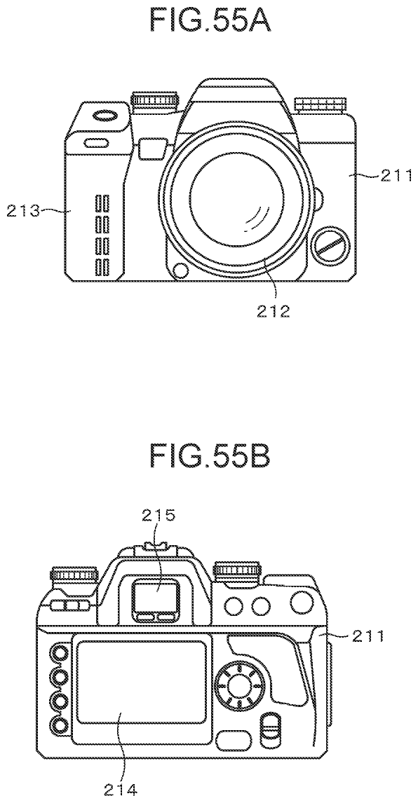

The display device of the present disclosure may be applied to a mirrorless interchangeable lens digital still camera. FIG. 55A is a front view of a digital still camera. FIG. 55B is a back view of the digital still camera. This mirrorless interchangeable lens digital still camera includes, for example, an interchangeable imaging lens unit (interchangeable lens) 212 on the front right side of a camera body 211, and a grip unit 213 to be held by a photographer on the front left side. A monitor device 214 is provided substantially at the center of the back surface of the camera body 211. An electronic view finder (eyepiece window) 215 is provided above the monitor device 214. The photographer can visually recognize an optical image of a subject guided from the imaging lens unit 212 and determine a composition by looking into the electronic view finder 215. The display device of the present disclosure can be used as the electronic view finder 215 in a mirrorless interchangeable lens digital still camera having such a configuration.

The present disclosure may also have the following configurations.

### [A01]

A display device comprising a plurality of light emitting element units,

the plurality of light emitting element units each including:

a first light emitting element including a first light emitting unit that emits light of a first color;

a second light emitting element including a second light emitting unit that emits light of a second color; and

a third light emitting element including a third light emitting unit that emits light of a third color,

wherein

in each light emitting element unit,

a first base having a thickness TB₁ is provided on the first light emitting unit,

a second base having a thickness TB₂ is provided on the second light emitting unit,

a third base having a thickness TB₃ is provided on the third light emitting unit,

a first lens unit having a thickness TL₁ is provided on the first base,

a second lens unit having a thickness TL₂ is provided on the second base,

a third lens unit having a thickness TL₃ is provided on the third base, and

(TL₃+TB₃)≤(TL₂+TB₂)<(TL₁+TB₁)

is satisfied, excluding a case where TB₃, TB₂, and TB₁ have a same value.

### [A02]

The display device according to [A01], wherein in each light emitting element unit, the bases have no side surface being in contact with a side surface of an adjacent base.

### [A03]

The display device according to [A01], wherein in each light emitting element unit, a base has a side surface being in contact with a side surface of an adjacent base.

### [A04]

The display device according to any one of [A01] to [A03], wherein in each light emitting element unit, each of the light emitting units includes a first electrode, an organic layer, and a second electrode.

### [A05]

The display device according to any one of [A01] to [A04], wherein

the first light emitting unit includes a first wavelength selection unit on a light emission side,

the second light emitting unit includes a second wavelength selection unit on the light emission side, and

the third light emitting unit includes a third wavelength selection unit on the light emission side.

### [A06]

The display device according to any one of [A01] to [A05], wherein in each light emitting element unit, the first light emitting unit, the second light emitting unit, and the third light emitting unit have a same thickness.

### [A07]

The display device according to any one of [A01] to [A05], wherein in each light emitting element unit, the first light emitting unit, the second light emitting unit, and the third light emitting unit are different in thickness.

### [A08]

The display device according to any one of [A01] to [A07], wherein in each light emitting element unit, the lens units are convex in a direction away from the light emitting units.

### [A09]

The display device according to [A08], wherein

n_{B-1}≤n_{L-1}

n_{B-2}≤n_{L-2}

n_{B-3}≤n_{L-3}

are satisfied where

n_{B-1} is a refractive index of a first base constituent material constituting the first base, n_{B-2} is a refractive index of a second base constituent material constituting the second base, n_{B-3} is a refractive index of a third base constituent material constituting the third base, n_{L-1} is a refractive index of a first lens unit constituent material constituting the first lens unit, n_{L-2} is a refractive index of a second lens unit constituent material constituting the second lens unit, and n_{L-3} is a refractive index of a third lens unit constituent material constituting the third lens unit.

### [A10]

The display device according to any one of [A01] to [A07], wherein in each light emitting element unit, the lens units are concave in a direction away from the light emitting units.

### [A11]

The display device according to any one of [A01] to [A07], wherein in each light emitting element unit, the lens units include a lens unit being convex in a direction away from the light emitting units and a lens unit being concave in a direction away from the light emitting units.

### [A12]

The display device according to [A01], wherein

in each light emitting element unit,

the first base has a stacked structure of a first L base, a first M base, and a first H base from a light emitting unit side,

the second base has a stacked structure of a second L base and a second H base from the light emitting unit side,

the first L base and the second L base each includes an extension part of the third base, and

the first M base includes an extension part of the second H base.

### [A13]

The display device according to [A12], wherein

n_{B-3}′>n_{B-2H}′>n_{B-1H}′

is satisfied where

n_{B-1H}′ is a refractive index of a first H base constituent material constituting the first H base, n_{B-2H}′ is a refractive index of a second H base constituent material constituting the second H base and the extension part of the second H base, and n_{B-3}′ is a refractive index of a third base constituent material constituting the third base and the extension part of the third base.

### [A14]

The display device according to [A12] or [A13], wherein in each light emitting element unit, the lens units are convex in a direction away from the light emitting units.

### [A15]

The display device according to any one of [A12] to [A14], wherein an orthographic projection image of the first lens unit of the first light emitting element and an orthographic projection image of the lens unit of a light emitting element adjacent to the first light emitting element partially overlap each other.

### [B01]

A display device comprising a plurality of light emitting element units,

the plurality of light emitting element units each including at least a first light emitting element having a first light emitting unit that emits light of a first color and a second light emitting element having a second light emitting unit that emits light of a second color,

wherein

in each light emitting element unit,

a first base having a thickness TB₁ is provided above the first light emitting unit,

a second base having a thickness TB₂ is provided above the second light emitting unit,

a first lens unit having a thickness TL₁ is provided on the first base, and

TB₂<(TL₁+TB₁)

is satisfied.

### [B02]

The display device according to [B01], wherein

each light emitting element unit further includes a third light emitting element including a third light emitting unit that emits light of a third color, and

in each light emitting element unit,

a third base having a thickness TB₃ is provided above the third light emitting unit, and

TB₃≤TB₂<(TL₁+TB₁)

is satisfied.

### [B03]

The display device according to [B01], wherein

a second lens unit having a thickness TL₂ is provided on the second base, and

(TL₂+TB₂)<(TL₁+TB₁)

is satisfied.

### [B04]

The display device according to [B03], wherein

each light emitting element unit further includes a third light emitting element including a third light emitting unit that emits light of a third color, and

in each light emitting element unit,

a third base having a thickness TB₃ is provided above the third light emitting unit, and

TB₃≤TB₂<(TL₁+TB₁)

is satisfied.

### [C01]

The display device according to any one of [A01] to [B04], wherein when a distance between a normal line passing through the center of the light emitting unit and a normal line passing through the center of the lens unit is D₀, a value of the distance D₀ is not 0 in at least some of the light emitting elements provided in the display panel.

### [C02]

The display device according to [C01], wherein a reference point P is assumed, and the distance D₀ depends on the distance D₁ from the reference point P to the normal line passing through the center of the light emitting unit.

### [C03]

The display device according to [C01] or [C02], wherein the reference point P is assumed in a display panel.

### [C04]

The display device according to [C03], wherein the reference point P is not located in the center region of the display panel.

### [C05]

The display device according to [C03] or [C04], wherein a plurality of the reference points P are assumed.

### [C06]

The display device according to [C03], wherein when one reference point P is assumed, the reference point P is not included in the center region of the display panel, and when a plurality of reference points P is assumed, at least one reference point P is not included in the center region of the display panel.

### [C07]

The display device according to [C01] or [C02], wherein the reference point P is assumed outside the display panel.

### [C08]

The display device according to [C07], wherein a plurality of the reference points P are assumed.

### [C09]

The display device according to any one of [C01] to [C08], wherein light emitted from each light emitting element and passing through the lens unit converges to a certain region in a space outside the display device.

### [C10]

The display device according to any one of [C01] to [C08], wherein light emitted from each light emitting element and passing through the lens unit diverges in a space outside the display device.

### [C11]

The display device according to any one of [C01] to [C06], wherein light emitted from each light emitting element and passing through the lens unit is parallel light.

### [C12]

The display device according to any one of [C01] to [C11], wherein

a reference point P is set, and

the plurality of light emitting elements are arranged in a first direction and a second direction different from the first direction,

when a distance from the reference point P to a normal line passing through the center of the light emitting unit is D₁, values of the distance D₀ in the first direction and the second direction are D_{0-X} and D_{0-Y}, respectively, and values of the distance D₁ in the first direction and the second direction are D_{1-X} and D_{1-Y}, respectively,

D_{0-X} changes linearly with respect to a change of D_{1-X}, and D_{0-Y} changes linearly with respect to a change of D_{1-Y}, or

D_{0-X} changes linearly with respect to a change of D_{1-X}, and D_{0-Y} changes nonlinearly with respect to a change of D_{1-Y}, or

D_{0-X} changes nonlinearly with respect to a change of D_{1-X}, and D_{0-Y} changes linearly with respect to a change of D_{1-Y}, or

D_{0-X} changes nonlinearly with respect to a change of D_{1-X}, and D_{0-Y} changes nonlinearly with respect to a change of D_{1-Y}.

### [C13]

The display device according to any one of [C01] to [C12], wherein

a reference point P is set, and

when a distance from the reference point P to a normal line passing through the center of the light emitting unit is D₁, a value of the distance D₀ increases as a value of the distance D₁ increases.

[C14] The display device according to any one of [C01] to [C13], wherein a wavelength selection unit is provided on a light incident side or a light emission side of the lens unit.

### [C15]

The display device according to [C14], wherein an orthogonal projection image of the lens unit matches up with an orthogonal projection image of the wavelength selection unit or is included in the orthogonal projection image of the wavelength selection unit.

### [C16]

The display device according to [C14] or [C15], wherein in the light emitting element in which the value of the distance D₀ is not 0, the normal line passing through the center of the wavelength selection unit matches up with the normal line passing through the center of the light emitting unit.

### [C17]

The display device according to [C14] or [C15], wherein in the light emitting element in which the value of the distance D₀ is not 0, the normal line passing through the center of the wavelength selection unit matches up with the normal line passing through the center of the lens unit.

### [C18]

The display device according to [C14], wherein

the orthographic projection image of the lens unit is included in the orthographic projection image of the wavelength selection unit, and

in the light emitting element in which the value of the distance D₀ is not 0, the normal line passing through the center of the wavelength selection unit matches up with the normal line passing through the center of the light emitting unit.

### [C19]

The display device according to [C14], wherein

the orthographic projection image of the lens unit is included in the orthographic projection image of the wavelength selection unit, and

in the light emitting element in which the value of the distance D₀ is not 0, the normal line passing through the center of the wavelength selection unit matches up with the normal line passing through the center of the lens unit.

### [C20]

The display device according to [C14], wherein

the orthographic projection image of the lens unit matches up with the orthographic projection image of the wavelength selection unit, and

in the light emitting element in which the value of the distance D₀ is not 0, the normal line passing through the center of the wavelength selection unit matches up with the normal line passing through the center of the lens unit.

### [C21]

The display device according to any one of [C14] to [C17], wherein a light absorption layer is formed between the wavelength selection units of adjacent light emitting elements.

### REFERENCE SIGNS LIST

10, 10₁, 10₂, 10₃ LIGHT EMITTING ELEMENT
20 TRANSISTOR
21 GATE ELECTRODE
22 GATE INSULATING LAYER
23 CHANNEL FORMATION REGION
24 SOURCE/DRAIN REGION
25 ELEMENT ISOLATION REGION
26 BASE BODY (INTERLAYER INSULATING LAYER)
27 CONTACT PLUG
28 INSULATING LAYER
29 VARIOUS COMPONENTS OF DISPLAY DEVICES LOCATED BELOW BASE BODY (INTERLAYER INSULATING LAYER)
30, 30₁, 30₂, 30₃ LIGHT EMITTING UNIT
31 FIRST ELECTRODE
32 SECOND ELECTRODE
33 ORGANIC LAYER (INCLUDING LIGHT EMITTING LAYER)
34 INTERMEDIATE LAYER
35, 35₁, 35₂, 35₃, 135₁, 135₂, 135₃ BASE
35′ BASE CONSTITUENT MATERIAL LAYER
35A EXTENSION PART OF THIRD BASE
35B SECOND BASE CONSTITUENT LAYER
35C FIRST BASE CONSTITUENT LAYER
35D BASE CONSTITUENT LAYER
35_{1-L} FIRST L BASE
35_{1-M} FIRST M BASE
35_{1-H} FIRST H BASE
35_{2-L} SECOND L BASE
35_{2-H} SECOND H BASE
36 SEALING RESIN LAYER
37 SUPPORT UNIT
38 FLATTENING LAYER
41 FIRST SUBSTRATE
42 SECOND SUBSTRATE
51, 51₁, 51₂, 51₃ LENS UNIT
51′ LIGHT EMISSION SURFACE (OUTER SURFACE) OF LENS UNIT
51″ LIGHT INCIDENT SURFACE OF LENS UNIT
61 LIGHT REFLECTION LAYER
62 INTERLAYER INSULATING LAYER
63 FOUNDATION FILM
CF, CF₁, CF₂, CF₃ WAVELENGTH SELECTION UNIT (COLOR FILTER LAYER)

1. A display device comprising a plurality of light emitting element units,
the plurality of light emitting element units each including:
a first light emitting element including a first light emitting unit that emits light of a first color;
a second light emitting element including a second light emitting unit that emits light of a second color; and
a third light emitting element including a third light emitting unit that emits light of a third color,
wherein
in each light emitting element unit,
a first base having a thickness TB₁ is provided on the first light emitting unit,
a second base having a thickness TB₂ is provided on the second light emitting unit,
a third base having a thickness TB₃ is provided on the third light emitting unit,
a first lens unit having a thickness TL₁ is provided on the first base,
a second lens unit having a thickness TL₂ is provided on the second base,
a third lens unit having a thickness TL₃ is provided on the third base, and
(TL₃+TB₃)≤(TL₂+TB₂)<(TL₁+TB₁)
is satisfied, excluding a case where TB₃, TB₂, and TB₁ have a same value.

2. The display device according to claim 1, wherein in each light emitting element unit, the bases have no side surface being in contact with a side surface of an adjacent base.

3. The display device according to claim 1, wherein in each light emitting element unit, a base has a side surface being in contact with a side surface of an adjacent base.

4. The display device according to claim 1, wherein in each light emitting element unit, each of the light emitting units includes a first electrode, an organic layer, and a second electrode.

5. The display device according to claim 1, wherein
the first light emitting unit includes a first wavelength selection unit on a light emission side,
the second light emitting unit includes a second wavelength selection unit on the light emission side, and
the third light emitting unit includes a third wavelength selection unit on the light emission side.

6. The display device according to claim 1, wherein in each light emitting element unit, the first light emitting unit, the second light emitting unit, and the third light emitting unit have a same thickness.

7. The display device according to claim 1, wherein in each light emitting element unit, the first light emitting unit, the second light emitting unit, and the third light emitting unit are different in thickness.

8. The display device according to claim 1, wherein in each light emitting element unit, the lens units are convex in a direction away from the light emitting units.

9. The display device according to claim 8, wherein
n_{B-1}≥n_{L-1}
n_{B-2}≥n_{L-2}
n_{B-3}≥n_{L-3}
are satisfied where
n_{B-1} is a refractive index of a first base constituent material constituting the first base, n_{B-2} is a refractive index of a second base constituent material constituting the second base, n_{B-3} is a refractive index of a third base constituent material constituting the third base, n_{L-1} is a refractive index of a first lens unit constituent material constituting the first lens unit, n_{L-2} is a refractive index of a second lens unit constituent material constituting the second lens unit, and n_{L-3} is a refractive index of a third lens unit constituent material constituting the third lens unit.

10. The display device according to claim 1, wherein in each light emitting element unit, the lens units are concave in a direction away from the light emitting units.

11. The display device according to claim 1, wherein in each light emitting element unit, the lens units include a lens unit being convex in a direction away from the light emitting units and a lens unit being concave in a direction away from the light emitting units.

12. The display device according to claim 1, wherein
in each light emitting element unit,
the first base has a stacked structure of a first L base, a first M base, and a first H base from a light emitting unit side,
the second base has a stacked structure of a second L base and a second H base from the light emitting unit side,
the first L base and the second L base each includes an extension part of the third base, and
the first M base includes an extension part of the second H base.

13. The display device according to claim 12, wherein
n_{B-3}′>n_{B-2H}′>n_{B-1H}′
is satisfied where
n_{B-1H}′ is a refractive index of a first H base constituent material constituting the first H base, n_{B-2H}′ is a refractive index of a second H base constituent material constituting the second H base and the extension part of the second H base, and n_{B-3}′ is a refractive index of a third base constituent material constituting the third base and the extension part of the third base.

14. The display device according to claim 12, wherein in each light emitting element unit, the lens units are convex in a direction away from the light emitting units.

15. The display device according to claim 12, wherein an orthographic projection image of the first lens unit of the first light emitting element and an orthographic projection image of the lens unit of a light emitting element adjacent to the first light emitting element partially overlap each other.

16. A display device comprising a plurality of light emitting element units,
the plurality of light emitting element units each including at least a first light emitting element having a first light emitting unit that emits light of a first color and a second light emitting element having a second light emitting unit that emits light of a second color,
wherein
in each light emitting element unit,
a first base having a thickness TB₁ is provided above the first light emitting unit,
a second base having a thickness TB₂ is provided above the second light emitting unit,
a first lens unit having a thickness TL₁ is provided on the first base, and
TB₂<(TL₁+TB₁)
is satisfied.

17. The display device according to claim 16, wherein
each light emitting element unit further includes a third light emitting element including a third light emitting unit that emits light of a third color, and
in each light emitting element unit,
a third base having a thickness TB₃ is provided above the third light emitting unit, and
TB₃≤TB₂<(TL₁+TB₁)
is satisfied.

18. The display device according to claim 16, wherein
a second lens unit having a thickness TL₂ is provided on the second base, and
(TL₂+TB₂)<(TL₁+TB₁)
is satisfied.

19. The display device according to claim 18, wherein
each light emitting element unit further includes a third light emitting element including a third light emitting unit that emits light of a third color, and
in each light emitting element unit,
a third base having a thickness TB₃ is provided above the third light emitting unit, and
TB₃≤TB₂<(TL₁+TB₁)
is satisfied.
